(19) United States
(12) Patent Application Publication
(10) Pub. No.: US 2010/0259201 A1
(43) Pub. Date: Oct. 14, 2010

(54) SEMICONDUCTOR DEVICE

(75) Inventors: Makoto KAWANO, Tokyo (JP); Katsutoshi Bito, Tokyo (JP); Atsushi Mitamura, Tokyo (JP); Kohei Kawano, Tokyo (JP)

Correspondence Address: MILES & STOCKBRIDGE PC, 1751 PINNACLE DRIVE, SUITE 500, MCLEAN, VA, 22102-3833, US

(73) Assignee: RENESAS TECHNOLOGY CORP.

(21) Appl. No.: 12/756,176

(22) Filed: Apr. 7, 2010

(30) Foreign Application Priority Data
Apr. 9, 2009 (JP) 2009-095084

(51) Int. Cl. H05B 37/02; H01L 27/06

(52) U.S. Cl. 315/362; 257/140; 257/E27.017

(57) ABSTRACT

The size of a light emitting device is reduced. The light emitting device for flash photography includes: a luminescent xenon tube; IGBT for the discharge switch of the xenon tube; a capacitor for discharging the xenon tube; and MOSFET for the charge switch of the capacitor. A semiconductor device used in this light emitting device is obtained by sealing the following in a package: a semiconductor chip in which the IGBT is formed; a semiconductor chip in which the MOSFET is formed; a semiconductor chip in which a drive circuit of the IGBT and a control circuit of the MOSFET are formed; and multiple leads coupled thereto.

### CROSS-REFERENCE TO RELATED APPLICATIONS

The disclosure of Japanese Patent Application No. 2009-95084 filed on Apr. 9, 2009 including the specification, drawings and abstract is incorporated herein by reference in its entirety.

### BACKGROUND OF THE INVENTION

The present invention relates to semiconductor devices and in particular to a technology effectively applicable to semiconductor devices used in light emitting devices for flash photography.

In recent years, the numbers of pixels of cameras built in cellular phones have been more and more increased and cellular phones equipped with a megapixel camera are becoming widely used. In these circumstances, the light emitting devices for flash photography of cameras built in cellular phones have increasingly adopted a xenon tube large in quantity of light, not a conventional LED.

Japanese Unexamined Patent Publication No. 2003-21860 (Patent Document 1) describes a technology related to a strobe unit for cameras.

Japanese Unexamined Patent Publication No. 2005-302380 (Patent Document 2) describes a technology related to a driver circuit for xenon lamps.

Japanese Unexamined Patent Publication No. 2003-315879 (Patent Document 3) describes a technology related to a camera with built-in strobe and discloses strobe circuitry.

Japanese Unexamined Patent Publication No. 2004-103995 (Patent Document 4) describes a technology related to an IGBT device for controlling a strobe.

[Patent Document 1]

Japanese Unexamined Patent Publication No. 2003-21860

[Patent Document 2]

Japanese Unexamined Patent Publication No. 2005-302380

[Patent Document 3]

Japanese Unexamined Patent Publication No. 2003-315879

[Patent Document 4]

Japanese Unexamined Patent Publication No. 2004-103995

### SUMMARY OF THE INVENTION

The investigation by the present inventors revealed the following:

Mobile communication instruments such as cellular phones are highly demanded to be reduced in size and thickness. Therefore, also with respect to light emitting devices for flash photography built therein, there is a high demand for size reduction.

When in a light emitting device for flash photography, the components comprising it are individually mounted over a mounting board, a problem arises. The number of components mounted over the mounting board is increased and this increases the cost of the light emitting device and the planar dimensions of the light emitting device as well. Consequently, to reduce the planar dimensions of the entire light emitting device, it is desired to add some twist to the geometries of each component comprising the light emitting device. In light emitting devices for flash photography, high voltage is applied to each component and a large current is passed when a xenon tube emits light. Therefore, to enhance the reliability of a light emitting device, it is required to take high voltage and large current into account when a twist is added to the geometries of each component comprising the light emitting device.

It is an object of the invention to enhance the characteristics of a semiconductor device and in particular to provide a technology that makes it possible to reduce the size of a semiconductor device including a light emitting device.

The above and other objects and novel features of the invention will be apparent from the description in this specification and the accompanying drawings.

The following is a brief description of the gist of the representative elements of the invention laid open in this application:

The semiconductor device in a typical embodiment is a semiconductor device used in a light emitting device including: a luminescent discharge tube; IGBT for the discharge switch of the discharge tube, coupled in series with the discharge tube; a capacitor for discharging the discharge tube, coupled in parallel with a series circuit of the discharge tube and the IGBT; and MOSFET for the charge switch of the capacitor. This semiconductor device includes: a first semiconductor chip in which the IGBT is formed; a second semiconductor chip in which the MOSFET is formed; a third semiconductor chip in which the drive circuit of the IGBT and the control circuit of the MOSFET are formed; and a sealing body that seals the first, second, and third semiconductor chips.

The following is a brief description of the gist of effect obtained by the representative elements of the invention laid open in this application:

According to atypical embodiment, it is possible to enhance the characteristics of a semiconductor device and in particular to reduce the size of a semiconductor device including a light emitting device.

Further, it is possible to enhance the reliability of a semiconductor device, in particular, a semiconductor device including a light emitting device.

### BRIEF DESCRIPTION OF THE DRAWINGS

FIG. 1 is a circuit diagram illustrating the circuitry of a light emitting device in an embodiment of the invention;

FIG. 2 is an explanatory drawing illustrating the overall configuration of a light emitting device in an embodiment of the invention;

FIG. 3 is an explanatory drawing illustrating an example of the overall configuration of a light emitting device in a comparative example;

FIG. 4 is a top view of a semiconductor device in an embodiment of the invention;

FIG. 5 is a bottom view of a semiconductor device in an embodiment of the invention;

FIG. 6 is a sectional view of a semiconductor device in an embodiment of the invention;

FIG. 7 is a sectional view of a semiconductor device in an embodiment of the invention;

FIG. 8 is a sectional view of a semiconductor device in an embodiment of the invention;

FIG. 9 is a sectional view of a semiconductor device in an embodiment of the invention;

FIG. 10 is a sectional view of a semiconductor device in an embodiment of the invention;

FIG. 11 is a planar transparent view of a semiconductor device in an embodiment of the invention;

FIG. 12 is a planar transparent view of a semiconductor device in an embodiment of the invention;

FIG. 13 is a planar transparent view of a semiconductor device in an embodiment of the invention;

FIG. 14 is an explanatory drawing of a light emitting device in an embodiment of the invention;

FIG. 15 is a planar transparent view illustrating a modification of a semiconductor device in an embodiment of the invention;

FIG. 16 is a sectional view illustrating a modification of a semiconductor device in an embodiment of the invention;

FIG. 17 is a bottom view illustrating a modification of a semiconductor device in an embodiment of the invention;

FIG. 18 is a planar transparent view illustrating another modification of a semiconductor device in an embodiment of the invention;

FIG. 19 is a sectional view illustrating another modification of a semiconductor device in an embodiment of the invention;

FIG. 20 is a bottom view illustrating another modification of a semiconductor device in an embodiment of the invention;

FIG. 21 is a sectional view illustrating another modification of a semiconductor device in an embodiment of the invention;

FIG. 22 is a planar transparent view of a semiconductor device in another embodiment of the invention;

FIG. 23 is a planar transparent view of a semiconductor device in another embodiment of the invention;

FIG. 24 is a sectional view of a semiconductor device in another embodiment of the invention;

FIG. 25 is a sectional view of a semiconductor device in another embodiment of the invention;

FIG. 26 is a bottom view of a semiconductor device in another embodiment of the invention;

FIG. 27 is a planar transparent view of a semiconductor device in another embodiment of the invention;

FIG. 28 is a planar transparent view of a semiconductor device in another embodiment of the invention;

FIG. 29 is a sectional view of a semiconductor device in another embodiment of the invention;

FIG. 30 is a planar transparent view of a semiconductor device in another embodiment of the invention;

FIG. 31 is a planar transparent view of a semiconductor device in another embodiment of the invention;

FIG. 32 is a sectional view of a semiconductor device in another embodiment of the invention;

FIG. 33 is a planar transparent view of a semiconductor device in another embodiment of the invention;

FIG. 34 is a sectional view of a semiconductor device in another embodiment of the invention;

FIG. 35 is a planar transparent view of a semiconductor device in another embodiment of the invention;

FIG. 36 is a planar transparent view of a semiconductor device in another embodiment of the invention;

FIG. 37 is a planar transparent view of a semiconductor device in another embodiment of the invention;

FIG. 38 is a sectional view of a semiconductor device in another embodiment of the invention;

FIG. 39 is a bottom view of a semiconductor device in another embodiment of the invention;

FIG. 40 is a planar transparent view of a semiconductor device in another embodiment of the invention;

FIG. 41 is a planar transparent view of a semiconductor device in another embodiment of the invention;

FIG. 42 is a sectional view of a semiconductor device in another embodiment of the invention;

FIG. 43 is a sectional view of a semiconductor device in another embodiment of the invention;

FIG. 44 is a substantial part sectional view of a semiconductor chip in an embodiment of the invention;

FIG. 45 is a substantial part sectional view of a semiconductor chip in another embodiment of the invention;

FIG. 46 is a sectional view of a semiconductor device in an embodiment of the invention in manufacturing process;

FIG. 47 is a sectional view of the semiconductor device in manufacturing process, following FIG. 46;

FIG. 48 is a sectional view of the semiconductor device in manufacturing process, following FIG. 47;

FIG. 49 is a sectional view of the semiconductor device in manufacturing process, following FIG. 48;

FIG. 50 is a sectional view of the semiconductor device in manufacturing process, following FIG. 49;

FIG. 51 is a sectional view of the semiconductor device in manufacturing process, following FIG. 50;

FIG. 52 is a sectional view of a semiconductor device in another embodiment of the invention;

FIG. 53 is a sectional view of a semiconductor device in another embodiment of the invention;

FIG. 54 is a sectional view of a semiconductor device in another embodiment of the invention;

FIG. 55 is a sectional view of a semiconductor device in another embodiment of the invention;

FIG. 56 is a planar transparent view of a semiconductor device in another embodiment of the invention;

FIG. 57 is a planar transparent view of a semiconductor device in another embodiment of the invention;

FIG. 58 is a bottom view of a semiconductor device in another embodiment of the invention;

FIG. 59 is a sectional view of a semiconductor device in another embodiment of the invention;

FIG. 60 is a sectional view of a semiconductor device in another embodiment of the invention;

FIG. 61 is a sectional view of a semiconductor device in another embodiment of the invention;

FIG. 62 is a sectional view of a semiconductor device in another embodiment of the invention;

FIG. 63 is a sectional view of a semiconductor device in another embodiment of the invention;

FIG. 64 is a planar transparent view of a semiconductor device in another embodiment of the invention;

FIG. 65 is a planar transparent view of a semiconductor device in another embodiment of the invention;

FIG. 66 is a bottom view of a semiconductor device in another embodiment of the invention;

FIG. 67 is a sectional view of a semiconductor device in another embodiment of the invention in manufacturing process;

FIG. 68 is a sectional view of the semiconductor device in manufacturing process, following FIG. 67;

FIG. 69 is a sectional view of the semiconductor device in manufacturing process, following FIG. 68;

FIG. 70 is a sectional view of the semiconductor device in manufacturing process, following FIG. 69;

FIG. 71 is a sectional view of the semiconductor device in manufacturing process, following FIG. 70;

FIG. 72 is a sectional view of the semiconductor device in manufacturing process, following FIG. 71;

FIG. 73 is a sectional view of the semiconductor device in manufacturing process, following FIG. 72;

FIG. 74 is a sectional view of the semiconductor device in manufacturing process, following FIG. 73;

FIG. 75 is a planar transparent view of a semiconductor device in another embodiment of the invention;

FIG. 76 is a bottom view of a semiconductor device in another embodiment of the invention;

FIG. 77 is a planar transparent view of a semiconductor device in another embodiment of the invention;

FIG. 78 is a bottom view of a semiconductor device in another embodiment of the invention; and

FIG. 79 is a substantial part sectional view of a semiconductor chip in an embodiment of the invention.

### DETAILED DESCRIPTION OF THE PREFERRED EMBODIMENTS

In the following description, each embodiment will be divided into multiple sections if necessary for the sake of convenience. Unless explicitly stated otherwise, they are not unrelated to one another and they are in such a relation that one is a modification, details, supplementary explanation, or the like of part or all of the other. When mention is made of any number of elements (including a number of pieces, a numeric value, a quantity, a range, and the like) in the following description of embodiments, the number is not limited to that specific number. Unless explicitly stated otherwise or the number is obviously limited to a specific number in principle, the foregoing applies and the number may be above or below that specific number. In the following description of embodiments, needless to add, their constituent elements (including elemental steps and the like) are not always indispensable unless explicitly stated otherwise or they are obviously indispensable in principle. Similarly, when mention is made of the shape, positional relation, or the like of a constituent element or the like in the following description of embodiments, it includes those substantially approximate or analogous to that shape or the like. This applies unless explicitly stated otherwise or it is apparent in principle that some shape or the like does not include those substantially approximate or analogous to that shape or the like. This is the same with the above-mentioned numeric values and ranges.

Hereafter, detailed description will be given to embodiments of the invention with reference to the drawings. In all the drawings for explaining embodiments, members having the same function will be marked with the same reference numerals and the repetitive description thereof will be omitted. With respect to the following embodiments, description will not be repeated about an identical or similar part unless necessary.

In every drawing used in the description of embodiments, hatching may be omitted to facilitate visualization even though it is a sectional view. Further, hatching may be provided to facilitate visualization even though it is a plan view.

In this specification, a field effect transistor will be described as MOSFET (Metal Oxide Semiconductor Field Effect Transistor) or simply as MOS. However, this is not intended to exclude non-oxide films from gate oxide films.

### First Embodiment

<Circuitry of Light Emitting Device>

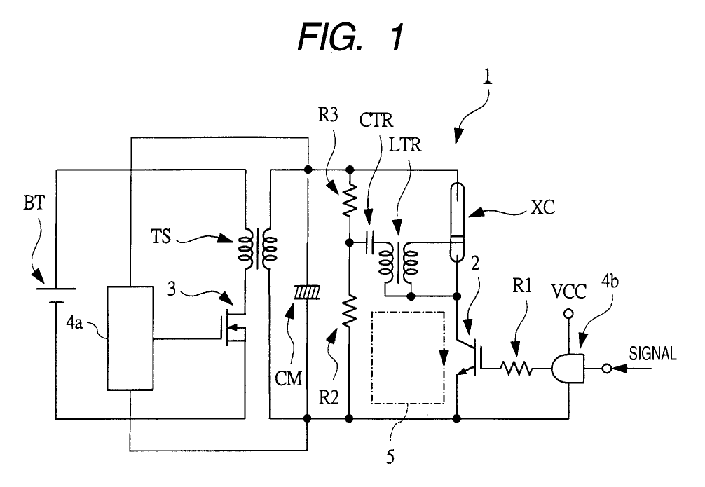

FIG. 1 is a circuit diagram illustrating an example of the basic circuitry of a flash (strobe) as a light emitting device used in photography and the like.

The light emitting device (flash, strobe) 1 illustrated in FIG. 1 includes: a xenon tube (discharge tube, discharge lamp, arc tube) XC as a luminescent discharge tube (discharge lamp); IGBT (Insulated Gate Bipolar Transistor) 2 coupled in series with the xenon tube XC; and a main capacitor (capacitor) CM coupled in parallel with a series circuit of the xenon tube XC and the IGBT 2. The IGBT 2 functions as a switching element for the discharge switch of the xenon tube XC and the main capacitor CM is a capacitor for discharging the xenon tube XC. More specifically, the collector of the IGBT 2 is coupled to one internal electrode of the xenon tube XC; the emitter of the IGBT 2 is coupled to one electrode of the main capacitor CM; and the other electrode of the main capacitor CM is coupled to the other internal electrode of the xenon tube XC. The xenon tube XC is comprised of a glass tube filled with xenon gas and an internal electrode is respectively placed in proximity to both ends in the glass tube so that the tube can be discharged between the internal electrodes. The xenon tube XC is also provided with a trigger electrode (external trigger electrode).

The light emitting device 1 illustrated in FIG. 1 further includes: a battery BT for charging the main capacitor CM through a step-up transformer (transformer) TS; and MOSFET (Metal Oxide Semiconductor Field Effect Transistor) 3 that functions a switching element for the charge switch of the main capacitor CM. Specifically, the drain of the MOSFET 3 is coupled to one end of the primary coil of the step-up transformer TS; the other end of this primary coil is coupled to the battery BT; the source of the MOSFET 3 is coupled to reference potential (ground potential, GND potential, grounding potential); and both ends of the secondary coil of the step-up transformer TS are respectively coupled to both electrodes of the main capacitor CM.

The light emitting device 1 illustrated in FIG. 1 further includes: a control circuit (charge control circuit, MOSFET control circuit) 4a that controls the MOSFET 3; and a drive circuit (driver circuit, IGBT driver circuit, IGBT control circuit) 4b for driving the IGBT 2. The drive circuit 4b is coupled to the gate of the IGBT 2 through a resistor R1.

The light emitting device 1 illustrated in FIG. 1 further includes: a trigger coil (coil for triggering) LTR coupled to the trigger electrode (external trigger electrode) of the xenon tube XC; a trigger capacitor (capacitor for triggering) CTR for passing current through the trigger coil LTR; and resistors R2, R3.

<Operation of Light Emitting Device>

Description will be given to the basic operation of the light emitting device 1 illustrated in FIG. 1.

First, description will be given to the charge operation of the light emitting device 1 (the charge operation of the main capacitor CM).

When a charge start control signal is inputted to the control circuit 4a (in the semiconductor device SM1 described later from the lead LDB1 described later), the following processing is carried out to start charging of the main capacitor CM: a predetermined voltage (on voltage, voltage equal to or higher than the threshold value of the MOSFET 3) is applied to the gate electrode of the MOSFET 3 by the control circuit 4a to turn on the MOSFET 3.

When the MOSFET 3 is brought into on state (conduction), a current can be passed through the coils of the step-up transformer TS. Therefore, the voltage of the battery BT is boosted (converted into high voltage) at the step-up transformer TS and applied to the main capacitor CM and the main capacitor CM is thereby charged. That is, when the MOSFET 3 is brought into on state, a current is passed through the primary coil of the step-up transformer TS by the voltage of the battery BT and thus a current is also passed through the secondary coil of the step-up transformer TS. For this reason, the main capacitor CM is charged. Therefore, it can be said that the MOSFET 3 is brought into on state by the control circuit 4a and the main capacitor CM is thereby charged. At this time, the charging voltage of the main capacitor CM can be set to, for example, 300 to 400V or so. When the main capacitor CM is charged, the trigger capacitor CTR can also be charged. While the main capacitor CM is being charged (while the MOSFET 3 is kept in on state), the IGBT 2 is kept in off state.

When the main capacitor CM is sufficiently charged, the MOSFET 3 is turned off by the control circuit 4a. That is, the application of on voltage to the gate electrode of the MOSFET 3 is stopped and the MOSFET 3 is turned off. When the MOSFET 3 is brought into off state, voltage application from the battery BT to the main capacitor CM through the step-up transformer TS is stopped and the charge operation of the main capacitor CM is terminated.

Description will be given to the light emitting operation of the light emitting device 1.

When after the main capacitor CM is charged through the above charge operation, an on signal (IGBT driving signal) is inputted to the drive circuit 4b (in the semiconductor device SM1 from the lead LDB5 described later), the following takes place: driving voltage for the IGBT 2 (IGBT driving voltage) is generated at the drive circuit 4b; this driving voltage is applied from the drive circuit 4b to the gate electrode of the IGBT 2 by way of the resistor R1; and the IGBT 2 is thereby turned on. When the IGBT 2 is brought into on state (conduction), the voltage charged in the main capacitor CM is applied to the internal electrodes of the xenon tube XC. As the result of the IGBT 2 being brought into on state by the drive circuit 4b, the xenon tube XC is discharged by voltage supplied by the main capacitor CM and emits light.

However, voltage may be insufficient to start arc discharge of the xenon tube XC just by the voltage charged in the main capacitor CM being applied to the internal electrodes of the xenon tube XC. To cope with this, the following measure is taken. When the IGBT 2 is brought into on state, the trigger capacitor CTR is first discharged through the path 5 schematically indicated by alternate long and short dash line in FIG. 1. As a result, a high trigger voltage (for example, 5 kV or so) is applied to the trigger electrode (external trigger electrode) of the xenon tube XC through the trigger coil LTR. This application of trigger voltage ionizes the gas in the xenon tube XC and the impedance is drastically reduced. Therefore, arc discharge is caused in the xenon tube XC by discharge from the main capacitor CM (voltage supplied by the main capacitor CM) and the xenon tube XC emits light. At this time, the discharging current can be set to, for example, 100 to 200 A or so.

When after the xenon tube XC emits light, an off signal is inputted to the drive circuit 4b, the application of driving voltage to the gate electrode of the IGBT 2 by the drive circuit 4b is stopped and the IGBT 2 is turned off. As a result, the current passed through the xenon tube XC is stopped and light emission of the xenon tube XC is stopped. Therefore, light emission of the xenon tube XC is switched between start and end by switching the state of the IGBT 2 between on state and off state by the drive circuit 4b. The light emission time of the xenon tube XC can be controlled by adjusting the time for which the IGBT 2 is in on state. For example, the following operation can be carried out: an on signal is inputted to the drive circuit 4b in conjunction with the shutter of the camera and IGBT driving voltage is thereby applied to the gate of the IGBT 2 to turn on the IGBT 2; and after an optimum light emission time has passed, an off signal is inputted to the drive circuit 4b and the application of IGBT driving voltage to the gate of the IGBT 2 is thereby stopped to turn off the IGBT 2. While the xenon tube XC is in light emitting operation (while the IGBT 2 is kept in on state), the MOSFET 3 is kept in off state.

<Overall Configuration of Light Emitting Device>

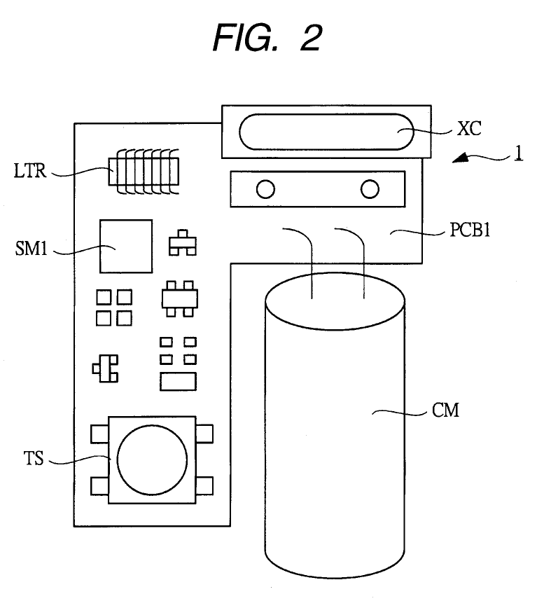

FIG. 2 is an explanatory drawing (plan view) illustrating an example of the overall configuration of the light emitting device 1 in FIG. 1.

In the light emitting device 1 illustrated in FIG. 2, components, such as the main capacitor CM, trigger coil LTR, step-up transformer TS, and xenon tube XC, are placed (mounted) over a circuit board (mounting board) PCB1. Further, the semiconductor device (semiconductor package) SM1 is placed (mounted) over the circuit board PCB1. In this semiconductor device SM1, the above-mentioned IGBT 2, MOSFET 3, control circuit 4a, and drive circuit 4b are embedded.

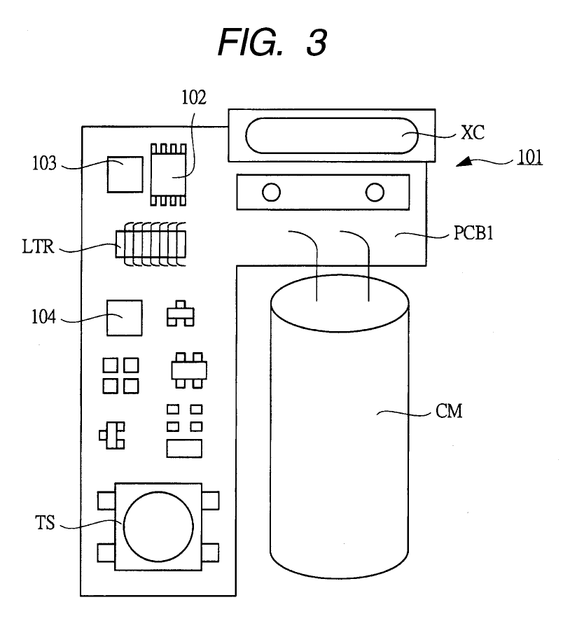

FIG. 3 is an explanatory drawing (plan view) illustrating the overall configuration of a light emitting device 101 in a comparative example and corresponds to FIG. 2 illustrating this embodiment. In the light emitting device 101 in the comparative example in FIG. 3, components, such as the main capacitor CM, trigger coil LTR, step-up transformer TS, and xenon tube XC are placed (mounted) over the circuit board PCB1. Further, semiconductor devices (semiconductor packages) 102, 103, 104 are placed over the circuit board PCB1. In the light emitting device 101 in the comparative example in FIG. 3, unlike that in this embodiment, the above-mentioned IGBT 2 is embedded in the semiconductor device 102; the above-mentioned MOSFET 3 is embedded in the semiconductor device 103; and the above-mentioned control circuit 4a and drive circuit 4b are embedded in the semiconductor device 104. That is, in the semiconductor device 102, only the semiconductor chip CP1 described later is packaged; in the semiconductor device 103, only the semiconductor chip CP2 described later is packaged; and in the semiconductor device 104, only the semiconductor chip CP3 described later is packaged.

In the light emitting device 101 in the comparative example in FIG. 3, the IGBT 2, MOSFET 3, and control circuit 4a and drive circuit 4b are respectively embedded in the different semiconductor devices 102, 103, 104; and these semiconductor devices 102, 103, 104 are mounted over the circuit board PCB1. This increases the number of components placed over the circuit board PCB1, which leads to the increased cost of the light emitting device 101 and the increased planar dimensions of the light emitting device 101

In this embodiment, meanwhile, the IGBT 2 is formed in the semiconductor chip CP1 described later; the MOSFET 3 is formed in the semiconductor chip CP2 described later; the control circuit 4a and the drive circuit 4b are formed in the semiconductor chip CP3 described later; and the three semiconductor chips CP1, CP2, CP3 are put together (packaged) into one semiconductor package (that is, the semiconductor device SM1) to obtain one semiconductor device SM1. This semiconductor device SM1 is placed (mounted) over the circuit board PCB1 to form the light emitting device 1. This makes it possible to reduce the number of components placed over the circuit board PCB1 in such a light emitting device 1 as illustrated in FIG. 2 and achieve reduction of the size (area) of the entire light emitting device 1. Further, since the wiring parasitic inductance can be reduced, it is possible to prevent erroneous light emission due to gate malfunction and the occurrences of underexposure and overexposure.

<Concrete Configuration of Semiconductor Device>

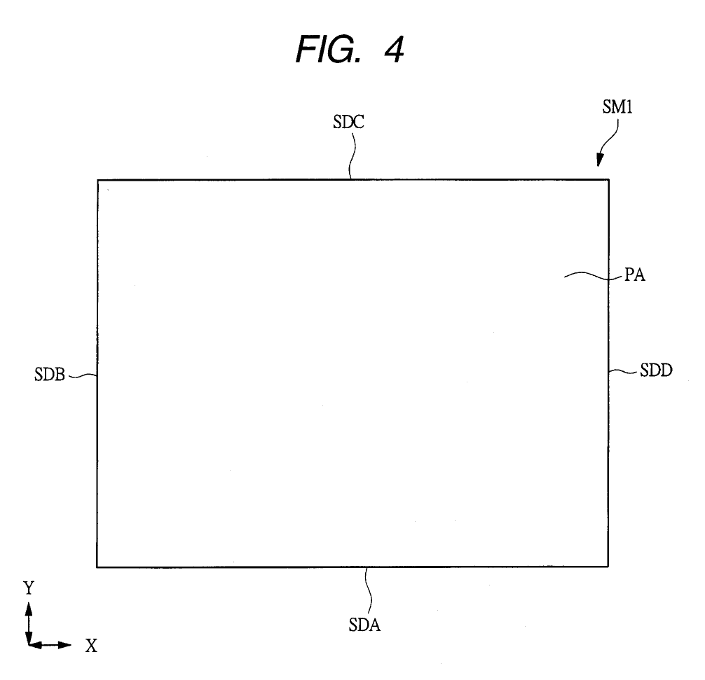

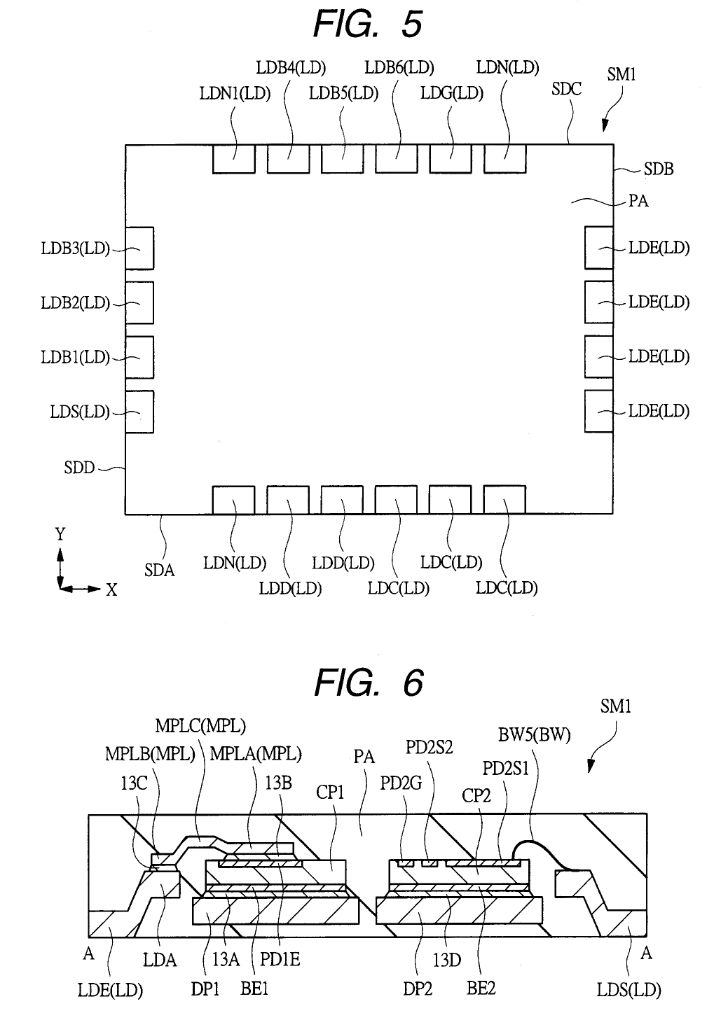

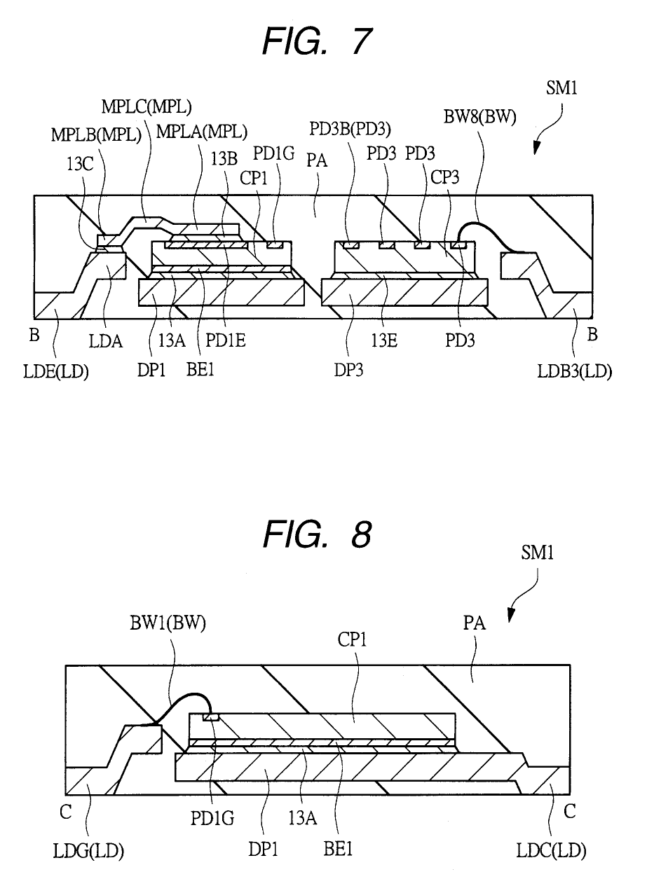

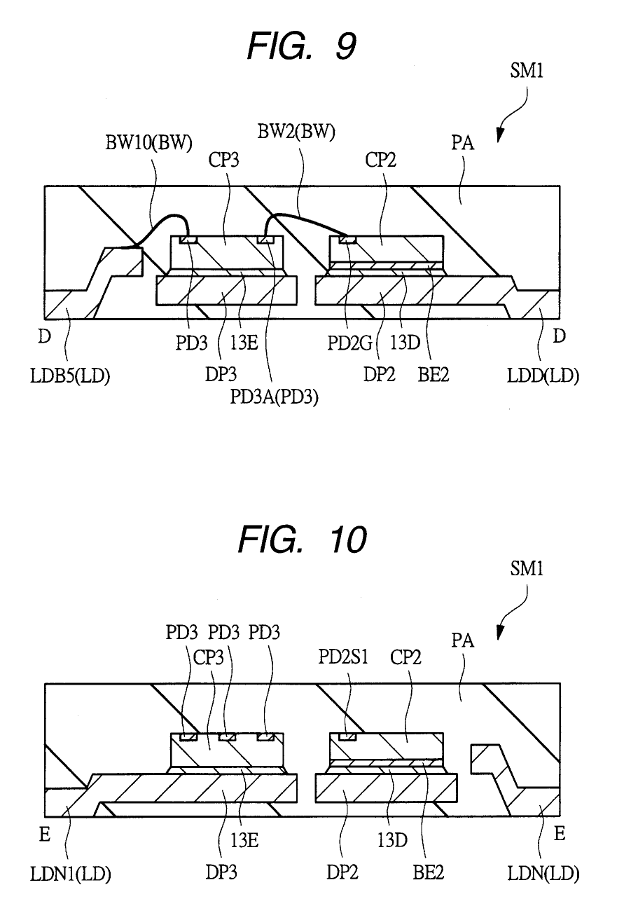

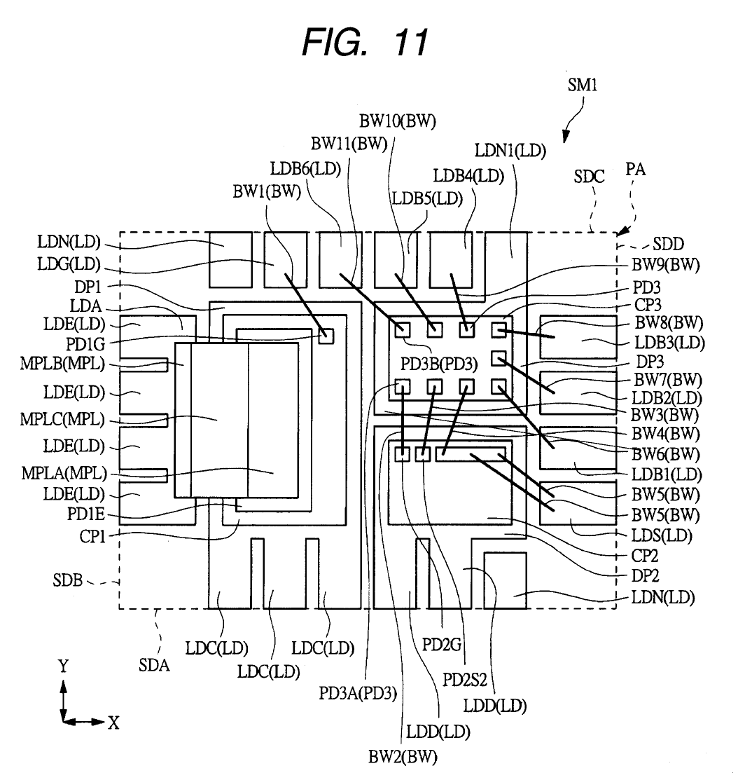

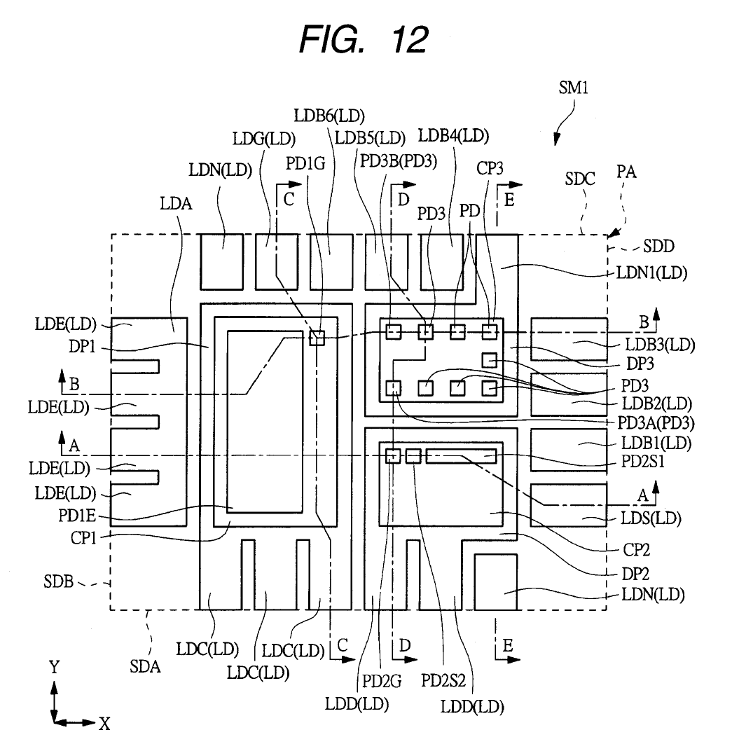

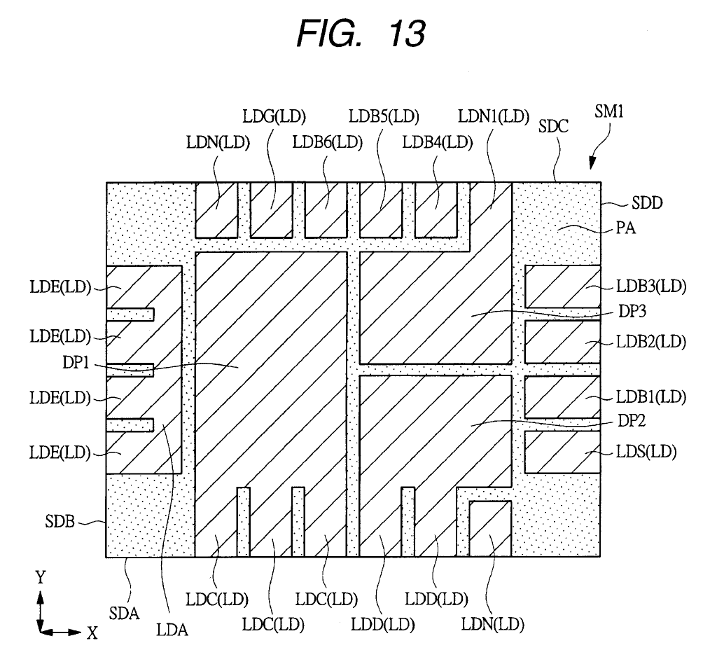

FIG. 4 is a top view of the semiconductor device SM1 in this embodiment; FIG. 5 is a bottom view (back side back view) of the semiconductor device SM1; FIG. 6 to FIG. 10 are sectional views (lateral sectional views) of the semiconductor device SM1; and FIG. 11 is a planar transparent view of the semiconductor device SM1. FIG. 11 shows an overall plan view of the interior of the package PA seen through. FIG. 12 is a planar transparent view of the semiconductor device SM1 in FIG. 11 with a metal plate MPL and wires BW further removed (seen through). FIG. 13 is a planar transparent view of the semiconductor device SM1 in FIG. 12 with the semiconductor chips CP1, CP2, CP3 further removed (seen through). The section of the semiconductor device SM1 taken in the position of line A-A of FIG. 12 substantially corresponds to FIG. 6; the section of the semiconductor device SM1 taken in the position of line B-B of FIG. 12 substantially corresponds to FIG. 7; the section of the semiconductor device SM1 taken in the position of line C-C of FIG. 12 substantially corresponds to FIG. 8; the section of the semiconductor device SM1 taken in the position of line D-D of FIG. 12 substantially corresponds to FIG. 9; and the section of the semiconductor device SM1 taken in the position of line E-E of FIG. 12 substantially corresponds to FIG. 10. Code X shown in each plan view indicates a first direction and code Y indicates a second direction orthogonal to the first direction X. In FIG. 11 and FIG. 12, the position of the outline of the package PA is indicated by broken line. Though FIG. 13 is a plan view, the following measure is taken to facilitate visualization: die pads DP1, DP2, DP3, lead wiring LDA, and leads LD are hatched with oblique lines and the material forming the package PA (resin material) is hatched with dots.

As mentioned above, the semiconductor device SM1 in this embodiment is a semiconductor device comprising at least part of the light emitting device 1. The semiconductor device SM1 includes: the semiconductor chip CP1 in which there is formed the IGBT 2 for the discharge switch (light emission switch, switching element) of the luminescent xenon tube XC; the semiconductor chip CP2 in which there is formed the MOSFET 3 for the charge switch (switching element) of the main capacitor CM for discharging the xenon tube XC; and the semiconductor chip CP3 in which there are formed the drive circuit 4b of the IGBT 2 and the control circuit 4a of the MOSFET 3. The semiconductor chip CP3 can also be considered as a semiconductor chip for controlling (the IGBT 2 in) the semiconductor chip CP1 and (the MOSFET 3 in) the semiconductor chip CP2.

The semiconductor device SM1 in this embodiment includes the surface mount package (sealing body, sealing resin body, sealing resin) PA of, for example, the QFN (Quad Flat Non-leaded package). That is, the package PA comprising the semiconductor device SM1 is a sealing body. In its appearance, the package is a thin plate encircled with a principal surface (upper surface) and a back surface (under surface) positioned on the opposite side to each other along the direction of thickness and a lateral surface intersecting them. The package PA is so formed that the planar shape of each of the principal surface and the back surface is, for example, rectangular.

The material of the package PA (the material of the sealing resin portion) is, for example, epoxy resin. To reduce stress or for any other like purpose, however, biphenyl thermosetting resin added with, for example, phenolic hardening agent, silicone rubber, filler, and the like may be used.

On the peripheries of the lateral surface and back surface of this package PA, multiple leads (lead terminals, external terminals) LD are exposed along the periphery of the package PA. That is, as illustrated in FIG. 5 as well, in the back surface of the package PA, at least part of the under surface of each lead LD is exposed along the periphery (the periphery comprised of sides SDA, SDB, SDC, SDD) and forms an external terminal (terminal for external coupling) of the semiconductor device SM1. When the semiconductor device SM1 is mounted over the circuit board PCB1, the following processing is carried out: the exposed surface of each lead LD in the back surface of the package PA is joined to a terminal of the circuit board PCB1 by a conductive joining material, such as solder, and electrically coupled thereto.

In the package PA, the following are sealed: the three die pads (tabs, chip placement portions) DP1, DP2, DP3; the semiconductor chips CP1, CP2, CP3 placed over the respective principal surfaces (upper surfaces) of the die pads DP1, DP2, DP3; a metal plate (conductor plate) MPL; bonding wires (conductive wires, hereafter, simply referred to as wires) BW; part of multiple leads (lead terminals) LD; and a lead wiring (wiring portion) LDA. That is, the die pads DP1, DP2, DP3, semiconductor chips CP1, CP2, CP3, metal plate MPL, multiple wires BW, lead wiring LDA, and part of multiple leads LD are covered and sealed with the sealing resin (sealing body) comprising the package PA.

The leads LD are placed around (a die pad group comprised of) the die pads DP1, DP2, DP3 and no lead LD is placed between the die pads DP1, DP2, DP3. The leads LD are sealed with the package (sealing body) PA so that part of each of them is exposed from the package PA.

More specific description will be given. As seen from the sectional views in FIG. 6 to FIG. 10, in the package PA, each lead LD is so bent that its portion close to the die pad DP1, DP2, DP3 is lifted. The portion of each lead LD close to the die pad DP1, DP2, DP3 has also its under surface covered with the package PA; and the portion of each lead LD farther from the die pad DP1, DP2, DP3 has its under surface exposed from the back surface of the package PA. As a result, the under surface of part of each lead LD is exposed along the periphery of the back surface of the package PA. Further, it is possible to facilitate coupling of the metal plate MPL or a wire BW and a lead LD (a lead LD to be coupled to the metal plate MPL or a wire BW). Alternatively, it is possible to facilitate joining of the die pad DP1, DP2 and a lead LD (a lead LD to be joined to the die pad DP1 or the die pad DP2).

As seen from FIG. 6 to FIG. 13 as well, the die pads DP1, DP2, DP3 are adjacently placed at predetermined distance in-between. Among the semiconductor chips CP1 to CP3, the semiconductor chip CP1 in which the IGBT 2 is formed is largest (largest in planar dimensions). With this reflected, among the die pads DP1 to DP3, the die pad DP1 over which the semiconductor chip CP1 is placed is largest in planar dimensions (area). The die pads DP1, DP2, DP3 are so placed that the center of each of them is out of alignment with the center of the package PA.

The die pads DP1, DP2, DP3 are so arranged that their sides are positioned along one another as viewed in a plane. As illustrated in FIG. 13 and the like, specifically, the die pad DP1 and the die pads DP2, DP3 are arranged opposite to each other so that the following is implemented: one side of the die pad DP2 and one side of the die pad D3 are positioned along one long side of the die pad DP1. Further, the die pad DP2 and the die pad DP3 are arranged opposite to each other so that the following is implemented: another side of the die pad DP3 intersecting the above one side thereof is positioned along another side of the die pad DP2 intersecting the above one side thereof. The die pad DP1 is a chip placement portion for placing the semiconductor chip CP1; the die pad DP2 is a chip placement portion for placing the semiconductor chip CP2; and the die pad DP3 is a chip placement portion for placing the semiconductor chip CP3. The areas between the die pads DP1, DP2, DP3 are filled with the resin material forming the package PA and the die pads DP1, DP2, DP3 are electrically isolated from one another.

The die pads DP1, DP2, DP3, leads LD, and lead wiring LDA are conductive and are desirably formed using such metal (metal material) as copper (Cu) or (Cu) copper alloy as a chief material. It is more desirable that the die pads DP1, DP2, DP3, leads LD, and lead wiring LDA are formed of the same material. This is because the semiconductor device SM1 including the die pads DP1, DP2, DP3, leads LD, and lead wiring LDA can be manufactured using the same lead frame. Each die pad DP1, DP2, DP3 is so formed that its area is larger than the area of the semiconductor chip CP1, CP2, CP3 placed there and each semiconductor chip CP1, CP2, CP3 is placed so that it is planarly embraced in the corresponding die pad DP1, DP2, DP3.

In the principal surface (upper surface) of each die pad DP1, DP2, DP3, the following measure may be taken: a plating layer (not shown) is provided in each area where each semiconductor chip CP1, CP2, CP3 is to be placed to enhance the stability of junction between each semiconductor chip CP1, CP2, CP3 and the corresponding die pad DP1, DP2, DP3. In the principal surface (upper surface) of the lead wiring LDA, the following measure may be taken: a plating layer (not shown) is provided in an area where the metal plate MPL is to be joined to enhance the stability of junction between the metal plate MPL and the lead wiring LDA. Further, in the principal surface (upper surface) of each lead LD, the following measure may be taken: a plating layer (not shown) is provided in an area where a wire BW is to be bonded to enhance the stability of contact bonding between the wire BW and the lead LD.

In the back surface (under surface) of the package PA, the under surface of each lead LD is exposed. It is desirable that after the formation of the package PA, a plating layer (not shown) such as a solder plating layer should have been formed over the under surface of each lead LD exposed in the back surface of the package PA. This makes it easier to mount the semiconductor device SM1 over the circuit board PCB1 or the like.

As seen from FIG. 13 as well, the die pad DP1 is formed in rectangular planar shape so that its length in the second direction Y is larger than its length in the first direction X. To one side (side along the side SDA of the package PA) of the die pad DP1, multiple leads LDC of the above multiple leads LD are integrally coupled along the one side. That is, the die pad DP1 and the multiple leads LDC are integrally formed.

As illustrated in FIG. 6 to FIG. 8, FIG. 11, and FIG. 12, the semiconductor chip CP1 for the IGBT 2 is placed over the principal surface (upper surface) of this die pad DP1 so that the following is implemented: its principal surface (front surface, upper surface) faces upward and its back surface (under surface, back surface electrode BE1 formation surface) faces toward the die pad DP1. The semiconductor chip CP1 is formed in a rectangular planar shape and is so placed that the long sides of the semiconductor chip CP1 are positioned along the direction of length of the die pad DP1. In conjunction with light emission (discharge) of the xenon tube XC, a larger current is passed through the semiconductor chip CP1 than through the semiconductor chips CP2, CP3. For this reason, the plane area of the semiconductor chip CP1 is larger than the plane area of each of the semiconductor chips CP2, CP3 and the long sides and short sides of the semiconductor chip CP1 are respectively longer than the long sides and short sides of each of the semiconductor chips CP2, CP3.

As illustrated in FIG. 6 to FIG. 8, in the back surface (under surface) of the semiconductor chip CP1, there is formed the back surface electrode (back surface collector electrode) BE1. This back surface electrode BE1 of the semiconductor chip CP1 is joined and fixed to the die pad DP1 through a conductive adhesive layer 13A and is electrically coupled thereto. The back surface electrode BE1 is formed throughout the back surface of the semiconductor chip CP1. The back surface electrode BE1 of the semiconductor chip CP1 is electrically coupled to the collector of the IGBT 2 formed in the semiconductor chip CP1. That is, the back surface electrode BE1 of the semiconductor chip CP1 corresponds to the collector electrode (back surface collector electrode) of the IGBT 2. To electrically couple the back surface electrode BE1 of the semiconductor chip CP1 to the die pad DP1, the adhesive layer 13A used to join the semiconductor chip CP1 to the die pad DP1 must be conductive. For this reason, such conductive paste adhesive as silver paste, solder, or the like can be used as the material of the adhesive layer 13A.

The above leads LDC are electrically coupled to the back surface electrode BE1 of the semiconductor chip CP1 (that is, the collector of the IGBT 2) through the die pad DP1 and the conductive adhesive layer 13A. Therefore, it is a lead terminal for the collector of the IGBT 2, which lead terminal should be coupled to (one internal electrode of) the xenon tube XC and the trigger coil LTR.

At least one lead LDC is provided for the collector; however, provision of multiple leads LDC makes it possible to reduce the resistance component and is more desirable. The following can be implemented by providing multiple leads LDC for the collector of the IGBT 2 and integrally coupling these leads LDE to the die pad DP1: it is possible to reduce the resistance component and enhance the light emission efficiency of the xenon tube XC.

As illustrated in FIG. 6 to FIG. 8, FIG. 11, and FIG. 12, the principal surface (front surface, upper surface) of the semiconductor chip CP1 is provided with the following: a pad electrode (bonding pad) PD1G for gate and a pad electrode (bonding pad) PD1E for emitter. The pad electrode PD1G for gate is an electrode (pad electrode, electrode pad, bonding pad) for bonding a wire BW; and the pad electrode PD1E for emitter is an electrode (pad electrode, electrode pad, bonding pad) for coupling the metal plate MPL.

The pad electrode PD1G for gate of the semiconductor chip CP1 is electrically coupled to the gate (gate electrode) of the IGBT 2 formed in the semiconductor chip CP1. That is, the pad electrode PD1G of the semiconductor chip CP1 corresponds to the pad electrode (bonding pad) for the gate of the IGBT 2. This pad electrode PD1G for gate is placed in proximity to a corner at an end of the semiconductor chip CP1 in the direction of its length. The semiconductor chip CP1 is placed with the pad electrode PD1G for gate facing toward the side SDC of the package PA. As illustrated in FIG. 8 and FIG. 11, the pad electrode PD1G for gate of the semiconductor chip CP1 is electrically coupled with the lead LDG of the multiple leads LD through (a single or multiple) wires BW1 of the multiple wires BW. That is, one end of the wire BW1 is bonded to the pad electrode PD1G for gate of the semiconductor chip CP1 and the other end of the wire BW1 is bonded to the lead LDG. The wires BW are a conductive member, have conductivity, and are formed of a metal small-gage wire of, for example, gold (Au).

The pad electrode PD1E for emitter of the semiconductor chip CP1 is electrically coupled to the emitter of the IGBT 2 formed in the semiconductor chip CP1. That is, the pad electrode PD1E for emitter of the semiconductor chip CP1 corresponds to the pad electrode (bonding pad) for the emitter of the IGBT 2. The pad electrode PD1E for emitter is larger than the pad electrode PD1G for gate and is formed in the shape of a rectangle extended along the direction (the second direction Y in this example) of length of the semiconductor chip CP1.

As illustrated in FIG. 6, FIG. 7, and FIG. 11 as well, the pad electrode PD1E for emitter of the semiconductor chip CP1 (that is, the emitter of the IGBT 2) is electrically coupled with the lead wiring LDA through the metal plate MPL. Specifically, one end of the metal plate MPL is joined to the pad electrode PD1E for emitter of the semiconductor chip CP1 through a conductive adhesive layer 13B and electrically coupled thereto; and the other end of the metal plate MPL is joined to the principal surface (upper surface) of the lead wiring LDA through a conductive adhesive layer 13C and electrically coupled thereto. The adhesive layers 13B, 13C used to join the metal plate MPL must be conductive and such conductive paste adhesive as silver paste, solder, or the like can be used for this purpose.

The lead wiring LDA is placed away from and adjacently to the die pad DP1 along one side of the die pad DP1 (the side on the opposite side to the side opposed to the die pads DP2, DP3). The area between the lead wiring LDA and the die pad DP1 is filled with the resin material comprising the package PA and the lead wiring LDA and the die pad DP1 are electrically isolated from each other. Some leads LDE of the multiple leads LD are integrally coupled to the lead wiring LDA. That is, the lead wiring LDA and the leads LDE are integrally formed. As mentioned above, the leads LDE are electrically coupled to the pad electrode PD1E for emitter of the semiconductor chip CP1 (that is, the emitter of the IGBT 2) through the lead wiring LDA, adhesive layers 13B, 13C, and metal plate MPL. Therefore, the lead wiring LDA and the leads LDE formed integrally thereon are lead terminals for the emitter of the IGBT 2, which lead terminals should be coupled to (one electrode of) the main capacitor CM.

As least one lead LDE is provided for the emitter; however, provision of multiple leads LDS makes it possible to reduce the resistance component and is more desirable. The following can be implemented by providing multiple leads LDE for the emitter of the IGBT 2 and coupling these leads LDE to the lead wiring LDA in a lump: the volume can be increased as compared with cases where multiple leads LDE are divided (separated) from one another. Therefore, it is possible to reduce the wiring resistance and enhance the light emission efficiency of the xenon tube XC.

The metal plate MPL is a conductive member and is formed of a metal having high conductivity and thermal conductivity, such as copper (Cu), copper (Cu) alloy, aluminum (Al), and aluminum (Al) alloy. Use of the metal plate MPL brings about the following advantage: it possible to enhance resistance to a large current passed in conjunction with light emission (discharge) of the xenon tube XC as compared with cases where the pad electrode PD1E for emitter and the lead wiring LDA are coupled together through multiple wires; and it is possible to reduce the resistance component and thus enhance the light emission efficiency of the xenon tube XC. The following advantage is also brought about by using the metal plate MPL formed of a metal material more inexpensive than gold, instead of using multiple wires formed of gold (Au): the cost of the semiconductor device SM1 can be reduced. The dimensions (widths) of the metal plate MPL in the first direction X and the second direction Y are both larger than the diameter of the wire BW.

The metal plate MPL integrally includes the first portion MPLA, second portion MPLB, and third portion MPLC described below.

The first portion (chip contact portion) MPLA is joined with the pad electrode PD1E for emitter of the semiconductor chip CP1 through the conductive adhesive layer 13B and is formed, for example, in a rectangular planar shape. As illustrated in FIG. 6 and FIG. 7, the first portion MPLA is formed flat along the principal surface (upper surface) of the semiconductor chip CP1 as viewed in a section.

The second portion (lead contact portion) MPLB is joined with the lead wiring LDA through the conductive adhesive layer 13C. The second portion MPLB planarly overlaps with part of the lead wiring LDA. As illustrated in FIG. 6 and FIG. 7, the second portion MPLB is formed flat along the principal surface (upper surface) of the lead wiring LDA as viewed in a section.

The metal plate MPL may be joined by, for example, ultrasonic joining, not by the adhesive layers 13B, 13C. This is the same with the following modifications and embodiments.

The third portion (intermediate portion) MPLC joins (couples) the first portion MPLA and the second portion MPLB together. As illustrated in FIG. 6 and FIG. 7, the third portion MPLC is so formed that the following is implemented: it is higher than the first portion MPLA and the second portion MPLB between the semiconductor chip CP1 and the lead wiring LDA so that it gets away from the principal surface (upper surface) of the semiconductor chip CP1 as viewed in a section. This makes the material of the adhesive layer 13B less prone to leak toward the lateral surface of the semiconductor chip CP1. Therefore, it is possible to reduce failure in continuity between the principal surface (the pad electrode PD1E for emitter) and the back surface (the back surface electrode BE1 for collector) of the semiconductor chip CP1, caused by the adhesive layer 13B.

Further, it is desirable to take the following measure: the area of the first portion MPLA of the metal plate MPL is made smaller than the area of the principal surface of the semiconductor chip CP1 or the total area of the placement region of the pad electrode PD1E for emitter; and the metal plate MPL is so placed that its first portion MPLA fits within the principal surface of the semiconductor chip CP1 and does not lie out of the semiconductor chip CP1. This makes it possible to prevent the material of the adhesive layer 13B from leaking toward the lateral surface of the semiconductor chip CP1. Therefore, it is possible to reduce failure in continuity between the principal surface (the pad electrode PD1E for emitter) and the back surface (the back surface electrode BE1 for collector) of the semiconductor chip CP1, caused by the material of the adhesive layer 13B.

As seen from FIG. 13 as well, the die pad DP2 is formed in a rectangular planar shape with its length in the first direction X larger than its length in the second direction Y. To one side of the die pad DP2 (the side positioned along the side SDA of the package PA), some leads LDD of the multiple leads LD are integrally coupled along the side. That is, the die pad DP2 and the leads LDD are integrally formed.

As illustrated in FIG. 6 and FIG. 9 to FIG. 12, the semiconductor chip CP2 for the MOSFET 3 is placed over the principal surface (upper surface) of this die pad DP2 so that the following is implemented: its principal surface (front surface, upper surface) faces upward and its back surface (under surface, back surface electrode BE2 formation surface) faces toward the die pad DP2. The semiconductor chip CP2 is formed in a rectangular planar shape and is so placed that the long sides of the semiconductor chip CP2 are positioned along the direction of length of the die pad DP2.

As illustrated in FIG. 6, FIG. 9, and FIG. 10, a back surface electrode (back surface drain electrode) BE2 is formed in the back surface of the semiconductor chip CP2. This back surface electrode (back surface drain electrode) BE2 of the semiconductor chip CP2 is joined and fixed to the die pad DP2 through a conductive adhesive layer 13D and electrically coupled thereto. This back surface electrode BE2 is formed throughout the back surface of the semiconductor chip CP2. The back surface electrode BE2 of the semiconductor chip CP2 is electrically coupled to the drain of the MOSFET 3 formed in the semiconductor chip CP2. That is, the back surface electrode BE2 of the semiconductor chip CP2 corresponds to the drain electrode (back surface drain electrode) of the MOSFET 3. To electrically couple the back surface electrode BE2 of the semiconductor chip CP2 to the die pad DP2, the adhesive layer 13D used to join the semiconductor chip CP2 to the die pad DP2 must be conductive. Such conductive paste adhesive as silver paste, solder, or the like can be used as the material of the adhesive layer 13D.

The leads LDD are electrically coupled to the back surface electrode BE2 of the semiconductor chip CP2 (that is, the drain of the MOSFET 3) through the die pad DP2 and the conductive adhesive layer 13D. Therefore, it is a lead terminal for the drain of the MOSFET 3, which lead terminal should be coupled to (one end of the primary coil of) the step-up transformer TS. At least one lead LDD is provided for the drain; however, provision of multiple leads LDD makes it possible to reduce the resistance component and is more desirable.

As illustrated in FIG. 6 and FIG. 9 to FIG. 12, the principal surface (front surface, upper surface) of the semiconductor chip CP2 is provided with a pad electrode (bonding pad) PD2G for gate and pad electrodes (bonding pads) PD2S1, PD2S2 for source. The pad electrode PD2G for gate and the pad electrodes PD2S1, PD2S2 for source are electrodes (pad electrodes, electrode pads, bonding pads) for bonding wires BW.

The pad electrode PD2G for gate of the semiconductor chip CP2 is electrically coupled to the gate (gate electrode) of the MOSFET 3 formed in the semiconductor chip CP2. That is, the pad electrode PD2G for gate of the semiconductor chip CP2 corresponds to the pad electrode (bonding pad) for the gate of the MOSFET 3. This pad electrode PD2G for gate is placed along the side closer to the semiconductor chip CP3 placed over the die pad DP3 in the principal surface (upper surface) of the semiconductor chip CP2. The pad electrode PD2G for gate of the semiconductor chip CP2 is electrically coupled to the pad electrode PD3 of the semiconductor chip CP3 placed over the die pad DP3 through (a single or multiple) wires BW2 of the multiple wires BW. (Specifically, the pad electrode PD2G is electrically coupled to the pad electrode PD3A of the multiple pad electrodes PD3 provided in the semiconductor chip CP3.) That is, the other end of the wire BW2 one end of which is bonded to the pad electrode PD2G for gate of the semiconductor chip CP2 is bonded to a pad electrode PD3 of the semiconductor chip CP3, not to a lead LD. (Specifically, the other end of the wire BW2 is bonded to the pad electrode PD3A.)

The pad electrodes PD2S1, PD2S2 for source of the semiconductor chip CP2 are electrically coupled to the source of the MOSFET 3 formed in the semiconductor chip CP2. That is, the pad electrodes PD2S1, PD2S2 for source of the semiconductor chip CP2 correspond to pad electrodes (bonding pads) for the source of the MOSFET 3.

The pad electrode PD2S1 for source of the semiconductor chip CP2 is electrically coupled to the lead LDS of the multiple lead LD through (a single or multiple) wires BW5 of the multiple wires BW. Further, it is electrically coupled to the pad electrode PD3 of the semiconductor chip CP3 placed over the die pad DP3 through (a single or multiple) wires BW4 of the multiple wires BW. That is, the pad electrode PD2S1 for source is formed long along a side of the semiconductor chip CP2 in the principal surface (upper surface) of the semiconductor chip CP2; therefore, multiple wires BW can be bonded to this pad electrode PD2S1. The multiple wires BW bonded to the pad electrode PD2S1 include at least one wire 5 bonded to the lead LDS and at least one wire BW4 bonded to the pad electrode PD3 of the semiconductor chip CP3. The pad electrode PD2S2 for source of the semiconductor chip CP2 is electrically coupled with a pad electrode PD3 of the semiconductor chip CP3 placed over the die pad DP3 through (a single or multiple) wires BW3 of the multiple wires BW.

The pad electrodes PD2S1, PD2S2 for source of the semiconductor chip CP2 are separated from each other by the protective film in the uppermost layer of the semiconductor chip CP2. However, they are integrally formed and electrically coupled with each other under the protective film (the protective film in the uppermost layer of the semiconductor chip CP2). Consequently, the other end of the wire BW5 one end of which is bonded to the lead LDS is bonded to the pad electrode PD2S1 for source of the semiconductor chip CP2, not to the pad electrode PD2S2 for source of the semiconductor chip CP2. Not only the pad electrode PD2S1 for source of the semiconductor chip CP2 but also the pad electrode PD2S2 for source is electrically coupled with the lead LDS.

The lead wiring LDS is electrically coupled to the pad electrodes PD2S1, PD2S2 for source of the semiconductor chip CP2 (that is, the source of the MOSFET 3) through the wire BW5. Therefore, the lead LDS is a lead terminal for the source of the MOSFET 3, which lead terminal should be coupled to ground potential (reference potential, GND potential, grounding potential).

As another embodiment, formation of the pad electrode PD2S2 for source and placement of the wire BW3 may be omitted in the semiconductor chip CP2. As further another embodiment, placement of the wire BW4 may be omitted. In this case, the pad electrode PD2S1 for source of the semiconductor chip CP2 is coupled only to the lead LDS through (a single or multiple) wires BW5; and the pad electrode PD2S2 for source of the semiconductor chip CP2 is coupled only to the pad electrode PD3 of the semiconductor chip CP3 through (a single or multiple) wires BW3. However, the pad electrode PD2S1 and the pad electrode PD2S2 can be integrally formed and electrically coupled with each other under the protective film in the uppermost layer of the semiconductor chip CP2. At least one lead LDS is provided for the source; however, provision of multiple leads LDS makes it possible to reduce the resistance component.

As seen from FIG. 13 as well, the die pad DP3 is formed in a rectangular planar shape with its length in the first direction X longer than its length in the second direction Y. To one side of the die pad DP3 (the side positioned along the side SDC of the package PA in this example), the lead LDN1 of the multiple leads LD is integrally coupled along the side. That is, the die pad DP3 and the lead LDN1 are integrally formed.

As illustrated in FIG. 7 and FIG. 9 to FIG. 12, the semiconductor chip CP3 for the control circuit 4a and the drive circuit 4b is placed over the principal surface (upper surface) of this die pad DP3 so that the following is implemented: its principal surface (front surface, upper surface) faces upward and its back surface (under surface) faces toward the die pad DP3. This semiconductor chip CP3 is formed in a rectangular planar shape and is so placed that the long sides of the semiconductor chip CP3 are positioned along the direction of length of the die pad DP3.

As illustrated in FIG. 7, FIG. 9, and FIG. 10, the semiconductor chip CP3 is joined and fixed to the die pad DP3 through an adhesive layer 13E. Since no electrode (back surface electrode) is formed in the back surface of the semiconductor chip CP3, it is unnecessary to electrically couple the back surface of the semiconductor chip CP3 to the die pad DP3. For this reason, the adhesive layer 13E used to join the semiconductor chip CP3 to the die pad DP3 need not be conductive and whichever adhesive, conductive adhesive or insulative adhesive, can be used. Therefore, such conductive paste adhesive as silver paste, solder, insulative adhesive, or the like can be used as the material of the adhesive layer 13E. However, when the same material (adhesive) is used for the adhesive layers 13A, 13D, 13E for respectively joining the semiconductor chips CP1, CP2, CP3 to the die pads DP1, DP2, DP3, the manufacturing process for the semiconductor device SM1 can be simplified. Therefore, that is desirable. In this case, the adhesive layer 13E is also provided with conductivity in agreement with the adhesive layers 13A, 13D.

As illustrate in FIG. 7 and FIG. 9 to FIG. 12, the principal surface (front surface, upper surface) of the semiconductor chip CP3 is provided with multiple pad electrodes (bonding pads) PD3. The pad electrodes PD3 of the semiconductor chip CP3 are electrically coupled to circuits (including the control circuit 4a and the drive circuit 4b) formed in the semiconductor chip CP3.

The pads PD3 of the semiconductor chip CP3 include the pad electrode PD3 (that is, the pad electrode PD3A) electrically coupled to the pad electrode PD2G for gate of the semiconductor chip CP2 through the wire BW2. Further, the pads PD3 of the semiconductor chip CP3 include the following: the pad electrode PD3 electrically coupled to the pad electrode PD2S2 for source of the semiconductor chip CP2 through the wire BW3; and the pad electrode PD3 electrically coupled to the pad electrode PD2S1 for source of the semiconductor chip CP2 through the wire BW4. Further, the pads PD3 of the semiconductor chip CP3 also include pad electrodes PD3 respectively electrically coupled to the leads LDB1, LDB2, LDB3, LDB4, LDB5, LDB6 of the multiple leads LD through wires BW6, BW7, BW8, BW9, BW10, BW11 of the multiple wires BW. The area between the leads LDB1, LDB2, LDB3, LDB4, LDB5, LDB6 and the die pad DP3 is filled with the resin material comprising the package PA; and the leads LDB1, LDB2, LDB3, LDB4, LDB5, LDB6 and the die pad DP3 are electrically isolated from each other.

The lead LDB1 is a lead terminal for inputting a charge start control signal (a signal controlling the start of charging of the main capacitor CM) to (the control circuit 4a in) the semiconductor chip CP3. The lead LDB2 is a lead terminal (open drain) for outputting a charge completion detection signal (a signal indicating that completion of charging of the main capacitor CM has been detected). The lead LDB3 is a lead terminal for inputting a charging current control signal (a signal controlling the charging current of the main capacitor CM through the step-up transformer TS). The lead LDB4 is a lead terminal for inputting supply voltage (power supply potential, fixed potential) VCC. The lead LDB5 is a lead terminal for inputting an IGBT driving signal (a signal controlling the IGBT 2 into on state) to (the drive circuit 4b in) the semiconductor chip CP3. The lead LDB6 is a lead terminal for outputting IGBT driving voltage (driving voltage to be applied to the gate of the IGBT 2 to turn on the IGBT 2).

Of the pad electrodes PD3 of the semiconductor chip CP3, the pad electrode PD3 electrically coupled to the pad electrode PD2G for gate of the semiconductor chip CP2 through (a single or multiple) wires BW2 will be marked with code PD3A and be designated as pad electrode PD3A. This pad electrode PD3A of the semiconductor chip CP3 is electrically coupled to the control circuit 4a formed in the semiconductor chip CP3. Driving voltage to be applied to the gate of the MOSFET 3 to turn on the MOSFET 3 is outputted from the pad electrode PD3A of the semiconductor chip CP3 by the control circuit 4a in the semiconductor chip CP3. Then it is inputted to the pad electrode PD2G for gate of the semiconductor chip CP2 through the wire BW2 and applied to the gate electrode of the MOSFET 3 formed in the semiconductor chip CP2.

Of the pad electrodes PD3 of the semiconductor chip CP3, the pad electrode PD3 electrically coupled to the lead LDB6 through (a single or multiple) wires BW11 will be marked with code PD3B and be designated as pad electrode PD3B. This pad electrode PD3B of the semiconductor chip CP3 is electrically coupled to the drive circuit 4b formed in the semiconductor chip CP3. When an IGBT driving signal is inputted from the lead LDB5 to the drive circuit 4b in the semiconductor chip CP3 through the wire BW10, the following takes place: driving voltage to be applied to the gate of the IGBT 2 to turn on the IGBT 2 is generated at the drive circuit 4b in the semiconductor chip CP3 and outputted from the pad electrode PD3B of the semiconductor chip CP3; and further, it is outputted from the lead LDB6 to outside the semiconductor device SM1 by way of the wire BW11. The driving voltage (the driving voltage of the IGBT 2) outputted from the lead LDB6 to outside the semiconductor device SM1 is inputted again from the lead LDG to the semiconductor device SM1 by way of the wiring in the circuit board PCB1 and the like. Further, it is inputted to the pad electrode PD1G for gate of the semiconductor chip CP1 by way of the wire BW1. The resistor R1 is provided between the lead LDB6 and the lead LDG outside the semiconductor device SM1 and is comprised of, for example, the wiring of the circuit board PCB1, a passive component placed over the circuit board PCB1, or the like.

The pad electrodes PD3 respectively coupled to the leads LDB1, LDB2, LDB3 through the wires BW6, BW7, BW8 are so arranged that the following is implemented in the principal surface (upper surface) of the semiconductor chip CP3: they are placed along the side on the (opposite) side closer to the side SDD of the package PA on which the leads LDB1, LDB2, LDB3 are placed. The pad electrodes PD3 (including the pad electrode PD3B) respectively coupled to the leads LDB4, LDB5, LDB6 through the wires BW9, BW10, BW11 are so arranged that the following is implemented in the principal surface (upper surface) of the semiconductor chip CP3: they are placed along the side on the (opposite) side closer to the side SDC of the package PA on which the leads LDB4, LDB5, LDB6 are placed. The pad electrodes PD3 (including the pad electrode PD3A) respectively coupled to the pad electrodes PD2S1, PD2S2, PD2G of the semiconductor chip CP2 through the wires BW4, BW3, BW2 are arranged as described below. They are placed along the side on the (opposite) side closer to the semiconductor chip CP2 placed over the die pad DP2 in the principal surface (upper surface) of the semiconductor chip CP3.

None of the pad electrodes PD3 of the semiconductor chip CP3 is electrically coupled to the lead LDN1 integrally coupled to the die pad DP3. Therefore, the lead LDN1 can be considered as a lead LD that is not electrically coupled to any electrode of the semiconductor chips CP1, CP2, CP3 (that is, a non-contact lead).

This lead LDN1 is provided in coupling with the die pad DP3 so that the die pad DP3 can be kept held or fixed until the package PA is formed. When the leads LDC, LDD, LDN1 are coupled to (the frame of) a lead frame for the manufacture of the semiconductor device SM1, the die pads DP1, DP2, DP3 can be held on the lead frame during the manufacture of the semiconductor device SM1. Therefore, the semiconductor device SM1 can be manufactured using a lead frame. The lead LDN1 is an unnecessary lead in terms of electricity. Therefore, it may be different from the other leads LD in shape and the lead LDN1 may be formed as a so-called suspended lead. The number of leads LDN1 coupled to the die pad DP3 may be one or more. However, it is desirable that the number of leads LDN1 should be reduced to the extent that the die pad DP3 can be fixed or held so that the leads LDB1 to LDB6 can be easily arranged around the die pad DP3. It is unnecessary to provide the lead LDN1 integrally coupled to the die pad DP3 as long as the semiconductor device SM1 can be manufactured without the lead LDN1 coupled to the die pad DP3. In case where no lead LDN1 integrally coupled to the die pad DP3 is provided, for example, the following measure can be taken: the lead LDB4 is placed in the position of the lead LDN1 in FIG. 13; the lead LDB5 is placed in the position of the lead LDB4 in FIG. 13; the lead LDB6 is placed in the position of the lead LDB5 in FIG. 13; the lead LDG is placed in the position of the lead LDB6 in FIG. 13; and a non-contact lead LDN is placed in the position of the lead LDG in FIG. 13. As illustrated in FIG. 13 as well, however, the following advantages can be brought about by integrally coupling the lead LDN1 to the die pad DP3: the die pad DP3 can be easily kept held or fixed until the package PA is formed and this facilitates the manufacture of the semiconductor device SM1; and the semiconductor device SM1 can be manufactured using a lead frame. As a result, a structure in which the die pad DP1, DP2, or DP3 is not exposed in the back surface of the package PA can be easily achieved.

<Relation of Coupling of Leads of Semiconductor Device>

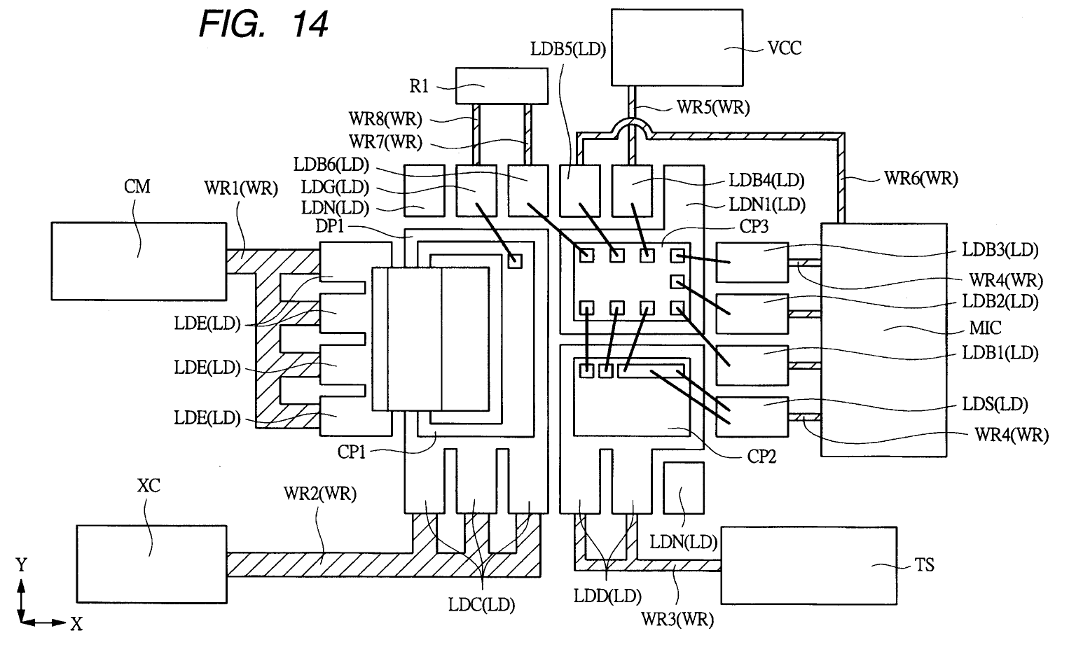

Description will be given to the relation of coupling of the individual leads LD of the semiconductor device SM1 with reference to FIG. 14. FIG. 14 is an explanatory drawing of the light emitting device 1. FIG. 14 schematically illustrates the wiring WR of the circuit board PCB1 coupled to each lead LD and components over the circuit board PCB1 superimposed on the same planar transparent view as in FIG. 11. (In this example, the above components over the circuit board PCB1 include the main capacitor CM, the xenon tube XC, the step-up transformer TS, a microcomputer MIC, and the resistor R1) Though FIG. 14 is a plan view, the wiring WR of the circuit board PCB1 is hatched in FIG. 14 to facilitate visualization. The wiring WR of the circuit board PCB1 includes the wirings WR1, WR2, WR3, WR4, WR5, WR6, WR7, WR8 described below. In FIG. 14, the main capacitor CM, xenon tube XC, step-up transformer TS, microcomputer MIC, and resistor R1 are schematically shown by rectangular blocks. The source or supply terminal of power supply potential (fixed potential) VCC is also schematically shown by rectangular block marked with code VCC.

As seen from FIG. 5, FIG. 11 to FIG. 13, and FIG. 14, the multiple leads LDE are arranged along the side SDB in the back surface of the package PA comprising the semiconductor device SM1. As mentioned above, these leads LDE are electrically coupled to the emitter of the IGBT 2 formed in the semiconductor chip CP1 through the metal plate MPL and the like. As seen from FIG. 14 as well, these leads LDE are soldered to (the terminal portion of) the wiring WR1 of the circuit board PCB1. They are electrically coupled to the main capacitor CM (specifically, one electrode of the main capacitor CM) placed over the circuit board PCB1 through this wiring WR1.

The multiple leads LDC, LDD, LDN are arranged along the side SDA in the back surface of the package PA comprising the semiconductor device SM1. Of these leads, the multiple leads LDC are electrically coupled to the collector of the IGBT 2 formed in the semiconductor chip CP1. As seen from FIG. 14 as well, these leads LDC are soldered to (the terminal portion of) the wiring WR2 of the circuit board PCB1. They are electrically coupled to the xenon tube XC (specifically, one internal electrode of the xenon tube XC) placed over the circuit board PCB1 through this wiring WR2. Of the above leads, as mentioned above, the multiple leads LDD are electrically coupled to the drain of the MOSFET 3 formed in the semiconductor chip CP2. As seen from FIG. 14 as well, these leads LDD are soldered to (the terminal portion of) the wiring WR3 of the circuit board PCB1. They are electrically coupled to the step-up transformer TS (specifically, one end of the primary coil of the step-up transformer TS) placed over the circuit board PCB1 through this wiring WR3.

Of the leads LDC, LDD, LDN arranged along the side SDA, the lead LDN is not electrically coupled to a pad electrode or back surface electrode of any of the semiconductor chips CP1, CP2, CP3 and is an unnecessary lead LD in terms of electricity. That is, not only the leads LDC, LDD are arranged on the side SDA in the back surface of the package PA comprising the semiconductor device SM1; the lead LDN that is not electrically coupled with an electrode of any of the semiconductor chips CP1, CP2, CP3 is also placed. For this reason, this lead LDN is not coupled (soldered) to the wiring WR of the circuit board PCB1. Alternatively, if the lead LDN is coupled to the wiring WR, any component (component placed over the circuit board PCB) is not electrically coupled to the wiring WR.

In the following description, a lead LD (the leads LDN, LDN1 in this example) that is not electrically coupled to an electrode of any of the semiconductor chips CP1, CP2, CP3 may be designated as non-contact lead for the sake of simplicity.

The multiple leads LDS, LDB1, LDB2, LDB3 are arranged along the side SDD in the back surface of the package PA comprising the semiconductor device SM1. As mentioned above, the lead LDS is electrically coupled to the source of the MOSFET 3 formed in the semiconductor chip CP2; and the leads LDB1, LDB2, LDB3 are respectively electrically coupled to pad electrodes PD3 of the semiconductor chip CP3 through the wires BW6, BW7, BW8. As seen from FIG. 14 as well, these leads LDS, LDB1, LDB2, LDB3 are soldered to (the terminal portions of) the wirings WR4 of the circuit board PCB1. They are electrically coupled to the microcomputer MIC (specifically, the respective terminals of the microcomputer MIC) placed over the circuit board PCB1 through these wirings WR4.

The multiple leads LDN1, LDB4, LDB5, LDB6, LDG, LDN are arranged along the side SDC in the back surface of the package PA comprising the semiconductor device SM1. Of these leads, as mentioned above, the lead LDB4 is electrically coupled to a pad electrode PD3 of the semiconductor chip CP3 through the wire BW9. As seen from FIG. 14 as well, it is soldered to (the terminal portion of) the wiring WR5 of the circuit board PCB1 and is electrically coupled to the power supply potential (fixed potential) VCC through this wiring WR5. Of the above leads, as mentioned above, the lead LDB5 is electrically coupled to a pad electrode PD3 of the semiconductor chip CP3 through the wire BW10. As seen from FIG. 14 as well, it is soldered to (the terminal portion of) the wiring WR6 of the circuit board PCB1 and is electrically coupled to the microcomputer MIC through this wiring WR6. In FIG. 14, the wiring WR5 and the wiring WR6 are depicted so that they intersect each other. In reality, however, the circuit board PCB1 is formed of a multilayer circuit board and the wiring WR5 and the wiring WR6 intersect each other in different wiring layers; therefore, the wiring WR5 and the wiring WR6 are not short-circuited to each other.

Of the above leads, as mentioned above, the lead LDB6 is electrically coupled to the pad electrode PD3B of the semiconductor chip CP3 through the wire BW11; and the lead LDG is electrically coupled to the gate of the IGBT 2 formed in the semiconductor chip CP1 through the wire BW1. As seen from FIG. 14 as well, these leads LDB6, LDG are respectively soldered to (the terminal portions of) the wirings WR7, WR8 of the circuit board PCB1. They are respectively coupled to the ends of the resistor R1 through these wirings WR7, WR8. In this case, the resistor R1 placed between the lead LDB6 and the lead LDG is formed of the wiring WR of the circuit board PCB1, a passive component (resistance element) placed over the circuit board PCB1, or the like.

Of the leads LDN1, LDB4, LDB5, LDB6, LDG, LDN arranged along the side SDC, the lead LDN1 or LDN is not electrically coupled to a pad electrode or back surface electrode of any of the semiconductors chip CP1, CP2, CP3; therefore, they are unnecessary leads LD in terms of electricity. That is, not only the leads LDB4, LDB5, LDB6, LDG are arranged on the side SDC in the back surface of the package PA comprising the semiconductor device SM1; the leads LDN1, LDN neither of which is electrically coupled with an electrode of any of the semiconductor chips CP1, CP2, CP3 are also placed. The lead LDN1 is integrally coupled with the die pad DP3 and the lead LDN is not coupled with any of the die pads DP1, DP2, DP3. Similarly with the lead LDN, the lead LDN1 is not electrically coupled with an electrode of any of the semiconductor chips CP1, CP2, CP3, either. Therefore, not only the lead LDN but also the lead LDN1 can be considered as a non-contact lead. The lead LDN or LDN1 is not coupled (soldered) to the wiring WR of the circuit board PCB1. Alternatively, if the leads LDN, LDN1 are coupled to the wiring WR, any component (component placed over the circuit board PCB1) is not electrically coupled to the wiring WR.

Because of this relation of coupling, a charge start control signal is inputted from the microcomputer MIC to the lead LDB1 of the semiconductor device SM1 and is inputted to (the control circuit 4a in) the semiconductor chip CP3 through the wire BW6. A charge completion detection signal for the main capacitor CM outputted from the semiconductor chip CP3 is outputted from the lead LDB2 of the semiconductor device SM1 through the wire BW7 and is inputted to the microcomputer MIC. A charging current control signal is inputted from the microcomputer MIC to the lead LDB3 of the semiconductor device SM1 and is inputted to (the control circuit 4a in) the semiconductor chip CP3 through the wire BW8. Supply voltage VCC is inputted to the lead LDB4 of the semiconductor device SM1 and is inputted to (the control circuit 4a and the drive circuit 4b in) the semiconductor chip CP3 through the wire BW9. An IGBT driving signal is inputted from the microcomputer MIC to the lead LDB5 of the semiconductor device SM1 and is inputted to (the drive circuit 4b in) the semiconductor chip CP3 through the wire BW10. IGBT driving voltage outputted from (the drive circuit 4b in) the semiconductor chip CP3 is outputted from the lead LDB6 of the semiconductor device SM1 through the wire BW11. Then it is inputted to the lead LDG of the semiconductor device SM1 by way of the resistor R1 external to the semiconductor device SM1. Thereafter, it is inputted to the pad electrode PD1G for gate of the semiconductor chip CP1 (that is, the gate of the IGBT 2 formed in the semiconductor chip CP1) through the wire BW1.

Fixed potential (power supply potential), preferably, ground potential (reference potential, GND potential, grounding potential) is inputted from the microcomputer MIC to the lead LDS of the semiconductor device SM1. Then it is inputted to the pad electrode PD2S1 for source of the semiconductor chip CP2 (that is, the source of the MOSFET 3 formed in the semiconductor chip CP2) through the wire BW5. This ground potential is also inputted to (the control circuit 4a and the drive circuit 4b in) the semiconductor chip CP3 through the wires BW3, BW4. (The wires BW3, BW4 couple together the pad electrodes PD2S1, PD2S2 for source of the semiconductor chip CP2 and pad electrodes PD3 of the semiconductor chip CP3.)

On voltage (voltage to be applied to the gate of the MOSFET 3 to turn on the MOSFET 3) from the control circuit 4a formed in the semiconductor chip CP3 is inputted to the pad electrode PD2G for gate of the semiconductor chip CP2. The on voltage is inputted through the wire BW2. (That is, the on voltage is inputted to the gate of the MOSFET 3 in the semiconductor chip CP2 through the wire BW2 coupling the pad electrode PD2G and the pad electrode PD3A together.)

As mentioned above, the leads LDD of the semiconductor device SM1 are electrically coupled to the back surface electrode BE2 of the semiconductor chip CP2 through the die pad DP2 and the conductive adhesive layer 13D. (That is, the leads LDD are electrically coupled to the drain of the MOSFET 3 formed in the semiconductor chip CP2.) These leads LDD have the voltage of the battery BT applied thereto through the step-up transformer TS. As mentioned above, on voltage is inputted from the control circuit 4a in the semiconductor chip CP3 to the pad electrode PD2G for gate of the semiconductor chip CP2 through the wire BW2. For above reason, the following takes place when the MOSFET 3 in the semiconductor chip CP2 is brought into on state by this on voltage: the source-drain current of the MOSFET 3 flows between the lead LDS and leads LDD of the semiconductor device SM1. The main capacitor CM can be thereby charged through the step-up transformer TS.

As mentioned above, the leads LDC of the semiconductor device SM1 are electrically coupled to the back surface electrode BE1 of the semiconductor chip CP1 through the die pad DP1 and the conductive adhesive layer 13A. (That is, the leads LDC are electrically coupled to the collector of the IGBT 2 formed in the semiconductor chip CP1.) As mentioned above, the leads LDE of the semiconductor device SM1 are electrically coupled to the pad electrode PD1E for emitter of the semiconductor chip CP1 through the metal plate MPL and the like. (That is, the leads LDE are electrically coupled to the emitter of the IGBT 2 formed in the semiconductor chip CP1.) As mentioned above, the leads LDC of the semiconductor device SM1 are coupled to one electrode of the main capacitor CM through the xenon tube XC; and the leads LDE of the semiconductor device SM1 are coupled to the other electrode of the main capacitor CM. As mentioned above, on voltage (IGBT driving voltage) is inputted from the drive circuit 4b in the semiconductor chip CP3 to the pad electrode PD2G for gate of the semiconductor chip CP1 through the wire BW11, lead LDB6, resistor R1, lead LDG, and wire BW1. For the above reason, the following takes place when the IGBT 2 in the semiconductor chip CP1 is brought into on state by this on voltage: in conjunction with light emission (discharge) of the xenon tube XC, the collector-emitter current of the IGBT 2 flows between the leads LDC and leads LDE of the semiconductor device SM1.

<Lead Arrangement of Semiconductor Device>

As mentioned above, the semiconductor device SM1 includes a lot of different kinds of leads LD (that is, the leads LDB1, LDB2, LDB3, LDB4, LDB5, LDB6, LDC, LDD, LDE, LDG, LDN, LDN1, LDS). Voltage applied to each lead LD is not identical. Especially, the potential difference between the collector and emitter of the IGBT 2 to which charging voltage of the main capacitor CM for causing the xenon tube XC to emit light (discharge) is applied is very large (for example, 300 to 400V). (That is, the potential difference between the leads LDC and the leads LDE is very large.) Further, a current flowing to between the collector and emitter of the IGBT 2 (that is, the leads LDC and the leads LDE) in conjunction with light emission (discharge) of the xenon tube XC is very large (for example, 100 to 200 A or so).

Even though a potential difference between leads LD is large or a current flowing between leads LD is large, no problem arises in the portions of the leads LD completely sealed in the package PA. They are sufficiently isolated from each other by the resin material (the resin material comprising the package PA) positioned therebetween. Therefore, it is unnecessary to pay attention to the arrangement of the leads LD in the semiconductor device SM1 as long as each lead LD is not exposed from the package PA at all. However, the leads LD function as external terminals of the semiconductor device SM1; therefore, each lead LD (each of the leads LDB1, LDB2, LDB3, LDB4, LDB5, LDB6, LDC, LDD, LDE, LDG, LDS) must be at least partly exposed from the package PA. When a potential difference between leads LD is large or a current flowing between leads LD is large, there is a possibility that the portions of the leads LD exposed from the package PA will be thereby influenced.

The semiconductor chip CP3 is a semiconductor chip for controlling in which the control circuit 4a, the drive circuit 4b, and the like are formed; therefore, it is susceptible to noise and the like. When a large current flows between the collector and the emitter of the IGBT 2 in conjunction with light emission (discharge) of the xenon tube XC, it is prone to be influenced by this large current. To cope with this, the following are implemented by, in addition to packaging the semiconductor chips CP1, CP2, CP3 into one, adding a twist to the arrangement of the leads LD in the semiconductor device SM1 as described later: when a large current flows between the collector and emitter of the IGBT 2 in conjunction with light emission (discharge) of the xenon tube XC, its influence on (the control circuit 4a and the drive circuit 4b in) the semiconductor chip CP3 is prevented; and malfunction and the like of (the control circuit 4a and the drive circuit 4b in) the semiconductor chip CP3 are prevented.

The multiple leads LD provided in the semiconductor device SM1 include: the leads LDB1, LDB2, LDB3, LDB4, LDB5, LDB6 respectively electrically coupled to the multiple pad electrodes PD3 of the semiconductor chip CP3; the leads LDE for emitter electrically coupled to the emitter of the IGBT 2; and the leads LDC for collector electrically coupled to the collector of the IGBT 2. The leads LDB1, LDB2, LDB3, LDB4, LDB5, LDB6 and the leads LDC, LDE for collector and for emitter are arranged on different sides of the package PA from each other as viewed in a plane. More desirably, the leads LDB1, LDB2, LDB3, LDB4, LDB5, LDB6, the leads LDE for emitter, and the leads LDC for collector are arranged on different sides of the package PA from one another as viewed in a plane. “As viewed in a plane” cited here refers to as viewed in a plane parallel with the under surface (back surface) of the package PA.

More specific description will be given. As illustrated in FIG. 5, FIG. 11 to FIG. 13, and the like, of the leads LD, the leads LDC, LDE coupled to the collector and emitter of the IGBT 2 are arranged along the sides SDA, SDB of the back surface of the package PA. That is, the multiple leads LDC are arranged along the side SDA of the back surface of the package PA; and the multiple leads LDE are arranged along the side SDB of the back surface of the package PA. Of the leads LD, the leads LDB1, LDB2, LDB3, LDB4, LDB5, LDB6 electrically coupled to the pad electrodes PD3 of the semiconductor chip CP3 for controlling through the wires BW6, BW7, BW8, BW9, BW10, BW11 are arranged as follows: they are arranged along the sides SDC, SDD of the back surface of the package PA. That is, the leads LDB1, LDB2, LDB3 are arranged along the side SDD of the back surface of the package PA; and the leads LDB4, LDB5, LDB6 are arranged along the side SDC of the back surface of the package PA.

In the under surface (back surface) of the semiconductor device SM1, that is, the back surface of the package PA, each side is defined as follows: the side SDA and the side SDB intersect each other; the side SDB and the side SDC intersect each other; the side SDC and the side SDD intersect each other; the side SDD and the side SDA intersect each other; the side SDA and the side SDC are positioned opposite to each other; and the side SDB and the side SDD are positioned opposite to each other.

As mentioned above, the leads LDB1, LDB2, LDB3, LDB4, LDB5, LDB6 electrically coupled to the pad electrodes PD3 of the semiconductor chip CP3 for controlling are arranged on the sides SDC, SDD. These sides are different from the sides SDA, SDB on which the leads LDC, LDE through which a large current is passed in conjunction with light emission of the xenon tube XC are arranged as viewed in a plane. As a result, the following is implemented even though a large current is passed through the leads LDC, LDE in conjunction with light emission of the xenon tube XC: the leads LDB1, LDB2, LDB3, LDB4, LDB5, LDB6 arranged on the sides SDC, SDD different from the sides SDA, SDB on which the leads LDC, LDE are arranged are hardly influenced by the large current passed through the leads LDC, LDE. For this reason, it is possible to implement the following when a large current flows between the collector and emitter of the IGBT 2 in conjunction with light emission of the xenon tube XC: it is possible to prevent (the control circuit 4a and the drive circuit 4b in) the semiconductor chip CP3 from being influenced. Further, it is possible to prevent malfunction and the like of (the control circuit 4a and the drive circuit 4b in) the semiconductor chip CP3. This makes it possible to enhance the performance and reliability of the semiconductor device SM1 and the light emitting device 1 using it.

A voltage of several tens of volts (for example, 60V or so) is also applied to the leads LDD for drain (that is, the drain of the MOSFET 3). For this reason, it is more desirable that the leads LDD for drain should be arranged on a side different from the sides SDC, SDD on which the leads LDB1, LDB2, LDB3, LDB4, LDB5, LDB6 are arranged as viewed in a plane. (This side different from the sides SDC, SDD is the side SDA in this embodiment and the side SDB in the sixth embodiment described later.) This makes it possible to adequately prevent voltage applied to the leads LDD for drain from having influence on (the control circuit 4a and the drive circuit 4b in) the semiconductor chip CP3. As a result, it is possible to further enhance the performance and reliability of the semiconductor device SM1 and the light emitting device 1 using it.

Meanwhile, the lead LDS for source (that is, the source of the MOSFET 3) is supplied with ground potential (reference potential, GND potential, grounding potential). For this reason, the lead LDS for source can be placed on the same side as the sides SDC, SDD on which the leads LDB1, LDB2, LDB3, LDB4, LDB5, LDB6 are arranged as viewed in a plane. In this embodiment, the lead LDS for source is placed on the side SDD. This makes it easy to couple the lead LDS for source and the pad electrode PD2S1 for source of the semiconductor chip CP2 through a wire BW. As another embodiment, however, the lead LDS for source may be placed on the side SDC.

How to arrange the leads LD (which lead LD should be placed on which side SDA to SDD) in the semiconductor device SM1 in this embodiment is basically the same with the following semiconductor devices unless especially stated otherwise: semiconductor devices in the first to third modifications described later and in the second to 12th embodiments described later. The above effect can be obtained by this.

<Modifications of Semiconductor Device>

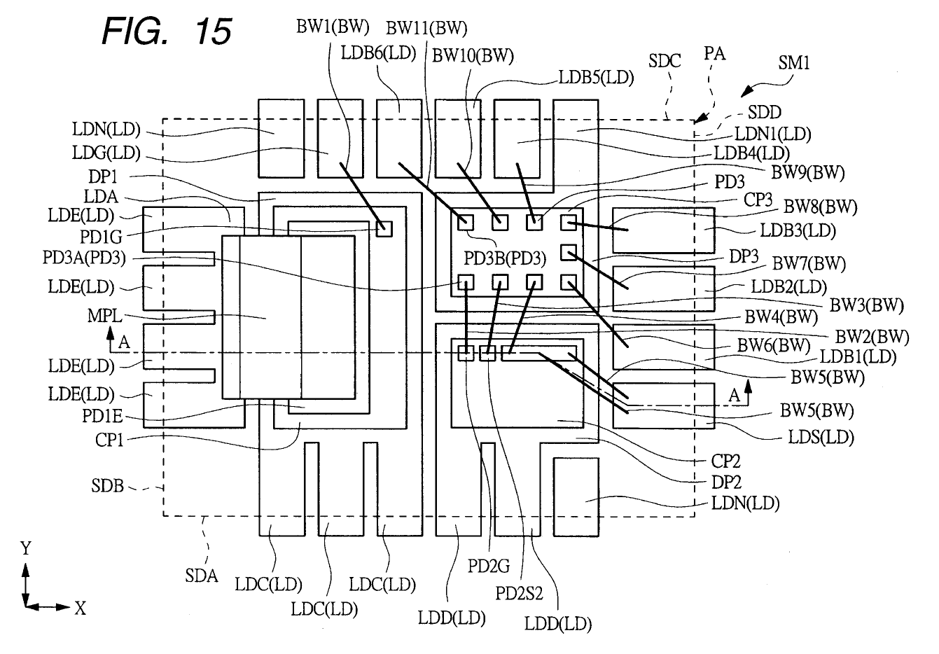

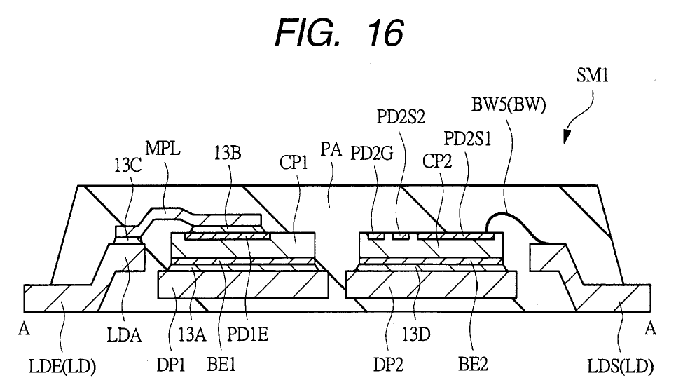

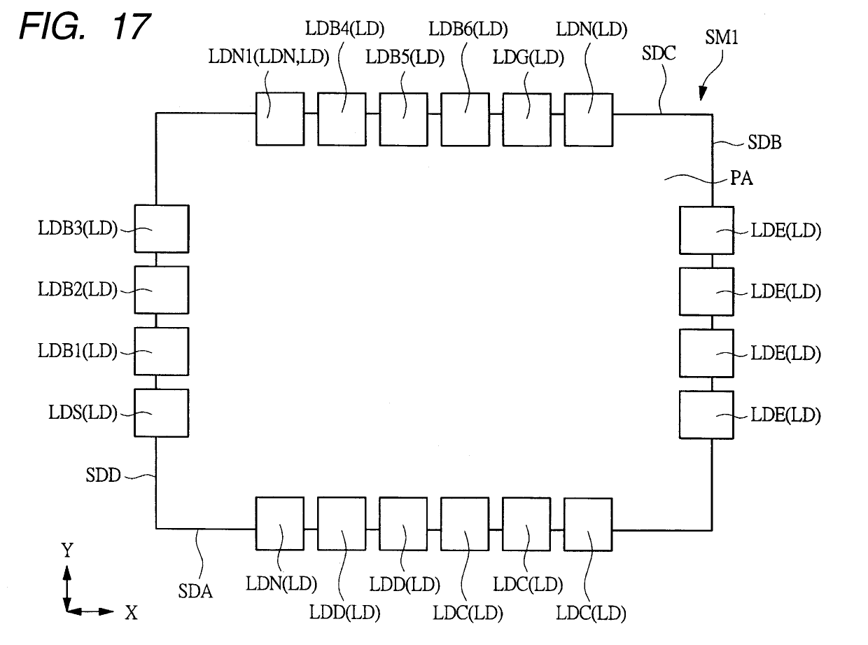

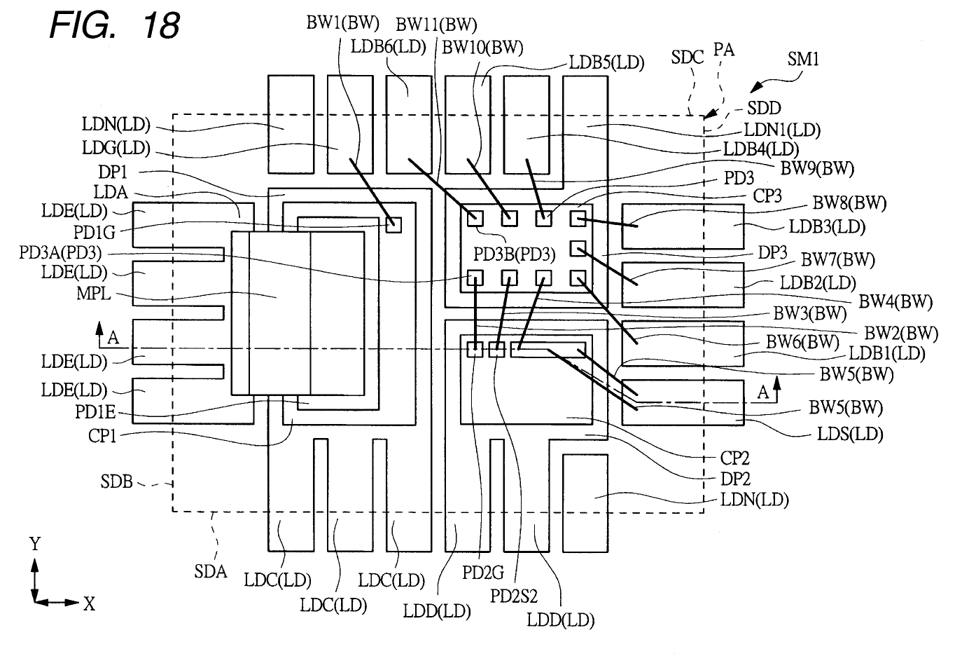

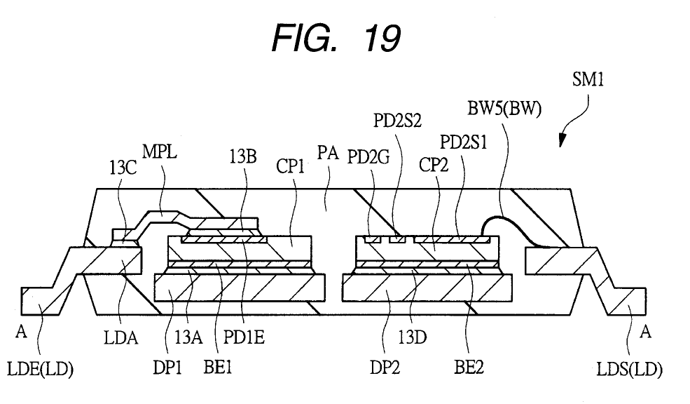

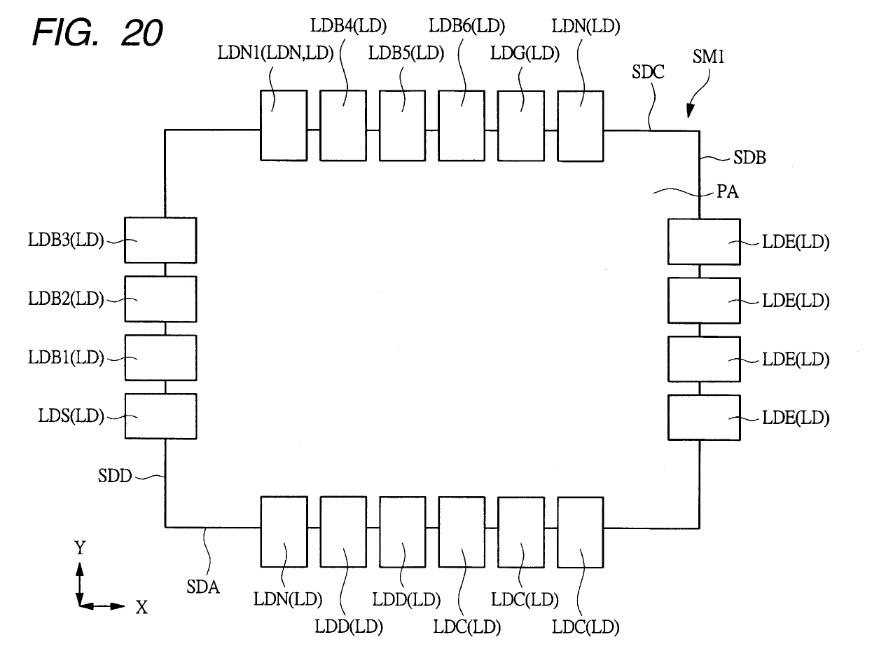

FIG. 15 is a planar transparent view illustrating a first modification of the semiconductor device SM1 in this embodiment; FIG. 16 is a sectional view thereof; and FIG. 17 is a bottom view (back side back view) thereof. FIG. 18 is a planar transparent view illustrating a second modification of the semiconductor device SM1 in this embodiment; FIG. 19 is a sectional view thereof; and FIG. 20 is a bottom view (back side back view) thereof. FIG. 15 and FIG. 18 correspond to FIG. 11; FIG. 16 and FIG. 19 correspond to FIG. 6; and FIG. 17 and FIG. 20 correspond to FIG. 5.

The first modification in FIG. 15 to FIG. 17 corresponds to a case where each lead LD is protruded sideways from the package PA as compared with the case illustrated in FIG. 4 to FIG. 13. The portions protruded from the package PA are flattened. Meanwhile, the second modification in FIG. 18 to FIG. 20 corresponds to a case where the following is implemented: any lead LD is not exposed in the back surface of the package PA and the leads LD are protruded from the lateral surface of the package PA; and each lead LD is bent at its portion protruded from the package PA.

The semiconductor device SM1 illustrated in FIG. 4 to FIG. 13 is of the QFN configuration and is so formed that each lead LD is not largely protruded outward from the package PA. As in FIG. 15 to FIG. 17 or in FIG. 18 to FIG. 20, instead, the semiconductor device may be of the QFP (Quad Flat Package) configuration so that part of each lead LD is largely protruded outward from the package PA. This is the same with the second and following embodiments described later.

With respect to the arrangement position of each lead LD in a plane, the first and second modifications are the same as the first embodiment. That is, both the semiconductors in the first modification in FIG. 15 to FIG. 17 and the second modification in FIG. 18 to FIG. 20 are the same as the semiconductor device SM1 illustrated in FIG. 4 to FIG. 13. Therefore, the description thereof will be omitted. The semiconductor devices in the second to 12th embodiments described later may also be of the QFP configuration.

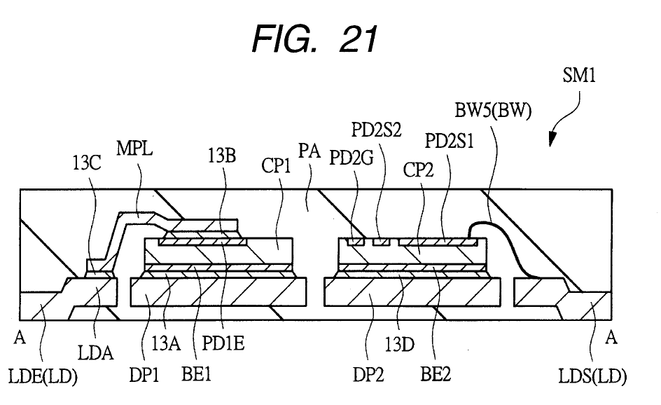

FIG. 21 is a sectional view illustrating a third modification of the semiconductor device SM1 in this embodiment and corresponds to FIG. 6.

In the semiconductor device SM1 illustrated in FIG. 4 to FIG. 13, the following measure is taken with respect to the leads LD other than the leads LD (the leads LDC, LDD, LDN1 in this example) integrally coupled to the die pads DP1 to DP3: each lead LD is processed so that its portion closer to the die pad DP1 to DP3 is lifted. The surface of the lead LD to which the metal plate MPL or a wire BW is to be coupled is thereby made higher than the upper surfaces of the die pads DP1 to DP3. (The upper surfaces of the die pads DP1 to DP3 are the surfaces over which the semiconductor chips CP1 to CP3 are to be placed). This makes it easier to couple the metal plate MPL or a wire BW to each lead LD.

In the third modification illustrated in FIG. 21, meanwhile, the surface of each lead LD to which the metal plate MPL or a wire BW is coupled is identical in height with the upper surfaces of the die pads DP1 to DP3. (The upper surfaces of the die pads DP1 to DP3 are the surfaces over which the semiconductor chips CP1 to CP3 are to be placed.) This makes it easier to process each lead LD. This is applicable also to the semiconductor devices in the second to seventh embodiments described later.

### Second Embodiment

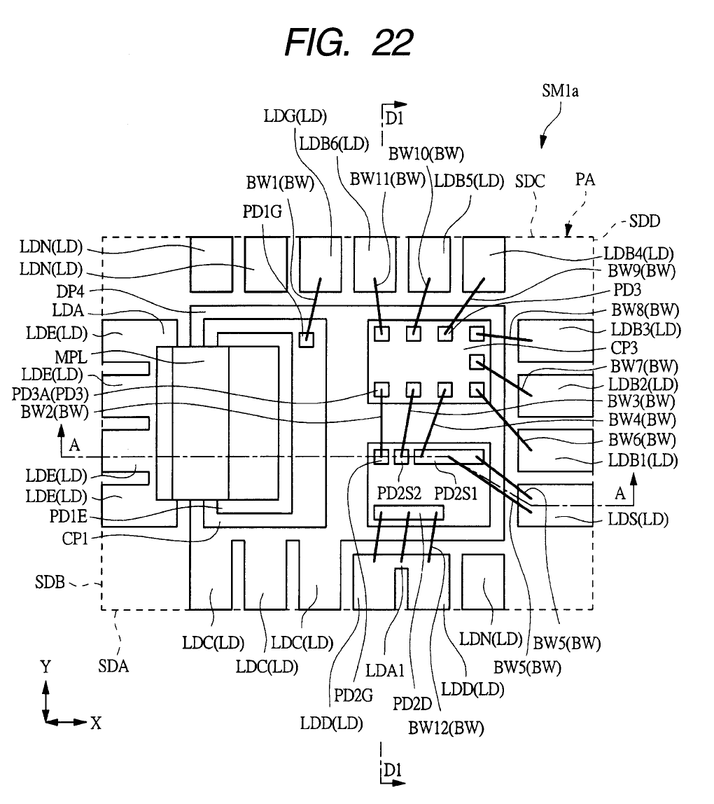

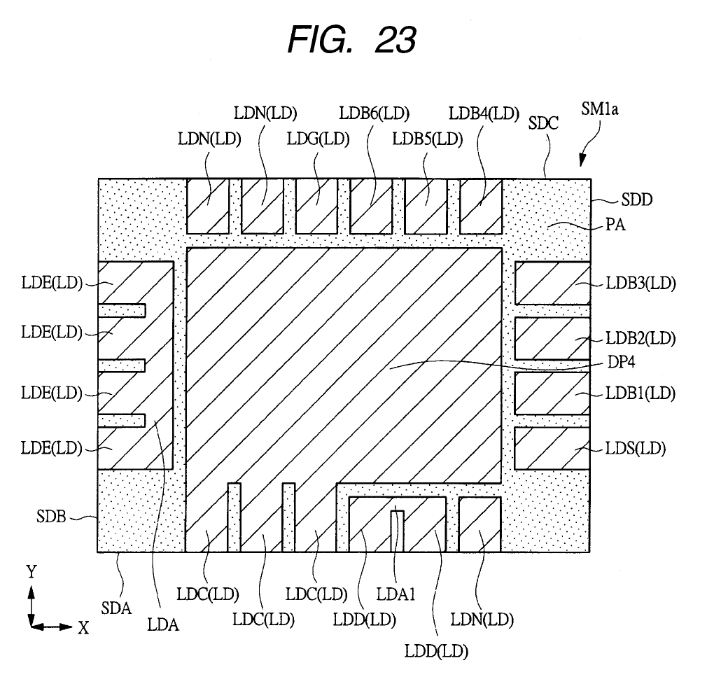

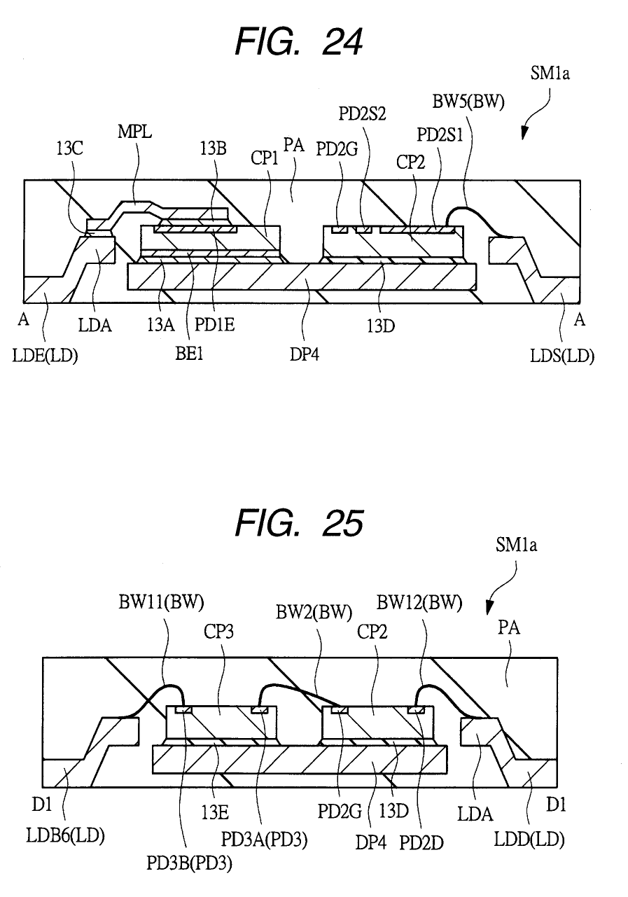

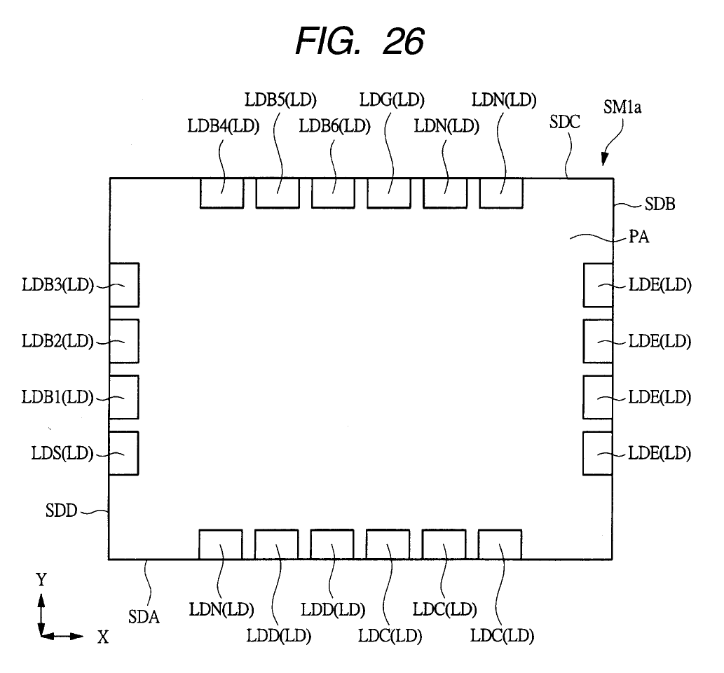

FIG. 22 is a planar transparent view of a semiconductor device SM1a in a second embodiment. FIG. 22 corresponds to FIG. 11 and shows an overall plan view illustrating the interior of the package PA seen through. FIG. 23 is a planar transparent view of the semiconductor device SM1a in FIG. 22 with the metal plate MPL, wires BW, and semiconductor chips CP1, CP2, CP3 further removed (seen through) and corresponds to FIG. 13. Though FIG. 23 is a plan view, in FIG. 23, a die pad DP4, lead wirings LDA, LDA1, and leads LD are hatched with oblique lines and the material (resin material) comprising the package PA is hatched with dots to facilitate visualization. FIG. 24 and FIG. 25 are sectional views (lateral sectional view) of the semiconductor device SM1a and are respectively taken in substantially the same sectional positions as in FIG. 6 and FIG. 9. FIG. 24 substantially corresponds to a sectional view of the semiconductor device SM1a taken in the position of line A-A of FIG. 22; and FIG. 25 substantially corresponds to a sectional view of the semiconductor device SM1a taken in the position of line D1-D1 of FIG. 22. FIG. 26 is a bottom view (back side back view) of the semiconductor device SM1a and corresponds to FIG. 5. A top view of the semiconductor device SM1a in this embodiment is the same as FIG. 4 and it will be obtained here.

The comparison of FIG. 22 to FIG. 26 with FIG. 11, FIG. 13, FIG. 6, FIG. 9, and FIG. 5 reveals the following: the semiconductor device SM1a in this embodiment illustrated in FIG. 22 to FIG. 26 is different from the semiconductor device SM1 in the first embodiment in that the semiconductor chips CP1, CP2, CP3 are placed over the common die pad DP4. The semiconductor device SM1a is substantially the same as the semiconductor device SM1 in the first embodiment in the other respects in configuration and functions and description will be given mainly to the difference.

In the semiconductor device SM1a in this embodiment, the semiconductor chips CP1, CP2, CP3 are placed over the common die pad DP4. The die pad DP4 is equivalent to what is obtained by integrally coupling together the die pad DP1, die pad DP2, and die pad DP3. More specific description will be given. In the first embodiment, the die pads DP1, DP2, DP3 are separated from one another and the areas between them are filled with the resin material (resin material comprising the package PA). In this embodiment, meanwhile, the one die pad DP4 obtained by integrating the die pads DP1, DP2, DP3 is used and the three semiconductor chips CP1, CP2, CP3 are placed over this die pad DP4. The multiple leads LD are arranged around the die pad DP4. The die pad DP4 is sealed with the package (sealing body) PA.

In the first embodiment, however, the multiple leads LDC are integrally coupled to the die pad DP1; the multiple leads LDD are integrally coupled to the die pad DP2; and the lead LDN1 is integrally coupled to the die pad DP3. In this embodiment, meanwhile, the multiple leads LDC are integrally coupled to the die pad DP4 but none of the multiple leads LDD is integrally coupled to the die pad DP4. The die pad DP4 and the leads LDD are separated and electrically isolated from each other. That is, while the die pad DP4 and the leads LDC are integrally formed, the die pad DP4 and the leads LDD are not integrally formed. In the package PA, the end of each lead LDD is integrally coupled to the lead wiring LDA1 and the leads LDD are electrically coupled with each other through the lead wiring LDA1.

What is equivalent to the lead LDN1 (that is, a non-contact lead integrally coupled to the die pad DP4) is not provided in the semiconductor device SM1a in this embodiment. The reason for this is as follows: since the leads LDC are coupled to the die pad DP4, the die pad DP4 can be kept held or fixed by these leads LDC until the package PA is formed; therefore, it is unnecessary to provide what is equivalent to the lead LDN1. When the semiconductor device SM1a is manufactured, the leads LDC are coupled to (the frame of) a lead frame for the manufacture of the semiconductor device SM1a. Thus the die pad DP4 can be held on the lead frame and the semiconductor device SM1a can be manufactured using a lead frame. In this embodiment, therefore, what is equivalent to the lead LDN1 is not present and thus the following measure is taken as seen from the comparison of FIG. 22 with FIG. 13: the lead LDB4 is placed in the position of the lead LDN1 in FIG. 13; the lead LDB5 is placed in the position of the lead LDB4 in FIG. 13; the lead LDB6 is placed in the position of the lead LDB5 in FIG. 13; the lead LDG is placed in the position of the lead LDB6 in FIG. 13; and the non-contact lead LDN is placed in the position of the lead LDG in FIG. 13.

Also in this embodiment as well as the first embodiment, the semiconductor chip CP1 has the back surface electrode BE1 (that is, a back surface electrode for the collector of the IGBT 2). This back surface electrode BE1 of the semiconductor chip CP1 is joined and fixed to the die pad DP4 through the conductive adhesive layer 13A and electrically coupled thereto. Therefore, each lead LDC is electrically coupled to the back surface electrode BE1 of the semiconductor chip CP1 (that is, the collector of the IGBT 2) through the die pad DP4 and the conductive adhesive layer 13A.

In this embodiment, unlike the first embodiment, the back surface electrode (back surface drain electrode) BE2 is not formed in the back surface (under surface) of the semiconductor chip CP2. Instead, not only the pad electrode PD2G for gate and the pad electrodes PD2S1, PD2S2 for source but also a pad electrode (bonding pad) PD2D for drain is provided in the principal surface (front surface, upper surface) of the semiconductor chip CP2. These pad electrodes PD2G, PD2S1, PD2S2, PD2D are all electrodes (pad electrodes, electrode pads, bonding pads) for bonding a wire BW.

The pad electrode PD2D for drain of the semiconductor chip CP2 is electrically coupled to the drain of the MOSFET 3 formed in the semiconductor chip CP2. That is, the pad electrode PD2D for drain of the semiconductor chip CP2 corresponds to a pad electrode (bonding pad) for the drain of the MOSFET 3. The pad electrode PD2D for drain of the semiconductor chip CP2 is electrically coupled to the lead wiring LDA1 through (a single or multiple) wires BW12 of the multiple wires BW. Therefore, each lead LDD for drain is electrically coupled to the pad electrode PD2D for drain of the semiconductor chip CP2 (that is, the drain of the MOSFET) through the lead wiring LDA1 and the wires BW12.

In this embodiment, unlike the first embodiment, the adhesive layer 13D joining the back surface of the semiconductor chip CP2 to the die pad DP4 must have insulating properties. In the first embodiment, the adhesive layer 13D must be conductive to electrically couple the back surface electrode BE2 of the semiconductor chip CP2 to the die pad DP2. In this embodiment, the semiconductor chip CP2 is placed over the die pad DP4 electrically coupling the back surface electrode BE1 of the semiconductor chip CP1; therefore, it is required to electrically isolate the die pad DP4 and the semiconductor chip CP2 from each other. In this embodiment, for this purpose, the die pad DP4 and the semiconductor chip CP2 are electrically isolated from each other by joining together the back surface of the semiconductor chip CP2 and the die pad DP4 using the insulating adhesive layer 13D. In this embodiment, for the same reason, the adhesive layer 13E joining the back surface of the semiconductor chip CP3 to the die pad DP4 must also have insulating properties.

The other respects in the configuration of the semiconductor device SM1a are substantially the same as in that of the semiconductor device SM1 in the first embodiment and the description thereof will be omitted. The relation of coupling and functions of the semiconductor device SM1a in the light emitting device 1 are the same as those of the semiconductor device SM1 in the first embodiment.

In this embodiment, as mentioned above, the three semiconductor chips CP1, CP2, CP3 are mounted over the common die pad DP4. As a result, in addition to the effect obtained in the first embodiment, the assemblability (ease of assembly) of the semiconductor device SM1a can be enhanced. Meanwhile, when the three semiconductor chips CP1, CP2, CP3 are respectively placed over different die pads DP1, DP2, DP3 as in the first embodiment, the following can be implemented: the die pads DP1, DP2, DP3 over which the respective semiconductor chips CP1, CP2, CP3 are placed can be isolated by the resin material comprising the package PA. Therefore, it is possible to further enhance the breakdown voltage and to further enhance the reliability of the semiconductor device.

### Third Embodiment

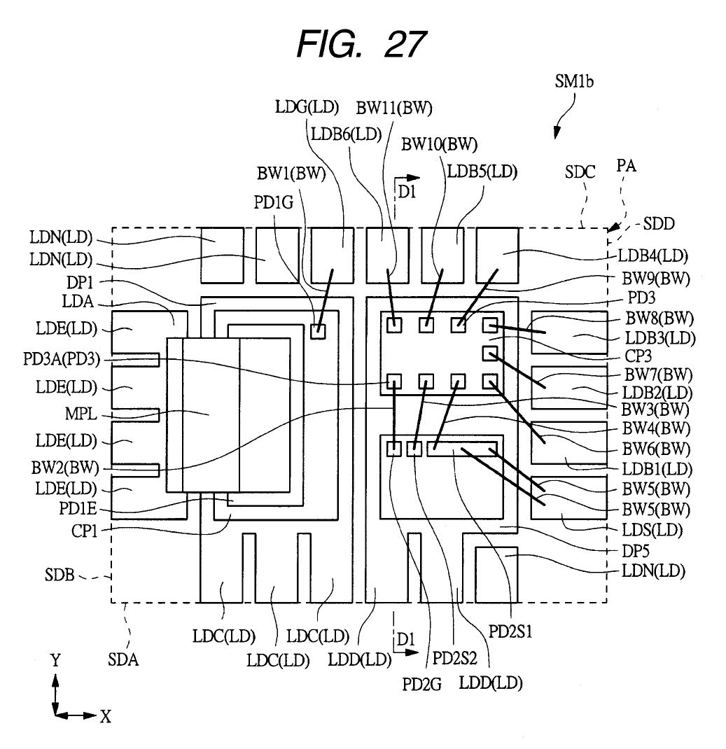

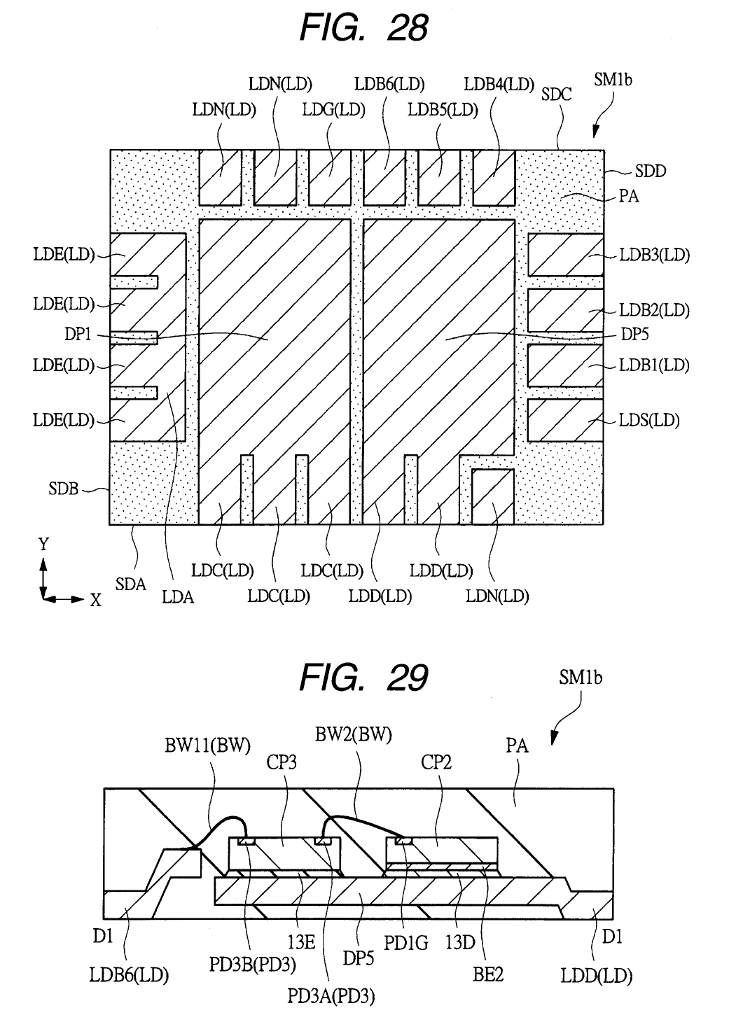

FIG. 27 is a planar transparent view of a semiconductor device SM1b in a third embodiment. FIG. 27 corresponds to FIG. 11 and shows an overall plan view illustrating the interior of the package PA seen through. FIG. 28 is a planar transparent view of the semiconductor device SM1b in FIG. 27 with the metal plate MPL, wires BW, and semiconductor chips CP1, CP2, CP3 further removed (seen through) and corresponds to FIG. 13. Though FIG. 28 is a plan view, in FIG. 28, a die pad DP1, DP5, lead wiring LDA, and leads LD are hatched with oblique lines and the material (resin material) comprising the package PA is hatched with dots to facilitate visualization. FIG. 29 is a sectional view (lateral sectional view) of the semiconductor device SM1b and is taken in substantially the same sectional position as in FIG. 9. FIG. 29 is substantially corresponds to a sectional view of the semiconductor device SM1b taken in the position of line D1-D1 of FIG. 27. A top view and a bottom view of the semiconductor device SM1b in this embodiment are respectively the same as FIG. 4 and FIG. 26 and they will be omitted here.

The comparison of FIG. 27 to FIG. 29 with FIG. 11, FIG. 13, and FIG. 9 reveals the following: the semiconductor device SM1b in this embodiment illustrated in FIG. 27 to FIG. 29 is different from the semiconductor device SM1 in the first embodiment in that the semiconductor chips CP2, CP3 are placed over the common die pad DP5. The semiconductor device SM1b in this embodiment is substantially the same as the semiconductor device SM1 in the first embodiment in the other respects in configuration and functions and description will be given mainly to the difference.

In the semiconductor device SM1b in this embodiment, the semiconductor chip CP1 is placed over the die pad DP1 as in the first embodiment. Unlike the first embodiment, however, the semiconductor chip CP2 and the semiconductor chip CP3 are placed over the common die pad DP5. The die pad DP5 is equivalent to what is obtained by integrally coupling the die pad DP2 and the die pad DP3 together. More specific description will be given. In the first embodiment, the die pad DP2 and the die pad DP3 are separated from each other and the area between them is filled with the resin material (resin material comprising the package PA). In this embodiment, meanwhile, the die pad DP5 obtained by integrating the die pad DP2 and the die pad DP3 together is used in place of the die pads DP2, DP3 and two semiconductor chips CP2, CP3 are placed over this die pad DP5. The multiple leads LD are arranged around (a die pad group comprised of) the die pads DP1, DP5 and no lead LD is placed between the die pad DP1 and the die pad DP5. Similarly with the die pad DP1, the die pad DP5 is also sealed with the package (sealing body) PA. In the first embodiment, the multiple leads LDD are integrally coupled to the die pad DP2. In this embodiment, similarly, multiple leads LDD are integrally coupled to the die pad DP5. That is, the die pad DP5 and the leads LDD are integrally formed.

However, what is equivalent to the lead LDN1 (that is, a non-contact lead integrally coupled to the die pad DP5) is not provided in the semiconductor device SM1b in this embodiment. The reason for this is as follows: since the leads LDD are coupled to the die pad DP5, the die pad DP5 can be kept held or fixed by these leads LDD until the package PA is formed; therefore, it is unnecessary to provide what is equivalent to the lead LDN1. When the semiconductor device SM1b is manufactured, the leads LDC, LDD are coupled to (the frame of) a lead frame for the manufacture of the semiconductor device SM1b. Thus the die pads DP1, DP5 can be held on the lead frame and the semiconductor device SM1b can be manufactured using a lead frame. In this embodiment, therefore, what is equivalent to the lead LDN1 is not present and thus the following measure is taken as seen from the comparison of FIG. 28 with FIG. 13: the lead LDB4 is placed in the position of the lead LDN1 in FIG. 13; the lead LDB5 is placed in the position of the lead LDB4 in FIG. 13; the lead LDB6 is placed in the position of the lead LDB5 in FIG. 13; the lead LDG is placed in the position of the lead LDB6 in FIG. 13; and a non-contact lead LDN is placed in the position of the lead LDG in FIG. 13.

Also in this embodiment as well as the first embodiment, the semiconductor chip CP1 has the back surface electrode BE1 (that is, a back surface electrode for the collector of the IGBT 2). This back surface electrode BE1 of the semiconductor chip CP1 is joined and fixed to the die pad DP1 through the conductive adhesive layer 13A and electrically coupled thereto. Therefore, each lead LDC is electrically coupled to the back surface electrode BE1 of the semiconductor chip CP1 (that is, the collector of the IGBT 2) through the die pad DP1 and the conductive adhesive layer 13A.

Also in this embodiment as well as the first embodiment, the semiconductor chip CP2 has the back surface electrode BE2 (that is, a back surface electrode for the drain of the MOSFET 3). This back surface electrode BE2 of the semiconductor chip CP2 is joined and fixed to the die pad DP5 through the conductive adhesive layer 13D and electrically coupled thereto. Therefore, each lead LDD is electrically coupled to the back surface electrode BE2 of the semiconductor chip CP2 (that is, the drain of the MOSFET 3) through the die pad DP5 and the conductive adhesive layer 13D.

Meanwhile, the semiconductor chip CP3 is joined and fixed to the die pad DP5 through the adhesive layer 13E. In this embodiment, the adhesive layer 13E joining the back surface of the semiconductor chip CP3 to the upper surface of the die pad DP5 must have insulating properties. More specific description will be given. The semiconductor chip CP3 is placed over the die pad DP5 electrically coupling the back surface electrode BE2 of the semiconductor chip CP2; therefore, it is required to electrically isolate the die pad DP5 and the semiconductor chip CP3 from each other. In this embodiment, consequently, the back surface of the semiconductor chip CP3 and the die pad DP5 are joined with each other through the insulating adhesive layer 13E. The die pad DP5 and the semiconductor chip CP3 are thereby electrically isolated from each other.

The other respects in the configuration of the semiconductor device SM1b are substantially the same as in that of the semiconductor device SM1 in the first embodiment and the description thereof will be omitted. The relation of coupling and functions of the semiconductor device SM1b in the light emitting device 1 are the same as those of the semiconductor device SM1 in the first embodiment.

In this embodiment, only two die pads (the die pads DP1, DP5) are required. In addition to the effect obtained in the first embodiment, therefore, the assemblability (ease of assembly) of the semiconductor device SM1b can be enhanced as compared with cases where three die pads are required. Meanwhile, when the three semiconductor chips CP1, CP2, CP3 are respectively placed over different die pads DP1, DP2, DP3 as in the first embodiment, the following can be implemented: it is possible to further enhance the breakdown voltage and to further enhance the reliability of the semiconductor device.

### Fourth Embodiment

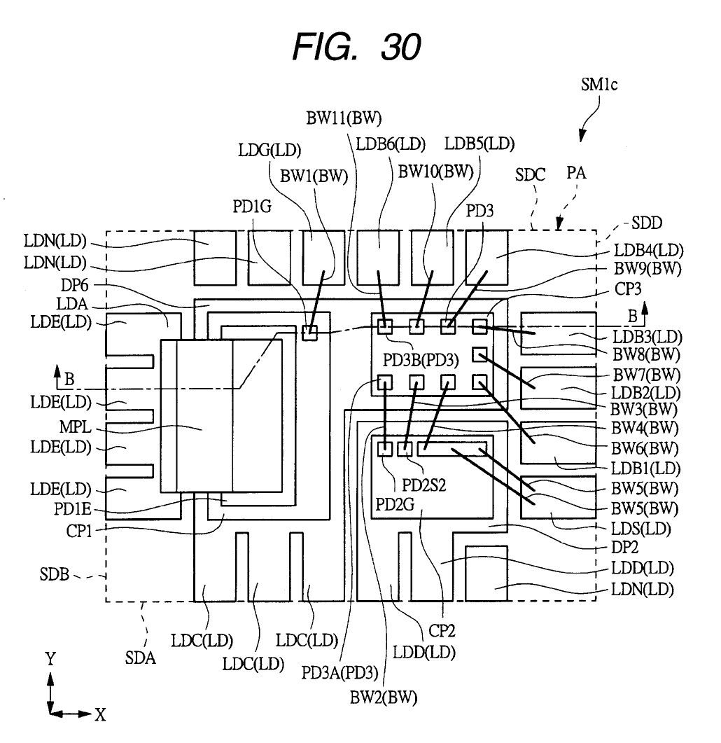

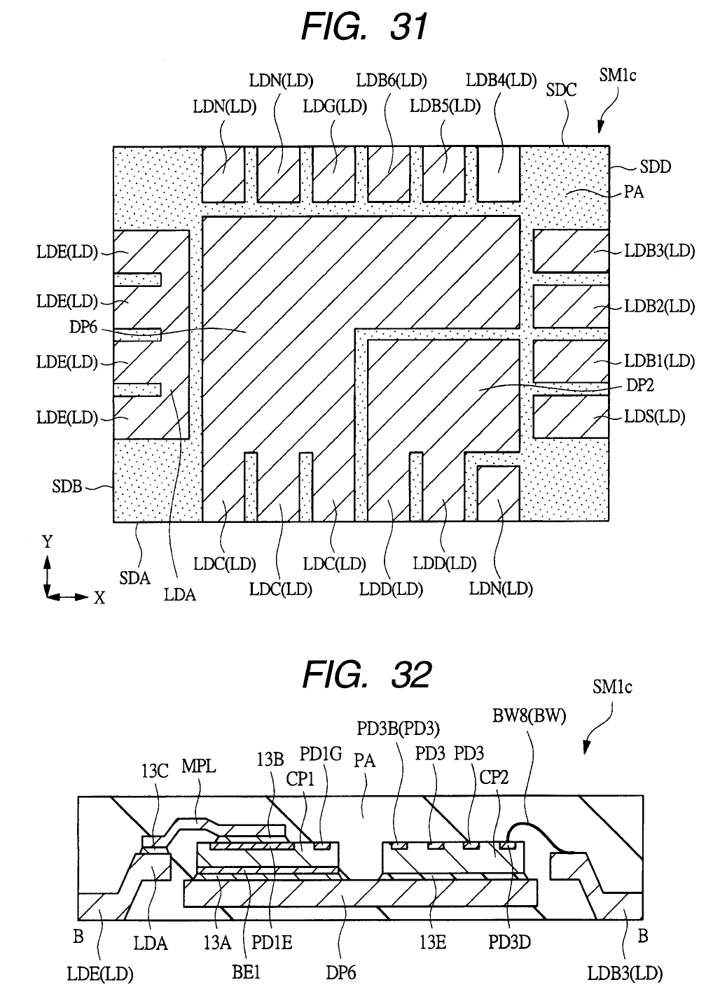

FIG. 30 is a planar transparent view of a semiconductor device SM1c in a fourth embodiment. FIG. 30 corresponds to FIG. 11 and shows an overall plan view illustrating the interior of the package PA seen through. FIG. 31 is a planar transparent view of the semiconductor device SM1c in FIG. 30 with the metal plate MPL, wires BW, and semiconductor chips CP1, CP2, CP3 further removed (seen through) and corresponds to FIG. 13. Though FIG. 31 is a plan view, in FIG. 31, die pads DP2, DP6, lead wiring LDA, and leads LD are hatched with oblique lines and the material (resin material) comprising the package PA is hatched with dots to facilitate visualization. FIG. 32 is a sectional view (lateral sectional view) of the semiconductor device SM1c and is taken in substantially the same sectional position as in FIG. 7. FIG. 32 substantially corresponds to a sectional view of the semiconductor device SM1c taken in the position of line B-B of FIG. 30. A top view and a bottom view of the semiconductor device SM1c in this embodiment are respectively the same as FIG. 4 and FIG. 26 and they will be omitted here.

The comparison of FIG. 30 to FIG. 32 with FIG. 11, FIG. 13, and FIG. 9 reveals the following: the semiconductor device SM1c in this embodiment illustrated in FIG. 30 to FIG. 32 is different from the semiconductor device SM1 in the first embodiment in that the semiconductor chips CP1, CP3 are placed over the common die pad DP6. The semiconductor device SM1c in this embodiment is substantially the same as the semiconductor device SM1 in the first embodiment in the other respects in configuration and functions and description will be given mainly to the difference.

In the semiconductor device SM1c in this embodiment, the semiconductor chip CP2 is placed over the die pad DP2 as in the first embodiment. Unlike the first embodiment, however, the semiconductor chip CP1 and the semiconductor chip CP3 are placed over the common die pad DP6. The die pad DP6 is equivalent to what is obtained by integrally coupling the die pad DP1 and the die pad DP3 together. More specific description will be given. In the first embodiment, the die pad DP1 and the die pad DP3 are separated from each other and the area between them is filled with the resin material (resin material comprising the package PA). In this embodiment, meanwhile, the die pad DP6 obtained by integrating the die pad DP1 and the die pad DP3 together is used in place of the die pads DP1, DP3 and two semiconductor chips CP1, CP3 are placed over this die pad DP6. The multiple leads LD are arranged around (a die pad group comprised of) the die pads DP2, DP6 and no lead LD is placed between the die pad DP2 and the die pad DP6. Similarly with the die pad DP2, the die pad DP6 is also sealed with the package (sealing body) PA. In the first embodiment, the multiple leads LDC are integrally coupled to the die pad DP1. In this embodiment, similarly, multiple leads LDC are integrally coupled to the die pad DP6. That is, the die pad DP6 and the leads LDC are integrally formed.

However, what is equivalent to the lead LDN1 (that is, a non-contact lead integrally coupled to the die pad DP6) is not provided in the semiconductor device SM1c in this embodiment. The reason for this is as follows: since the leads LDC are coupled to the die pad DP6, the die pad DP6 can be kept held or fixed by these leads LDC until the package PA is formed; therefore, it is unnecessary to provide what is equivalent to the lead LDN1. When the semiconductor device SM1c is manufactured, the leads LDC, LDD are coupled to (the frame of) a lead frame for the manufacture of the semiconductor device SM1c. Thus the die pads DP2, DP6 can be held on the lead frame and the semiconductor device SM1c can be manufactured using a lead frame. In this embodiment, therefore, what is equivalent to the lead LDN1 is not present and thus the following measure is taken as seen from the comparison of FIG. 31 with FIG. 13: the lead LDB4 is placed in the position of the lead LDN1 in FIG. 13; the lead LDB5 is placed in the position of the lead LDB4 in FIG. 13; the lead LDB6 is placed in the position of the lead LDB5 in FIG. 13; the lead LDG is placed in the position of the lead LDB6 in FIG. 13; and a non-contact lead LDN is placed in the position of the lead LDG in FIG. 13.

Also in this embodiment as well as the first embodiment, the semiconductor chip CP2 has the back surface electrode BE2 (that is, a back surface electrode for the drain of the MOSFET 3). This back surface electrode BE2 of the semiconductor chip CP2 is joined and fixed to the die pad DP2 through the conductive adhesive layer 13D and electrically coupled thereto. Therefore, each lead LDD is electrically coupled to the back surface electrode BE2 of the semiconductor chip CP2 (that is, the drain of the MOSFET 3) through the die pad DP2 and the conductive adhesive layer 13D.

Also in this embodiment as well as the first embodiment, the semiconductor chip CP1 has the back surface electrode BE1 (that is, aback surface electrode for the collector of the IGBT 2). This back surface electrode BE1 of the semiconductor chip CP1 is joined and fixed to the die pad DP6 through the conductive adhesive layer 13A and electrically coupled thereto. Therefore, each lead LDC is electrically coupled to the back surface electrode BE1 of the semiconductor chip CP1 (that is, the collector of the IGBT 2) through the die pad DP6 and the conductive adhesive layer 13A.

Meanwhile, the semiconductor chip CP3 is joined and fixed to the die pad DP6 through the adhesive layer 13E. In this embodiment, the adhesive layer 13E joining the back surface of the semiconductor chip CP3 to the upper surface of the die pad DP6 must have insulating properties. More specific description will be given. The semiconductor chip CP3 is placed over the die pad DP6 electrically coupling the back surface electrode BE1 of the semiconductor chip CP1; therefore, it is required to electrically isolate the die pad DP6 and the semiconductor chip CP3 from each other. In this embodiment, consequently, the back surface of the semiconductor chip CP3 and the die pad DP6 are joined with each other through the insulating adhesive layer 13E. The die pad DP6 and the semiconductor chip CP3 are thereby electrically isolated from each other.

The other respects in the configuration of the semiconductor device SM1c are substantially the same as in that of the semiconductor device SM1 in the first embodiment and the description thereof will be omitted. The relation of coupling and functions of the semiconductor device SM1c in the light emitting device 1 are the same as those of the semiconductor device SM1 in the first embodiment.

In this embodiment, only two die pads (the die pads DP1, DP6) are required. In addition to the effect obtained in the first embodiment, therefore, the assemblability (ease of assembly) of the semiconductor device SM1c can be enhanced as compared with cases where three die pads are required. Meanwhile, when the three semiconductor chips CP1, CP2, CP3 are respectively placed over different die pads DP1, DP2, DP3 as in the first embodiment, the following can be implemented: it is possible to further enhance the breakdown voltage and to further enhance the reliability of the semiconductor device.

### Fifth Embodiment

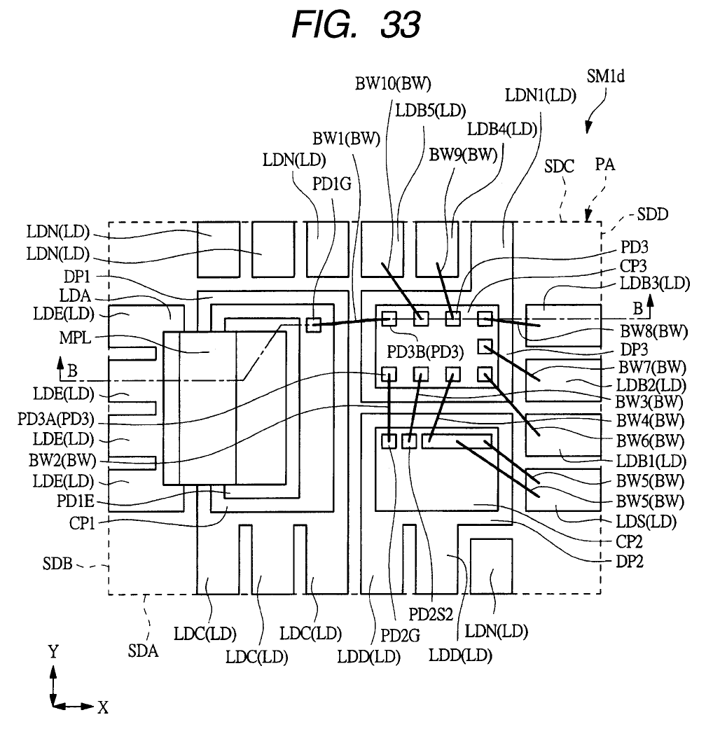

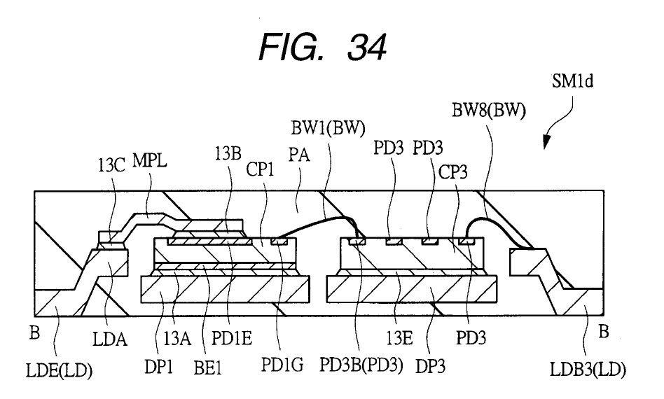

FIG. 33 is a planar transparent view of a semiconductor device SM1d in a fifth embodiment. FIG. 33 corresponds to FIG. 11 and shows an overall plan view illustrating the interior of the package PA seen through. FIG. 34 is a sectional view (lateral sectional view) of the semiconductor device SM1d and is taken in substantially the same sectional position as in FIG. 7. FIG. 34 substantially corresponds to a sectional view of the semiconductor device SM1d taken in the position of line B-B of FIG. 33. A top view and a bottom view of the semiconductor device SM1d in this embodiment are respectively the same as FIG. 4 and FIG. 5 and they will be omitted here.

The comparison of FIG. 33 and FIG. 34 with FIG. 11 and FIG. 7 reveals that the semiconductor device SM1d in this embodiment illustrated in FIG. 33 and FIG. 34 is different from the semiconductor device SM1 in the first embodiment in that: the pad electrode PD3B of the semiconductor chip CP3 and the pad electrode PD1G for gate of the semiconductor chip CP1 are directly coupled with each other through (a single or multiple) wires BW1. The semiconductor device SM1d in this embodiment is substantially the same as the semiconductor device SM1 in the first embodiment in the other respects in configuration and functions and description will be given mainly to the difference.

In the semiconductor device SM1 in the first embodiment, the pad electrode PD3B of the semiconductor chip CP3 is electrically coupled to the lead LDB6 through the wire BW11; and the pad electrode PD1G for gate of the semiconductor chip CP1 is electrically coupled to the lead LDG through the wire BW1. For this reason, IGBT driving voltage generated at the drive circuit 4b in the semiconductor chip CP3 and outputted from the pad electrode PD3B of the semiconductor chip CP3 is transmitted as follows: it is once outputted from the lead LDB6 of the semiconductor device SM1 to outside the semiconductor device SM1; it is inputted again to the lead LDG of the semiconductor device SM1 by way of the resistor R1 external to the semiconductor device SM1; and then it is inputted to the pad electrode PD1G for gate of the semiconductor chip CP1. In this case, the resistor R1 can be provided outside the semiconductor device SM1; therefore, the resistance of the resistor R1 can be adjusted externally to the semiconductor device SM1.

In the semiconductor device SM1d in this embodiment, meanwhile, the pad electrode PD3B of the semiconductor chip CP3 is not coupled to a lead LD (lead LD equivalent to the lead LDB6) through a wire BW. At the same time, the pad electrode PD1G for gate of the semiconductor chip CP1 is not coupled to a lead LD (lead LD equivalent to the lead LDG) through a wire BW. In this embodiment, instead, the pad electrode PD3B of the semiconductor chip CP3 and the pad electrode PD1G for gate of the semiconductor chip CP1 are directly tied and electrically coupled with each other only through (a single or multiple) wires BW.

For this reason, in the semiconductor device SM1d in this embodiment, the following measure is taken with respect to the leads LD in positions corresponding to the leads LDB6, LDG of the semiconductor device SM1 in the first embodiment: neither of the leads LD is electrically coupled with a pad electrode or back surface electrode of any of the semiconductor chips CP1, CP2, CP3. Therefore, they are unnecessary leads (non-contact leads) LDN in terms of electricity. The wire BW11 used in the first embodiment is not placed in this embodiment and the relation of coupling of the wire BW1 differs between the first embodiment and this embodiment. More specific description will be given. In the first embodiment, the wire BW1 ties together the lead LDG and the pad electrode PD1G for gate of the semiconductor chip CP1. In this embodiment, meanwhile, the wire BW1 ties together the pad electrode PD3B of the semiconductor chip CP3 and the pad electrode PD1G for gate of the semiconductor chip CP1. In this embodiment, the resistor R1 is formed in the semiconductor chip CP3. In this embodiment, specifically, not only the control circuit 4a and the drive circuit 4b but also the resistor R1 is formed in the semiconductor chip CP3.

In this embodiment, for this reason, IGBT driving voltage generated at the drive circuit 4b in the semiconductor chip CP3 is transmitted as follows: it is outputted from the pad electrode PD3B of the semiconductor chip CP3 by way of the resistor R1 internal to the semiconductor chip CP3; and it is inputted to the pad electrode PD1G for gate of the semiconductor chip CP1 through the wire BW1 (the wire BW1 coupling the pad electrode PD3B and the pad electrode PD1G together). (That is, it is inputted to the gate electrode of the MOSFET 3 in the semiconductor chip CP1.) In this embodiment, in other words, the IGBT driving voltage outputted from the pad electrode PD3B of the semiconductor chip CP3 is not outputted to outside the semiconductor device SM1d. Instead, it is inputted to the pad electrode PD1G for gate of the semiconductor chip CP1 by way of a conducting path (that is, the wire BW1 coupling the pad electrode PD3B and the pad electrode PD1 together) in the package PA.

The other respects in the configuration of the semiconductor device SM1d in this embodiment are substantially the same as in that of the semiconductor device SM1 in the first embodiment and the description thereof will be omitted. The relation of coupling and functions of the semiconductor device SM1d in the light emitting device 1 are the same as those of the semiconductor device SM1 in the first embodiment, except that the resistance element R1 is embedded in the semiconductor device SM1d.

In this embodiment, it is unnecessary to provide the resistor R1 externally to the semiconductor device SM1d. Therefore, the following can be implemented as compared with cases where the resistor R1 is comprised of the wiring of the circuit board PCB1, a component placed over the circuit board PCB1, or the like: the area of the circuit board PCB1 can be reduced and the light emitting device 1 can be further reduced in size (area). In addition, the following measure can also be taken: ROM (Read Only Memory) is embedded in the semiconductor chip CP3 and the electrical resistivity of the resistor R1 provided in the semiconductor chip CP3 can be adjusted with respect to each model of the semiconductor device SM1d.

In the above description of this embodiment, the following case has been taken as an example: a case where, unlike the first embodiment, the pad electrode PD3B of the semiconductor chip CP3 and the pad electrode PD1G for gate of the semiconductor chip CP1 are directly tied and electrically coupled together only through (a single or multiple) wires BW. The above method is not limited to this and is applicable to any of the first to fourth embodiments described above and the sixth to 12th embodiments described later.

### Sixth Embodiment

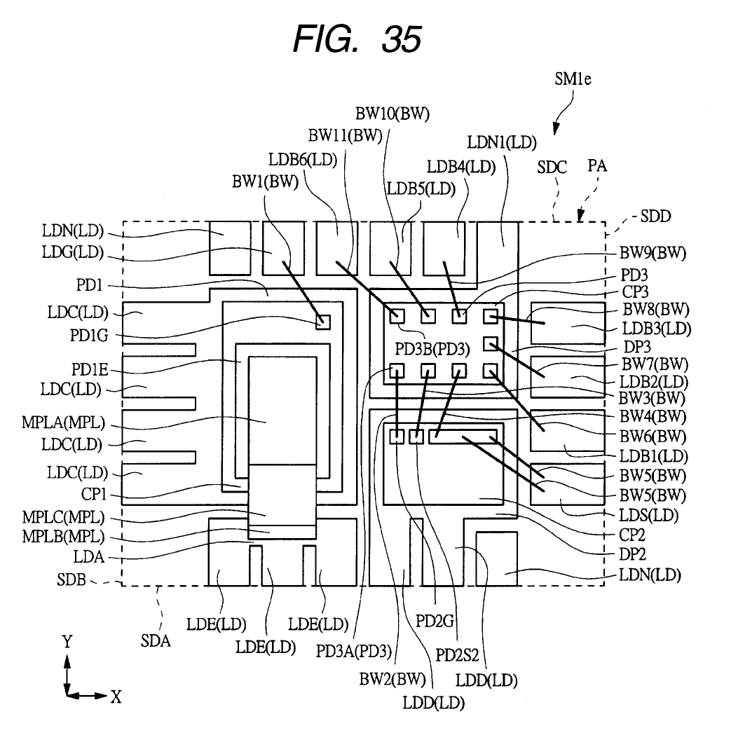

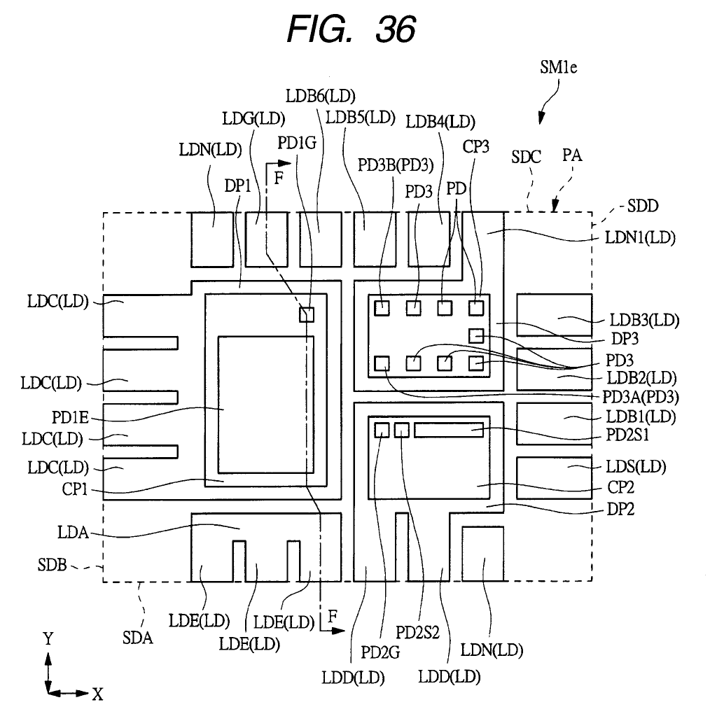

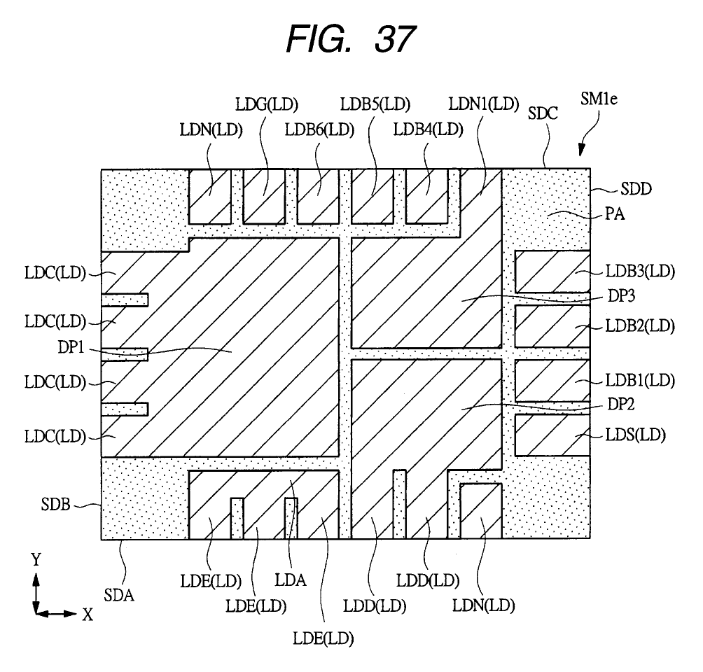

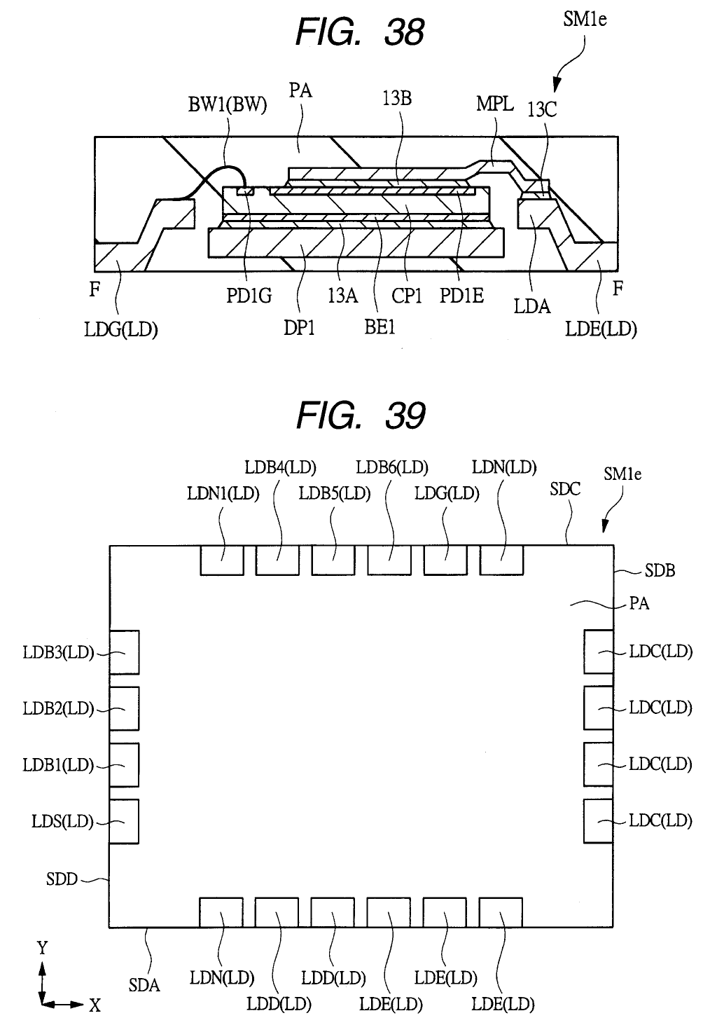

FIG. 35 is a planar transparent view of a semiconductor device SM1e in a sixth embodiment. FIG. 35 corresponds to FIG. 11 and shows an overall plan view illustrating the interior of the package PA seen through. FIG. 36 is a planar transparent view of the semiconductor device SM1e in FIG. 35 with the metal plate MPL and the wires BW further removed (seen through) and corresponds to FIG. 12. FIG. 37 is a planar transparent view of the semiconductor device SM1e in FIG. 36 with the semiconductor chips CP1, CP2, CP3 further removed (seen through) and corresponds to FIG. 13. Though FIG. 37 is a plan view, in FIG. 37, the die pads DP1, DP2, DP3, lead wiring LDA, and leads LD are hatched with oblique lines and the material (resin material) comprising the package PA is hatched with dots to facilitate visualization. FIG. 38 is a sectional view (lateral sectional view) of the semiconductor device SM1e and substantially corresponds to a sectional view of the semiconductor device SM1e taken in the position of line F-F of FIG. 36. FIG. 39 is a bottom view (back side back view) of the semiconductor device SM1e and corresponds to FIG. 5. A top view of the semiconductor device SM1e in this embodiment is the same as in FIG. 4 and it will be omitted here.

The comparison of FIG. 35 to FIG. 39 with FIG. 11 to FIG. 13, FIG. 6, and FIG. 5 reveals the following: the semiconductor device SM1e in this embodiment illustrated in FIG. 35 to FIG. 39 is different from the semiconductor device SM1 in the first embodiment in that: the leads LDE for emitter are arranged on the side SDA of the back surface of the package PA; and the leads LDC for collector are arranged on the side SDB of the back surface of the package PA. The semiconductor device SM1e in this embodiment is substantially the same as the semiconductor device SM1 in the first embodiment in the other respects in configuration and functions and description will be given mainly to the difference.

In the semiconductor device SM1 in the first embodiment, the following measure is taken: the leads LDC coupled to the collector of the IGBT 2 are arranged on the side SDA on which the leads LDD coupled to the drain of the MOSFET 3 are arranged in the back surface of the package PA. The leads LDE coupled to the emitter of the IGBT 2 are arranged along the side SDB of the back surface of the package PA and none of the leads LDC, LDD, LDS, LDB1 to LDB6 other than the leads LDE for emitter is placed on this side SDB.

In the semiconductor device SM1e in this embodiment, meanwhile, the following is measure is taken: the leads LDE coupled to the emitter of the IGBT 2 are arranged on the side SDA on which the leads LDD coupled to the drain of the MOSFET 3 are arranged in the back surface of the package PA. The leads LDC coupled to the collector of the IGBT 2 are arranged along the side SDB of the back surface of the package PA and none of the leads LDE, LDD, LDS, LDB1 to LDB6 other than the leads LDC for collector is placed on this side SDB.

The other respects in the configuration of the semiconductor device SM1e are substantially the same as in that of the semiconductor device SM1 in the first embodiment and the description thereof will be omitted. The relation of coupling and functions of the semiconductor device SM1e in the light emitting device 1 are the same as those of the semiconductor device SM1 in the first embodiment.

The leads LDE for the emitter of the IGBT 2 have ground potential (reference potential, GND potential, grounding potential) coupled thereto. The leads LDC for the collector of the IGBT 2 have high voltage arising from the charging voltage of the main capacitor CM applied thereto when the xenon tube XC emits light. For this reason, the potential difference (in absolute value) between the leads LDC for collector and the leads LDD for drain is larger than the potential difference (in absolute value) between the leads LDE for emitter and the leads LDD for drain. For this reason, the potential difference between leads LD arranged on the same side among the sides SDA, SDB, SDC, SDD can be reduced by taking the following measure as in this embodiment: no lead LDC for collector is placed on the side SDA on which the leads LDD for drain are arranged and the leads LDE for emitter are arranged there; and the leads LDC for collector are arranged on the side SDB on which none of the leads LDE, LDD, LDS, LDB1 to LDB6 is placed. As a result, it is possible to further enhance the breakdown voltage and to further enhance the reliability of the semiconductor device SM1e.

This embodiment is applicable not only to the first embodiment mentioned above but also to any of the first to fifth embodiments described above and the seventh to 12th embodiments described later.

### Seventh Embodiment

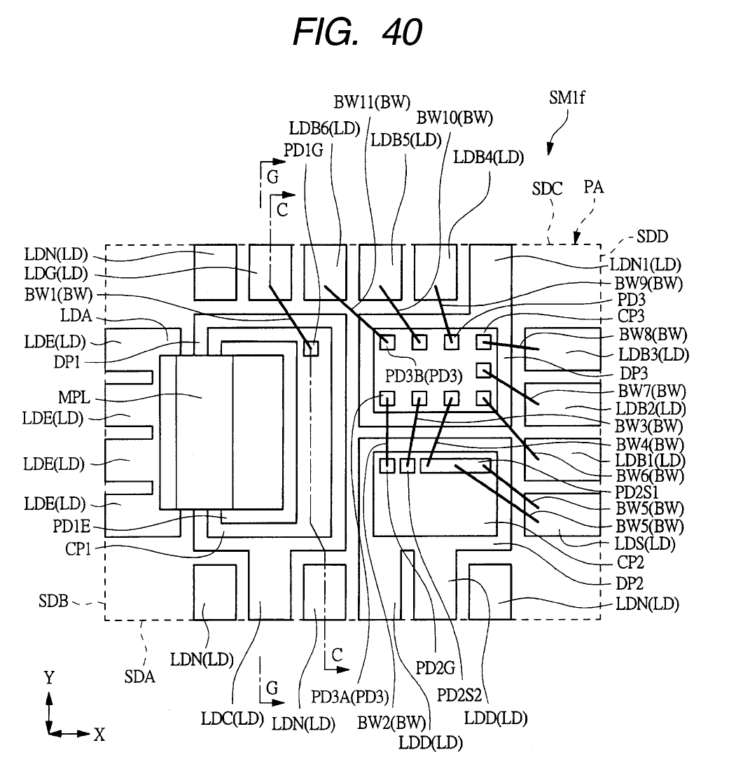

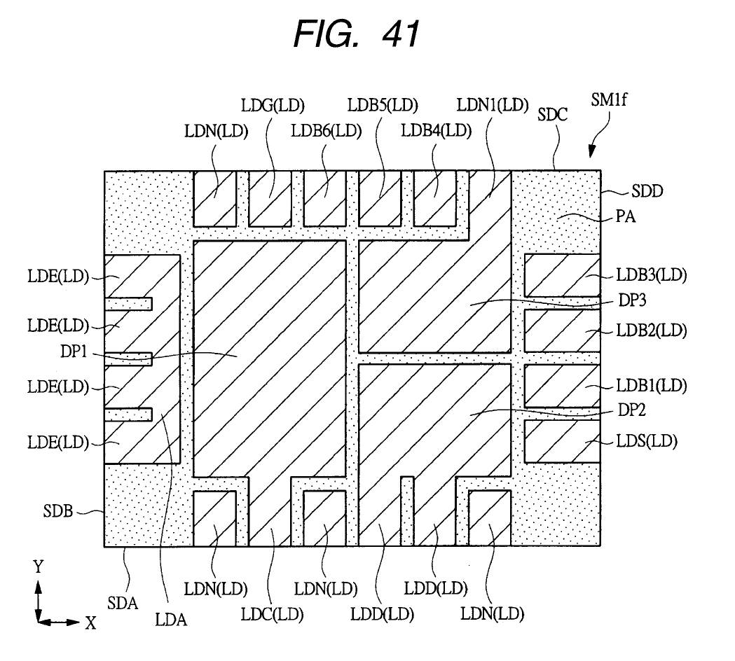

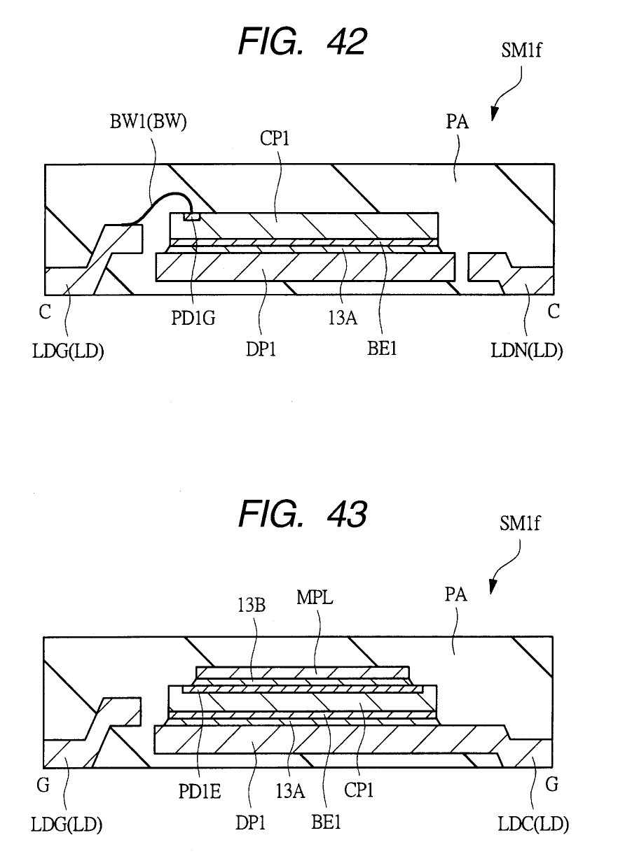

FIG. 40 is a planar transparent view of a semiconductor device SM1f in a seventh embodiment. FIG. 40 corresponds to FIG. 11 and shows an overall plan view illustrating the interior of the package PA seen through. FIG. 41 is a planar transparent view of the semiconductor device SM1f in FIG. 40 with the metal plate MPL, wires BW, and semiconductor chips CP1, CP2, CP3 further removed (seen through) and corresponds to FIG. 13. Though FIG. 41 is a plan view, in FIG. 41, the die pads DP1, DP2, DP3, lead wiring LDA, and leads LD are hatched with oblique lines and the material (resin material) comprising the package PA is hatched with dots to facilitate visualization. FIG. 42 and FIG. 43 are sectional views (lateral sectional views) of the semiconductor device SM1f. FIG. 42 is taken in substantially the same sectional position as in FIG. 8 and FIG. substantially corresponds to a sectional view of the semiconductor device SM1f taken in the position of line C-C of FIG. 40. FIG. 43 substantially corresponds to a sectional view taken in the position of line G-G of FIG. 40. A top view and a bottom view of the semiconductor device SM1f in this embodiment are respectively the same as FIG. 4 and FIG. 5 and they will be omitted here.

The comparison of FIG. 40 to FIG. 43 with FIG. 11, FIG. 13, and FIG. 6 reveals that the semiconductor device SM1f in this embodiment is different from the semiconductor device SM1 in the first embodiment in that: the following measure is taken with respect to the arrangement of multiple leads LD arranged along the side SDA of the back surface of the package PA: non-contact leads LDN neither of which is electrically coupled with a pad electrode or back surface electrode of any of the semiconductor chip CP1, CP2, CP3 are placed next to the lead LDC for collector. The semiconductor device SM1f in this embodiment is substantially the same as the semiconductor device SM1 in the first embodiment in the other respects in configuration and functions and description will be given mainly to the difference.

In the first embodiment, the following measure is taken with respect to the arrangement of leads LD arranged along the side SDA of the back surface of the package PA: multiple leads LDD for drain are arranged next to multiple arranged leads LD for collector. The leads LD for collector and the leads LDD for drain are arranged adjacently to each other.

In the semiconductor device SM1f in this embodiment, meanwhile, the following measure is taken with respect to the arrangement of leads LD arranged along the side SDA of the back surface of the package PA: non-contact leads LDN are arranged next to the lead LDC for collector. More specific description will be given. In the semiconductor device SM1f in this embodiment, one lead LDC is integrally coupled to the die pad DP1. Neither of both leads LD adjacent to the lead LDC is coupled to the die pad DP1 and they are leads LDN (that is, non-contact leads LDN) neither of which is electrically coupled to an electrode of any of the semiconductor chips CP1, CP2, CP3. Since the non-contact leads LDN are placed next to the lead LDC for collector, the following takes place even when both the lead LDC for collector and the leads LDD for drain are arranged along the side SDA of the back surface of the package PA: a non-contact lead LDN is placed between the lead LDC for collector and the leads LDD for drain. As the result of the non-contact lead LDN being placed between the lead LDC for collector and the leads LDD for drain, the distance (spacing) between the lead LDC for collector and the leads LDD for drain can be increased. Therefore, it is possible to enhance the breakdown voltage between the lead LDC for collector and the leads LDD for drain. For this reason, it is possible to sufficiently ensure the breakdown voltage between the lead LDC for collector and the leads LDD for drain even when high voltage is applied to the lead LDC for collector when the xenon tube XC emits light. Thus the reliability of the semiconductor device SM1f can be further enhanced.

The highest voltage is applied to the lead LDC for collector among the leads LDC, LDE, LDD, LDS, LDB1 to LDB6. For this reason, the following measure can be taken when any of the other leads LDE, LDD, LDS, LDB1 to LDB6 is placed on the side of the package PA on which the lead LDC for collector is placed (this side is the side SDA in the example in FIG. 40 and FIG. 41): this embodiment is applied and a non-contact lead LDN is placed between the lead LDC for collector and the other lead (any of the leads LDE, LDD, LDS, LDB1 to LDB6) arranged on the same side. This produces the profound effect of enhancing the breakdown voltage between leads LD.

As described in relation to the first embodiment, it is desired to place no lead LDB1 to LDB6 on the side (side SDA in this example) on which the lead LDC for collector is placed. From this viewpoint, what can be placed next to the lead LDC for collector is any of the leads LDE, LDD, LDS. For this reason, the following measure can be taken when any of the leads LDE, LDD, LDS is placed on the side of the package PA on which the lead LDC for collector is placed (this side is the side SDA in the example in FIG. 40 and FIG. 41): this embodiment is applied and a non-contact lead LDN is placed between the lead LDC for collector and another lead (any of the leads LDE, LDD, LDS) arranged on the same side. This produces the profound effect of preventing malfunction of the semiconductor chip CP3 and enhancing the breakdown voltage between leads LD.

This embodiment is applicable not only to the first embodiment mentioned above but also to any of the first to sixth embodiments described above and the eighth to 12th embodiments described later.

### Eighth Embodiment

With respect to this embodiment, description will be given to an example of the configuration of the semiconductor chip CP2 used in the first to seventh embodiments.

In the first and third to seventh embodiments, the semiconductor chip CP2 is a semiconductor chip in which a vertical MOSFET is formed. The vertical MOSFET cited here corresponds to MOSFET in which source-drain current flows in the direction of the thickness of a semiconductor substrate (direction substantially perpendicular to the principal surface of the semiconductor substrate). A semiconductor chip in which a vertical MOSFET is formed is used for the semiconductor chip CP2 in the first and third to seventh embodiments. This is intended to draw the drain of the MOSFET 3 from the back surface electrode BE2 of the semiconductor chip CP2 and easily couple it to the die pad DP2.

In the second embodiment, meanwhile, the semiconductor chip CP2 is a semiconductor chip in which a horizontal MOSFET is formed. The horizontal MOSFET cited here corresponds to MOSFET in which source-drain current flows in the lateral direction of a semiconductor substrate (direction substantially parallel with the principal surface of the semiconductor substrate). A semiconductor chip in which a horizontal MOSFET is formed is used for the semiconductor chip CP2 in the second embodiment. This is intended to draw the drain of the MOSFET 3 from the pad electrode PD2D of the semiconductor chip CP2 and easily couple it to a lead LDD.

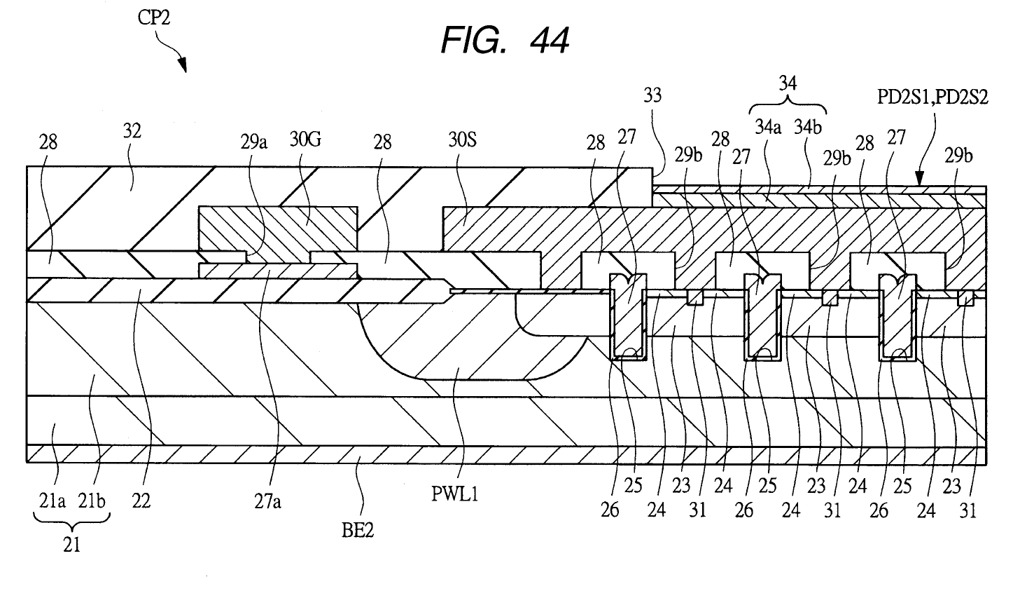

Description will be given to an example of the configuration of the semiconductor chip CP2 in the first and third to seventh embodiments with reference to FIG. 44.

FIG. 44 is a substantial part sectional view of the semiconductor chip CP2 in the first and third to seventh embodiments.

The MOSFET 3 is formed in the principal surface of a semiconductor substrate (hereafter, simply referred to as substrate) 21 comprising the semiconductor chip CP2. As illustrated in FIG. 44, the substrate 21 includes: a substrate body (semiconductor substrate, semiconductor wafer) 21a comprised of, for example, n⁺-type single-crystal silicon or the like doped with arsenic (As); and an epitaxial layer (semiconductor layer) 21b comprised of, for example, a n⁻-type silicon single crystal formed over the principal surface of the substrate body 21a. For this reason, the substrate 21 is a so-called epitaxial wafer. In the principal surface of the epitaxial layer 21b, there is formed a field insulating film (element isolation region) 22 comprised of, for example, silicon oxide or the like. In the active region encircled with this field insulating film 22 and a p-type well PWL1 positioned thereunder, there are formed multiple unit transistor cells comprising the MOSFET 3 and the MOSFET 3 is formed by coupling these unit transistor cells in parallel. Each unit transistor cell is formed of, for example, an n-channel power MOS with a trench gate structure.

The substrate body 21a and the epitaxial layer 21b function as the drain region of each unit transistor cell. Over the back surface of the substrate 21 (semiconductor chip CP2), there is formed the back surface electrode BE2 for drain electrode. This back surface electrode BE2 is formed by stacking, for example, a titanium (Ti) layer, a nickel (Ni) layer, and a gold (Au) layer over the back surface of the substrate 21 in this order.

A p-type semiconductor region 23 formed in the epitaxial layer 21b functions as the channel formation region for each unit transistor cell. A n⁺-type semiconductor region 24 formed in the upper part of the p-type semiconductor region 23 functions as the source region of each unit transistor cell. Therefore, the semiconductor region 24 is a semiconductor region for source.

In the substrate 21, there are formed trenches 25 extended from its principal surface in the direction of the thickness of the substrate 21. Each trench 25 is so formed that it penetrates the n⁺-type semiconductor region 24 and the p-type semiconductor region 23 from the upper surface of the n⁺-type semiconductor region and is terminated in the epitaxial layer 21b positioned thereunder. Over the bottom surface and lateral surface of each trench 25, there is formed a gate oxide film 26 comprised of, for example, silicon oxide. In each trench 25, a gate electrode 27 is buried with the gate oxide film 26 in-between. The gate electrode 27 is comprised of, for example, a polycrystalline silicon film added with an n-type impurity (for example, phosphorus). The gate electrode 27 functions as the gate electrode of the unit transistor cell. Also over the field insulating film 22, there is formed a wiring portion 27a for drawing gate comprised of a conductive film in the same layer as the gate electrodes 27 are. The gate electrodes 27 and the wiring portion 27a for drawing gate are integrally formed and electrically coupled to each other. In an area not depicted in the sectional view in FIG. 44, the gate electrodes 27 and the wiring portion 27a for drawing gate are integrally coupled with each other. The wiring portion 27a for drawing gate is electrically coupled with a gate wiring 30G through a contact hole 29a formed in an insulating film 28 covering it.

Meanwhile, a source wiring 30S is electrically coupled with the n⁺-type semiconductor region 24 for source through contact holes 29b formed in the insulating film 28. The source wiring 30S is electrically coupled to p⁺-type semiconductor regions 31 formed between the adjoining n⁺-type semiconductor regions 24 in the upper part of the p-type semiconductor region 23. It is then electrically coupled with the p-type semiconductor region 23 for channel formation therethrough. The gate wiring 30G and the source wiring 30S can be formed by: forming a metal film, for example, an aluminum film (or an aluminum alloy film) over the insulating film 28 in which the contact holes 29a, 29b are formed so that the contact holes 29a, 29b are filled therewith; and patterning this metal film (aluminum film or aluminum alloy film). For this reason, the gate wiring 30G and the source wiring 30S are comprised of an aluminum film, an aluminum alloy film, or the like.

The gate wiring 30G and the source wiring 30S are covered with a protective film (insulating film) 32 comprised of polyimide resin or the like. This protective film 32 is the film (insulating film) in the uppermost layer of the semiconductor chip CP2.

In part of the protective film 32, there is formed an opening 33 exposing part of the gate wiring 30G and the source wiring 30S positioned thereunder. The part of the gate wiring 30G exposed from this opening 33 is the above-mentioned pad electrode PD2G for gate and the part of the source wiring 30S exposed from the opening 33 is the above-mentioned pad electrodes PD2S1, PD2S2 for source. As mentioned above, the pad electrodes PD2S1, PD2S2 for source are separated from each other by the protective film 32 in the uppermost layer but they are electrically coupled to each other through the source wiring 30S.

Over the surfaces of the pad electrodes PD2G, PD2S1, PD2S2 (that is, the portions of the gate wiring 30G and source wiring 30S exposed at the bottom of the opening 33), a metal layer 34 may be formed sometimes by plating or the like. The metal layer 34 is formed of a laminated film of a metal layer 34a formed over the gate wiring 30G and the source wiring 30S and a metal layer 34b formed thereover. The metal layer 34a positioned underneath is comprised of, for example, nickel (Ni) and mainly has a function of suppressing or preventing the oxidation of aluminum in the gate wiring 30G and source wiring 30S positioned thereunder. The metal layer 34b positioned thereover is comprised of, for example, gold (Au) and mainly has a function of suppressing or preventing the oxidation of nickel in the metal layer 34a positioned thereunder.

In the thus configured semiconductor chip CP2, the operating current of each unit transistor of the MOSFET 3 flows as described below between the epitaxial layer 21b for drain and the n⁺-type semiconductor region 24 for source: it flows along the lateral surface of each gate electrode 27 (that is, the lateral surface of each trench 25) in the direction of the thickness of the substrate 21. That is, channels are formed along the direction of the thickness of the semiconductor chip CP2.

In the first and third to seventh embodiments, as mentioned above, the semiconductor chip CP2 is a semiconductor chip in which a vertical MOSFET is formed. In the description given with reference to FIG. 44, a case where the semiconductor chip CP2 is a semiconductor chip in which a vertical MOSFET with a trench gate structure is formed has been taken as an example. As another embodiment, the semiconductor chip CP2 may be a semiconductor chip in which a vertical MOSFET having a planar structure is formed.

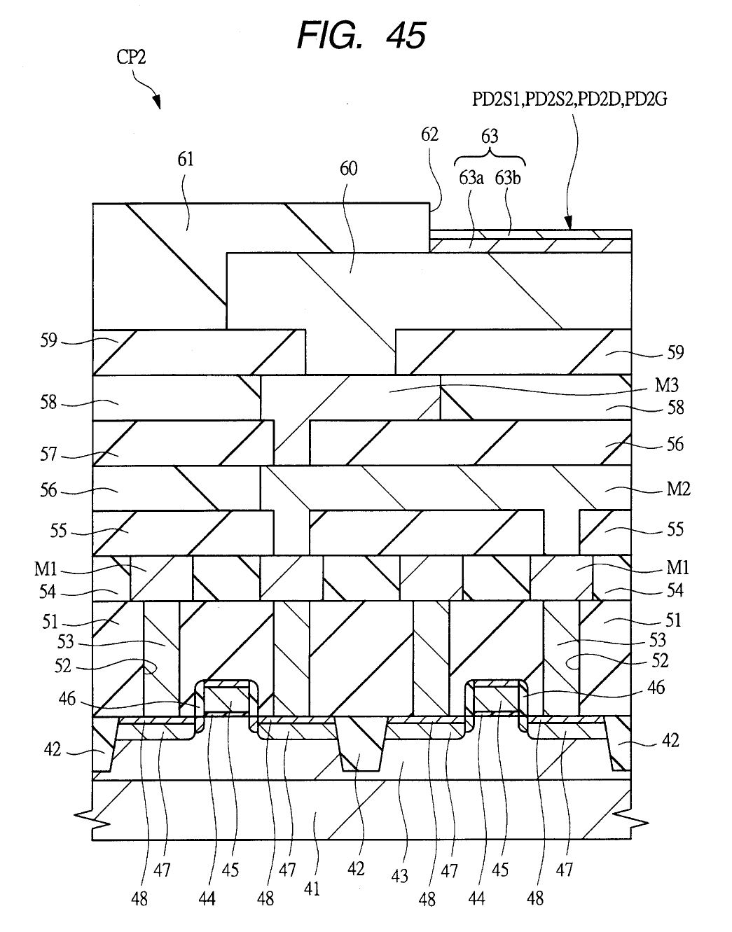

Description will be given to an example of the configuration of the semiconductor chip CP2 in the second embodiment with reference to FIG. 45.

FIG. 45 is a substantial part sectional view of the semiconductor chip CP2 in the second embodiment.

The MOSFET 3 is formed over the principal surface of a semiconductor substrate (hereafter, simply referred to as substrate) 41 comprising the semiconductor chip CP2. As illustrated in FIG. 45, the substrate 41 is comprised of p-type single-crystal silicon or the like having a specific resistance of, for example, 1 to 100 cm. Over the principal surface of the substrate 41, there is formed an element isolation region (element isolation insulating film) 42 obtained by STI (Shallow Trench Isolation) or the like.

In the substrate 41, there is formed a p-type well 43 extended from its principal surface to a predetermined depth. Over the principal surface of the p-type well 43, there are formed gate electrodes 45 comprising the gate electrode of the MOSFET 3 with a gate oxide film 44 in-between. Over the side wall of each gate electrode 45, there is formed a side wall (side wall insulating film) 46 comprised of insulator. In the regions of the p-type well 43 on both sides of each gate electrode 45, there is formed a n⁺-type semiconductor region 47 that functions as the source-drain region of the MOSFET 3.

In the superficial portions of the n⁺-type semiconductor regions 47 and gate electrodes 45, a metal silicide layer 48 is formed by salicide (self aligned silicide) or the like.

Over this substrate 41, there is formed an insulating film (interlayer insulating film) 51 so that the gate electrodes 45 and the side walls 46 are covered therewith. Contact holes (through holes) 52 are formed in the insulating film 51 and the contact holes 52 are filled with a plug 53. The bottom portion of each plug 53 is in contact with (the metal silicide layer 48 over) each n⁺-type semiconductor region 47, (the metal silicide layer 48 over) each gate electrode 45, and the like and is electrically coupled thereto.

An insulating film (interlayer insulating film) 54 is formed over the insulating film 51 with the plugs 53 embedded therein and wiring (first-layer wiring) M1 formed by single damacine is embedded in this insulating film 54. Over the insulating film 54 with the wiring M1 embedded therein, insulating films (interlayer insulating films) 55, 56 are formed in this order from bottom; and wiring (second-layer wiring) M2 formed by dual damacine is embedded in the insulating films 56, 55. Over the insulating film 56 with the wiring M2 embedded therein, insulating films (interlayer insulating films) 57, 58 are formed in this order from bottom; and wiring (third-layer wiring) M3 formed by dual damacine is embedded in the insulating films 58, 57. Over the insulating film 58 with the wiring M3 embedded therein, an insulating film (interlayer insulating film) 59 is formed and an aluminum wiring 60 as the uppermost-layer wiring is formed over this insulating film 59. A protective film (uppermost-layer protective film, insulating film) 61 is formed over the insulating film 59 so that it covers the aluminum wiring 60. Multiple unit transistors (horizontal MOSFETs in this example) comprised of a gate electrode 45, n⁺-type semiconductor region 47, gate oxide film 44, and the like are formed in the substrate 41. They are coupled in parallel by the wirings M1, M2, M3 and the aluminum wiring 60 to form the MOSFET 3.

In part of the protective film 61, there are formed openings 62 exposing part of the aluminum wiring 60 positioned thereunder. The portions of the aluminum wiring 60 exposed from these openings 62 are the above-mentioned pad electrodes PD2S1, PD2S2, PD2G, PD2D. More specific description will be given. The aluminum wiring 60 electrically coupled to the n⁺-type semiconductor region 47 for source through the plugs 53 and the wirings M1, M2, M3 is exposed from openings 62 and the pad electrodes PD2S1, PD2S2 for source are thereby formed. The aluminum wiring 60 electrically coupled to the n⁺-type semiconductor region 47 for drain through the plugs 53 and the wirings M1, M2, M3 is exposed from an opening 62 and the pad electrode PD2D for drain is thereby formed. The aluminum wiring 60 electrically coupled to the gate electrodes 45 through the plugs 53 and the wirings M1, M2, M3 is exposed from an opening 62 and the pad electrode PD2G for gate is thereby formed.

A metal layer 63 is formed by plating or the like over the surfaces of the pad electrodes PD2S1, PD2S2, PD2G, PD2D (that is, over the aluminum wiring 60 exposed at the bottom of each opening 62). The metal layer 63 is formed of a laminated film of a metal layer 63a positioned underneath and a metal layer 63b formed over the metal layer 63a. The metal layer 63a positioned underneath is comprised of, for example, nickel (Ni) and the metal layer 63b positioned above is comprised of, for example, gold (Au).

In the thus configured semiconductor chip CP2, the channel region of each unit transistor of the MOSFET 3 is formed along the principal surface of the substrate 41 under each gate electrode 45. As a result, operating current (source-drain current) flows between the n⁺-type semiconductor regions 47 (between the source and the drain) opposed to each other with this channel region in-between. A semiconductor chip in which a horizontal MOSFET is formed is used for the semiconductor chip CP2. This makes it possible to implement the following without providing an electrode (back surface electrode) in the back surface of the semiconductor chip CP2: the pad electrodes PD2S1, PD2S2 for source, pad electrode PD2G for gate, and pad electrode PD2D for drain of the MOSFET 3 are provided in the front surface of the semiconductor chip CP. In the second embodiment, as mentioned above, the semiconductor chip CP2 is a semiconductor chip in which a horizontal MOSFET is formed.

### Ninth Embodiment

With respect to this embodiment, description will be given to an example of a manufacturing method for the semiconductor device SM1 in the first embodiment.

FIG. 46 to FIG. 51 are sectional views of the semiconductor device SM1 in manufacturing process and illustrate the section corresponding to FIG. 6.

To manufacture the semiconductor device SM1, first, a lead frame integrally including the die pads DP1 to DP3, leads LD, and lead wiring LDA required to form the semiconductor device SM1 is prepared. FIG. 46 is a sectional view of the lead frame. The die pads DP1 to DP3, leads LD, and lead wiring LDA are integrally coupled to the frame (not shown) or the like of the lead frame and held thereby. Though not shown in the sectional view in FIG. 46, the die pad DP1 is coupled to the frame of the lead frame through the leads LDC formed integrally with the die pad DP1; the die pad DP2 is coupled to the frame of the lead frame through the leads LDD formed integrally with the die pad DP2; and the die pad DP3 is coupled to the frame of the lead frame through the lead LDN1 formed integrally with the die pad DP3.

Each of the semiconductor chips CP1, CP2, CP3 can be prepared by: forming required semiconductor elements and the like in a semiconductor wafer (semiconductor substrate) and then cutting the semiconductor wafer into each separated semiconductor chip by dicing or the like or any other like method. The semiconductor chips CP1, CP2, CP3 are respectively fabricated using different semiconductor wafers.

After the lead frame and the semiconductor chips CP1, CP2, CP3 are prepared, the semiconductor chips CP1, CP2, CP3 are respectively die-bonded to the die pads DP1, DP2, DP3 of the lead frame. As illustrated in FIG. 47, as a result, the semiconductor chip CP1 is bonded to the die pad DP1 through the adhesive layer 13A and the semiconductor chip CP2 is bonded to the die pad DP2 through the adhesive layer 13D. Though not shown in the sectional view in FIG. 47, the semiconductor chip CP3 is bonded to the die pad DP3 through the adhesive layer 13E.

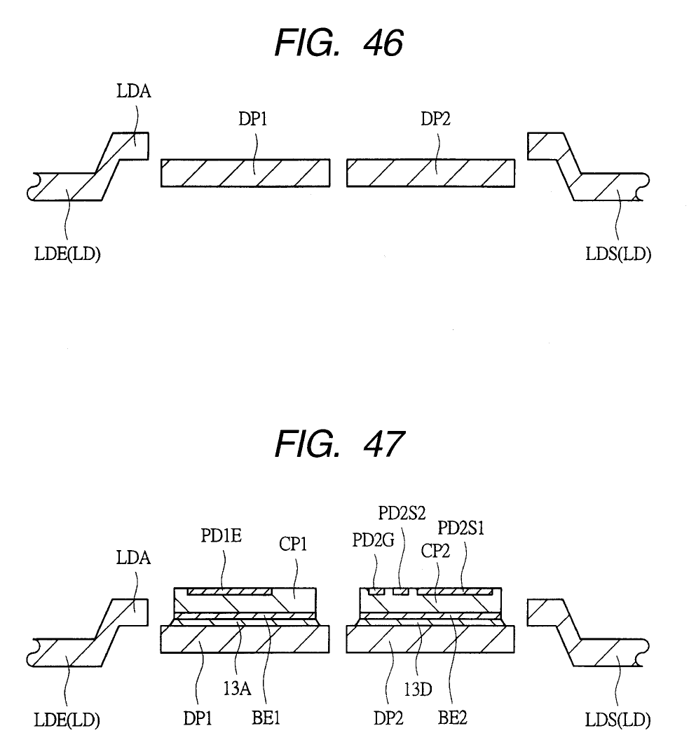

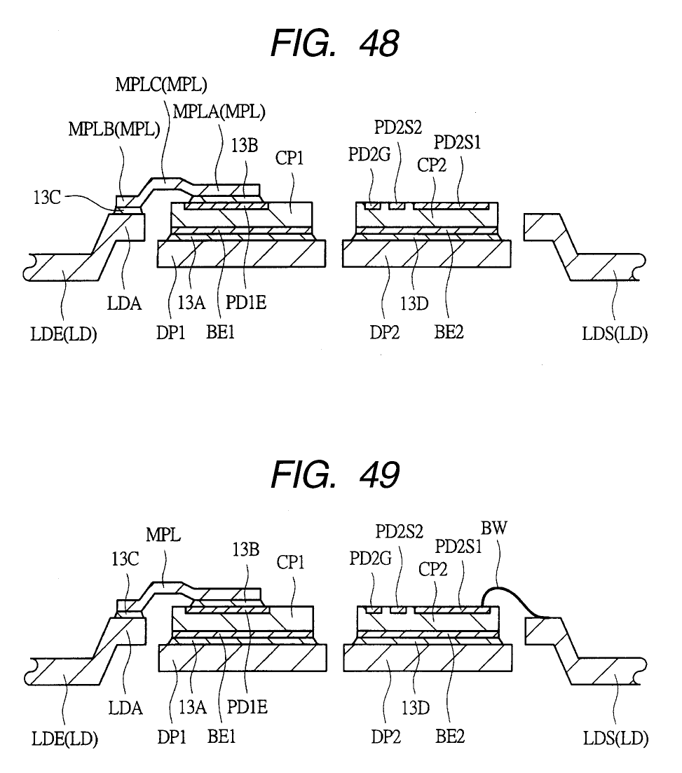

Subsequently, the metal plate MPL is placed over the semiconductor chip CP1 and the lead wiring LDA and is joined thereto. As illustrated in FIG. 48, as a result, the first portion MPLA of the metal plate MPL is joined to the pad electrode PD1E for emitter of the semiconductor chip CP1 through the adhesive layer 13B; and the second portion MPLB of the metal plate MPL is joined to the lead wiring LDA through the adhesive layer 13C.

Subsequently, a wire bonding step (step for bonding wires BW) is carried out. The pad electrodes PD1G, PD2S1, PD3 of the semiconductor chips CP1, CP2, CP3 and respective leads LD to be electrically coupled thereto are thereby coupled together through wires BW. Further, the pad electrodes PD1G, PD2S1, PD2S2 of the semiconductor chip CP2 and respective pad electrodes PD3 of the semiconductor chip CP3 to be electrically coupled thereto are coupled together through wires BW. FIG. 49 is a sectional view obtained after the wire bonding step.

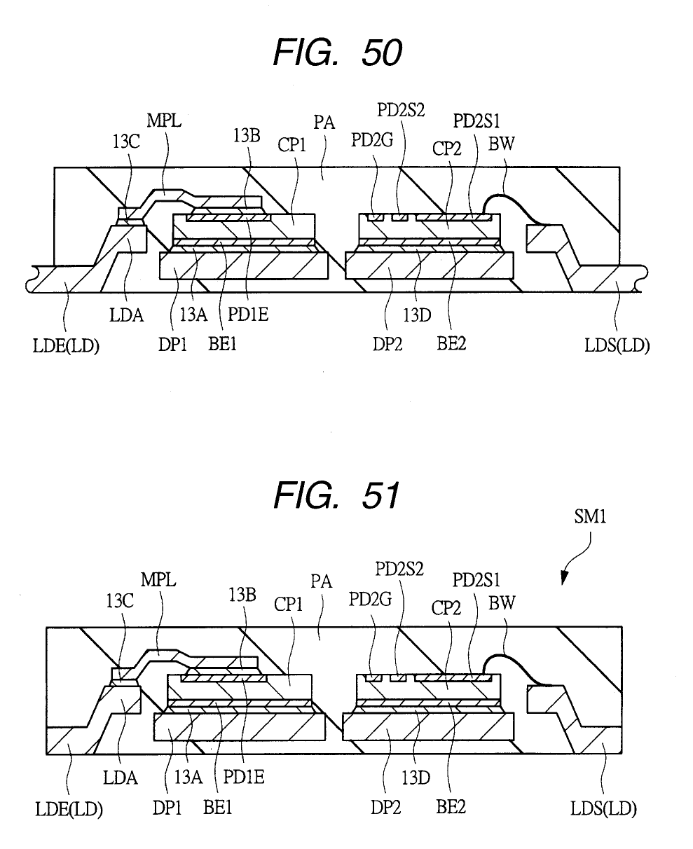

Subsequently, a molding step (resin sealing step, for example, transfer molding step) is carried out. The semiconductor chips CP1, CP2, CP3, leads LD, lead wiring LDA, die pads DP1, DP2, DP3, metal plate MPL, and wires BW are thereby sealed with the resin comprising the package PA. FIG. 50 is a sectional view obtained after the molding step. After this molding step, a plating layer (solder plating layer) may be formed over the surface of each lead LD of the lead frame exposed from the package PA.

Subsequently, the lead frame (leads LD) protruded from the package PA is cut and removed. FIG. 51 is a sectional view obtained after this cutting step. The semiconductor device SM1 can be manufactured as mentioned above.

In the above description of this embodiment, a case where the semiconductor device SM1 in the first embodiment is manufactured has been taken as an example. However, the semiconductor devices SM1a to SM1f in the second to seventh embodiments can also be manufactured in substantially the same manner.

### 10th Embodiment

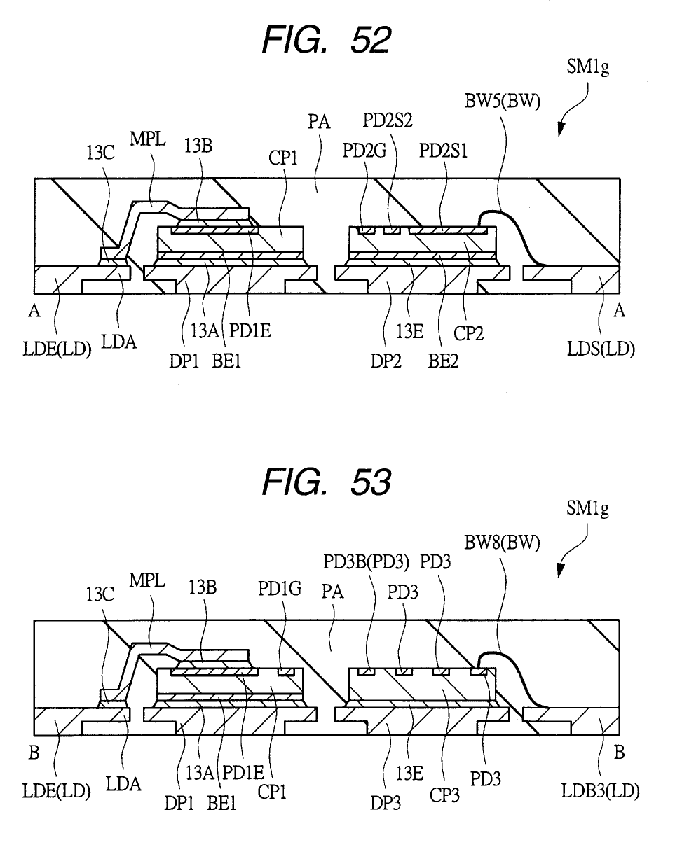

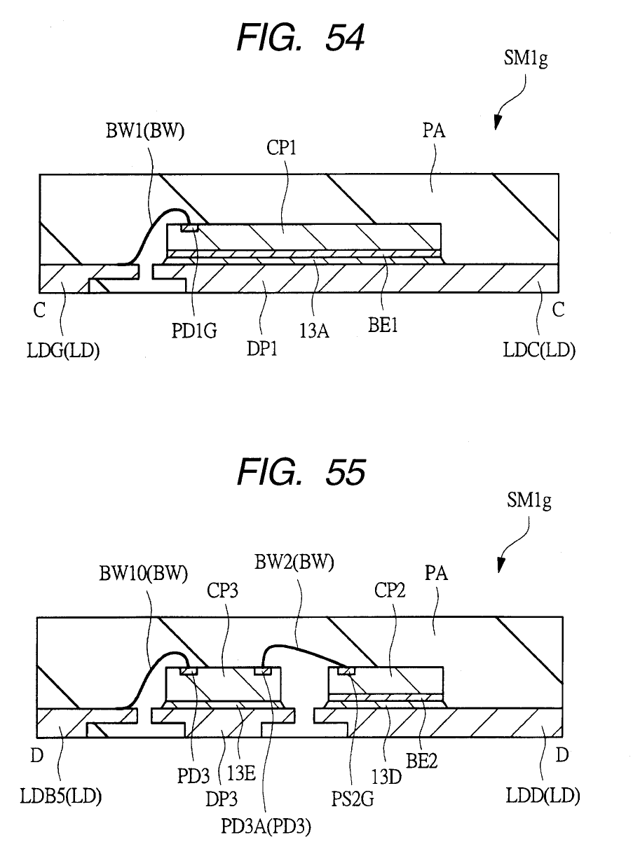

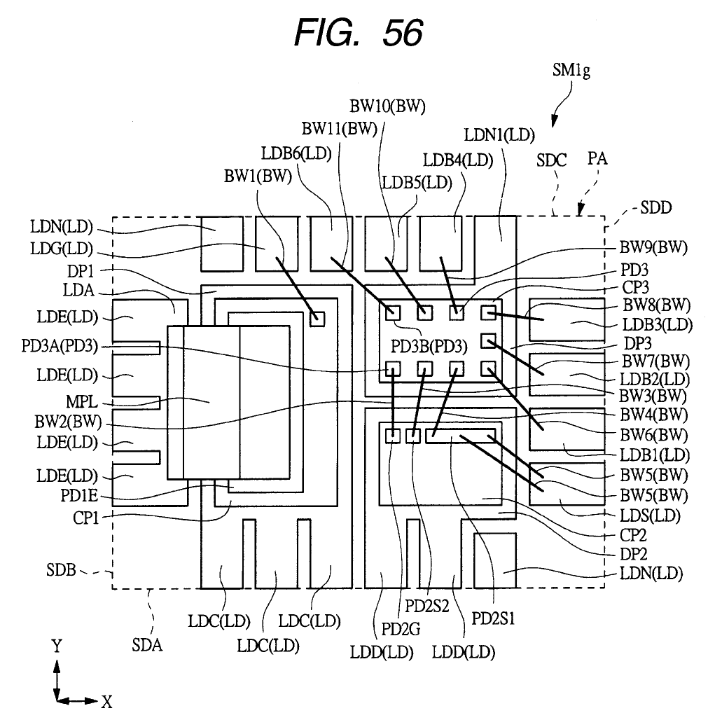

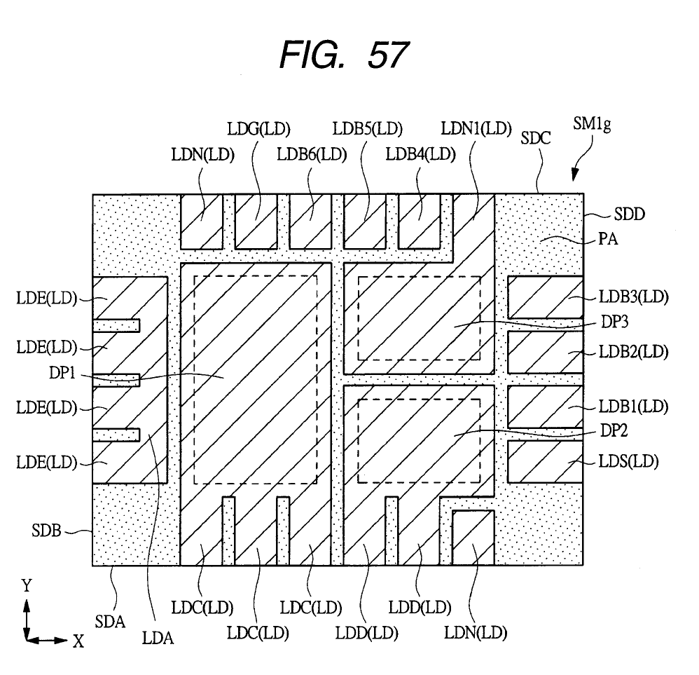

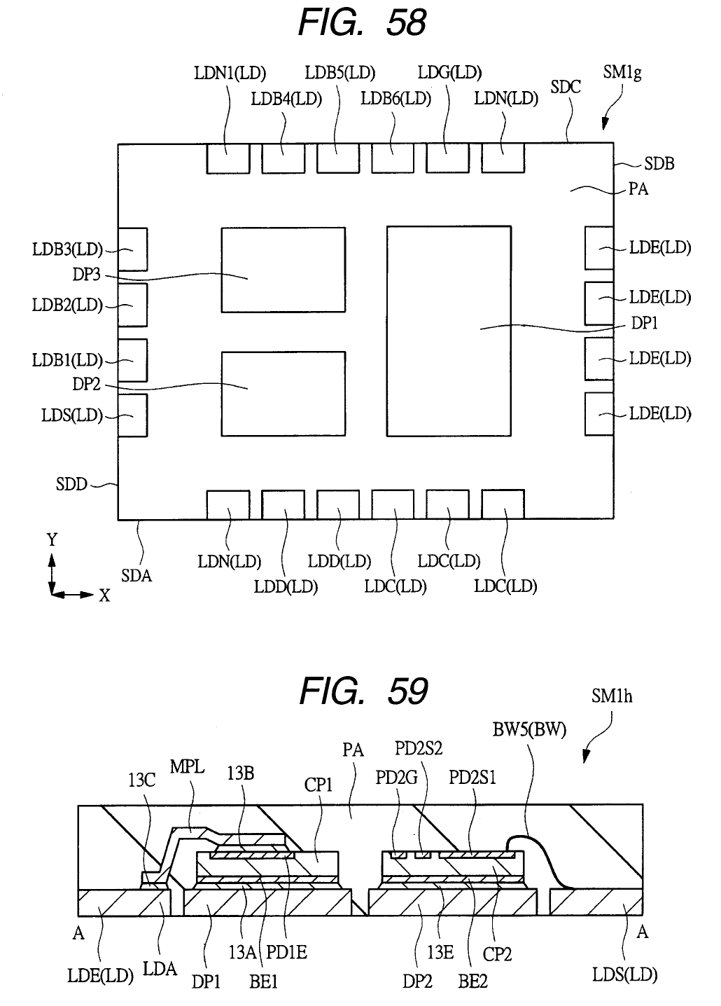

FIG. 52 to FIG. 55 are sectional views of a semiconductor device SM1g in a 10th embodiment and respectively taken in substantially the same sectional position as in FIG. 6 to FIG. 9. FIG. 56 is a planar transparent view of the semiconductor device SM1g, corresponding to FIG. 11, and shows an overall plan view illustrating the interior of the package PA seen through. FIG. 57 is a planar transparent view of the semiconductor device SM1g in FIG. 56 with the metal plate MPL, wires BW, and semiconductor chips CP1, CP2, CP3 further removed (seen through) and corresponds to FIG. 13. Though FIG. 57 is a plan view, in FIG. 57, the die pads DP1, DP2, DP3, lead wiring LDA, and leads LD are hatched with oblique lines and the material (resin material) comprising the package PA is hatched with dots to facilitate visualization. In FIG. 57, the areas corresponding to the under surfaces of the die pads DP1, DP2, DP3 are indicated by broken lines. As illustrated in FIG. 58, the under surfaces of the die pads DP1, DP2, DP3 positioned in the planar areas encircled with these broken lines are exposed in the back surface of the package PA. FIG. 58 is a bottom view (back side back view) of the semiconductor device SM1g and corresponds to FIG. 5. A top view of the semiconductor device SM1g in this embodiment is the same as FIG. 4 and it will be omitted here.

In the semiconductor devices SM1 to SM1f in the first to seventh embodiments, the die pads DP1, DP2, DP3, DP4, DP5, DP6 are entirely sealed in the package PA and none of them is exposed even in the back surface of the package PA. In the semiconductor devices SM1 to SM1f in the first to seventh embodiments, for this reason, the leads LD are exposed but each of the die pads DP1 to DP6 is not exposed from the package PA. The under surface of each of the die pads DP1 to DP6 is not exposed, especially, in the back surface of the package PA as the mounting surface of each of the semiconductor devices SM1 to SM1f. (The under surface of each die pad is its surface on the opposite side to the side where the semiconductor chips CP1 to CP3 are placed. As mentioned above, the back surface electrode BE1 of the semiconductor chip CP1 (that is, the collector electrode of the IGBT 2) is electrically coupled to the die pad DP1, DP4, DP6. Therefore, high voltage (applied voltage to the lead LDC for collector) is applied to the die pad DP1, DP4, DP6 and a large current is passed in conjunction with light emission (discharge) of the xenon tube XC. In the semiconductor devices SM1 to SM1f in the first to seventh embodiments, each of the die pads DP1 to DP6 is not exposed from the package PA. Therefore, even though high voltage is applied to the die pad DP1, DP4, DP6 and a large current is passed in conjunction with light emission of the xenon tube XC, it is possible to prevent it from having influence on the other die pads DP2, DP3, DP5 and the leads LD. For this reason, in the semiconductor devices SM1 to SM1f in the first to seventh embodiments, the following can be implemented by exposing no die pad DP1 to DP6 in the back surface of the package PA: it is possible to further enhance the breakdown voltage of the leads LD and to further enhance the reliability of the semiconductor device.

In the semiconductor device SM1g in this embodiment illustrated in FIG. 52 to FIG. 58, meanwhile, the under surface of each of the die pads DP1, DP2, DP3 is exposed in the back surface of the package PA. (The under surface of each die pad is its surface on the opposite side to the side where the semiconductor chips CP1 to CP3 are placed.) In this embodiment, it is unnecessary to cover the under surfaces of the die pads DP1, DP2, DP3 with the resin comprising the package PA; therefore, it is possible to reduce the thickness of the package PA and thus the thickness of the semiconductor device SM1g.

For this reason, the following measure can be taken on a case-by-case basis: when a high priority is given to the enhancement of the breakdown voltage of the semiconductor device, each of the die pads DP1 to DP6 is not exposed in the back surface of the package PA as in the first to seventh embodiments; and when a high priority is given to the reduction of the thickness of the semiconductor device, the die pads DP1 to DP6 are exposed in the back surface of the package PA as in this embodiment.

Though the under surfaces of the die pads DP1 to DP3 are exposed in the back surface of the package PA in this embodiment, however, the following measure is taken to minimize its influence on breakdown voltage as seen from FIG. 52 to FIG. 58: the dimensions (area) of the under surface of each of the die pads DP1 to DP3 exposed in the back surface of the package PA are made smaller than the dimensions (area) of the upper surface of each of the die pads DP1 to DP3 over which the semiconductor chips CP1 to CP3 are placed.

More specific description will be given. In this embodiment, the following measure is taken with respect to the under surface of the die pad DP1 exposed in the back surface of the package PA: it is made smaller in area than the upper surface of the die pad DP1 over which the semiconductor chip CP1 is placed and is embraced in the upper surface of the die pad DP1 in a plane. The following measure is taken with respect to the under surface of the die pad DP2 exposed in the back surface of the package PA: it is made smaller in area than the upper surface of the die pad DP2 over which the semiconductor chip CP2 is placed and is embraced in the upper surface of the die pad DP2 in a plane. The following measure is taken with respect to the under surface of the die pad DP3 exposed in the back surface of the package PA: it is made smaller in area than the upper surface of the die pad DP3 over which the semiconductor chip CP3 is placed and is embraced in the upper surface of the die pad DP3 in a plane. Specifically, the die pads DP1, DP2, DP3 are half etched from the under surface side when they are fabricated (the lead frame is fabricated). As a result, the peripheral portion of each of the die pads DP1 to DP3 is thinner than its central portion. The under surface of each of the die pads DP1 to DP3 is exposed from the package PA at its thicker central portion and its thinner peripheral portion is covered with the resin comprising the package PA.

As seen from FIG. 58 as well, this makes it possible to increase the spacing between the respective portions of the die pads DP1 to DP3 exposed from the back surface of the package PA. Further, it is possible to increase the spacing between the portion of each of the die pads DP1 to DP3 exposed from the back surface of the package PA and the portion of each of the leads LD exposed from the back surface of the package PA. As a result, it is possible to suppress the influence of exposure of the die pads DP1 to DP3 in the back surface of the package PA on breakdown voltage. Further, even though the die pads DP1 to DP3 are exposed from the back surface of the package PA, the die pads DP1 to DP3 can be prevented from coming off from the package PA and the strength of the semiconductor device can be enhanced.

In the semiconductor device SM1g in this embodiment , any lead LD is not bent in the package PA. Each lead LD is half etched from the under surface side when it is fabricated (the lead frame is fabricated). As a result, the leads are thinner in their portions closer to the die pads DP1 to DP3 than in their portions farther therefrom (portions on the side of the peripheral portion of the back surface of the package PA). The under surface of each lead LD is exposed at its thicker portion in the back surface of the package PA and its thinner portion is covered with the resin comprising the package PA.

The other respects in the configuration of the semiconductor device SM1g are substantially the same as in that of the semiconductor device SM1 in the first embodiment and the description thereof will be omitted. The relation of coupling and functions of the semiconductor device SM1g in the light emitting device 1 are the same as those of the semiconductor device SM1 in the first embodiment.

This embodiment is equivalent to a modification to the first embodiment in which the under surfaces of the die pads DP1, DP2, DP3 are exposed in the back surface of the package PA. Similarly with this embodiment, the under surface of each of the die pads DP1, DP2, DP3, DP4, DP5, DP6 can be exposed in the back surface of the package PA in the second to seventh embodiments. The thickness of the semiconductor device can be thereby reduced as in this embodiment. For this reason, the following measure can be taken on a case-by-case basis: when a high priority is given to the enhancement of the breakdown voltage of the semiconductor device, each of the die pads DP1 to DP6 is not exposed in the back surface of the package PA as in the first to seventh embodiment; and when a high priority is given to the reduction of the thickness of the semiconductor device, the die pads DP1 to DP6 are exposed in the back surface of the package PA as described in relation to this embodiment.

The semiconductor device SM1g in this embodiment can be manufactured by substantially the same manufacturing process as for the semiconductor device SM1 described in relation to the ninth embodiment.

### 11th Embodiment

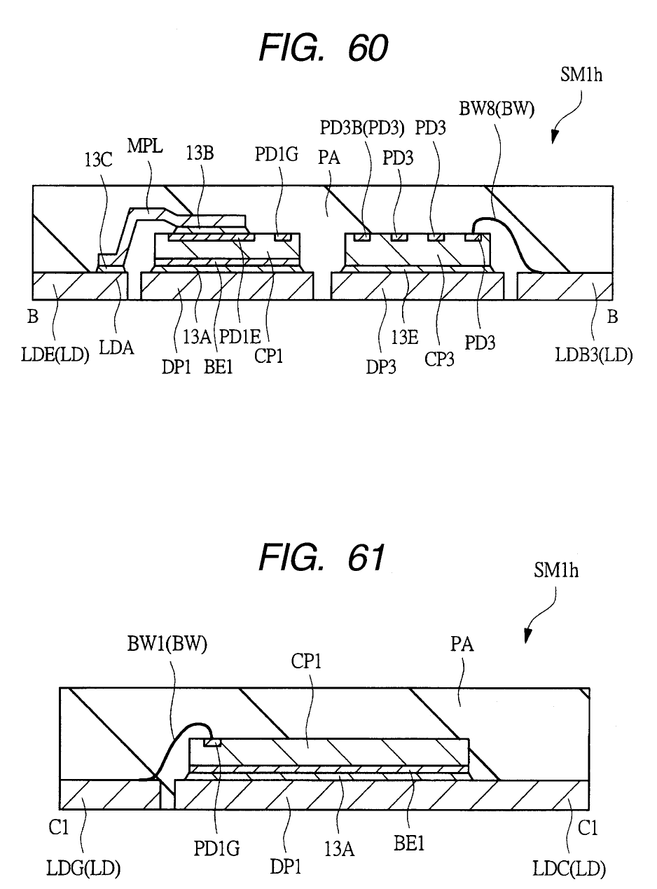

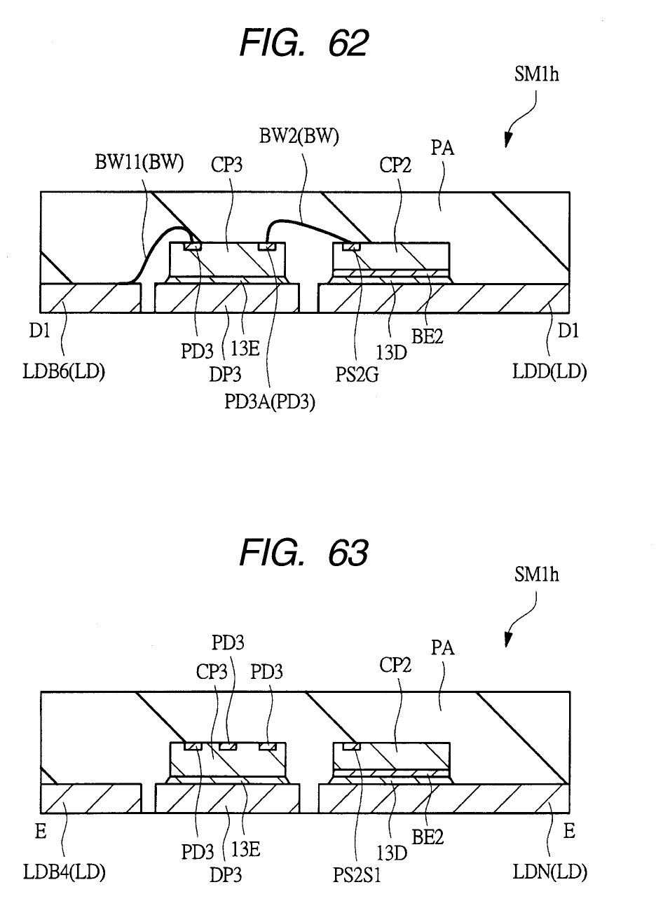

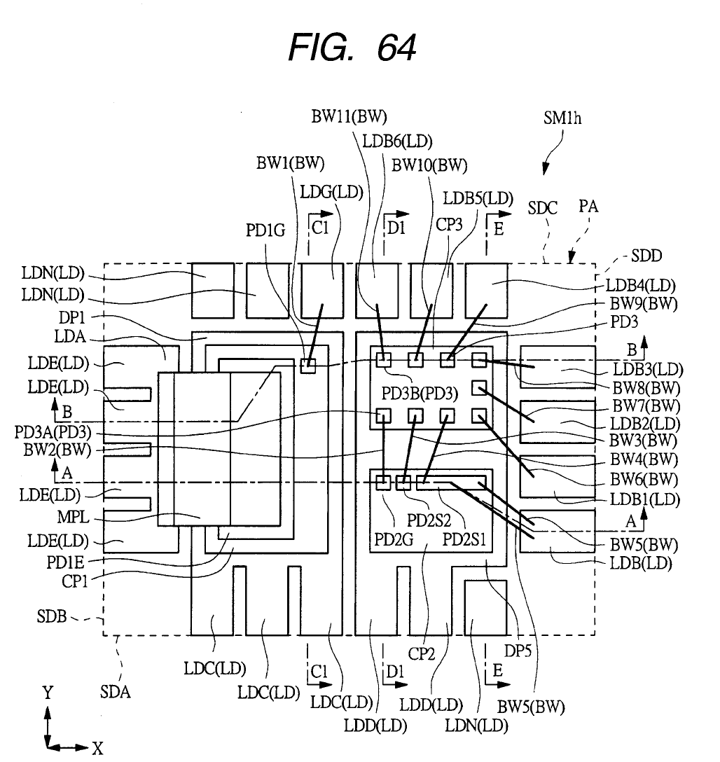

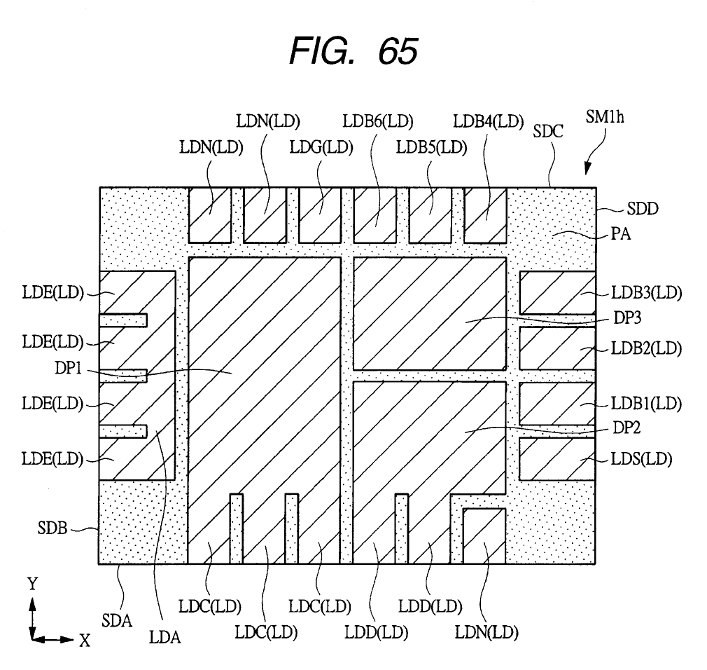

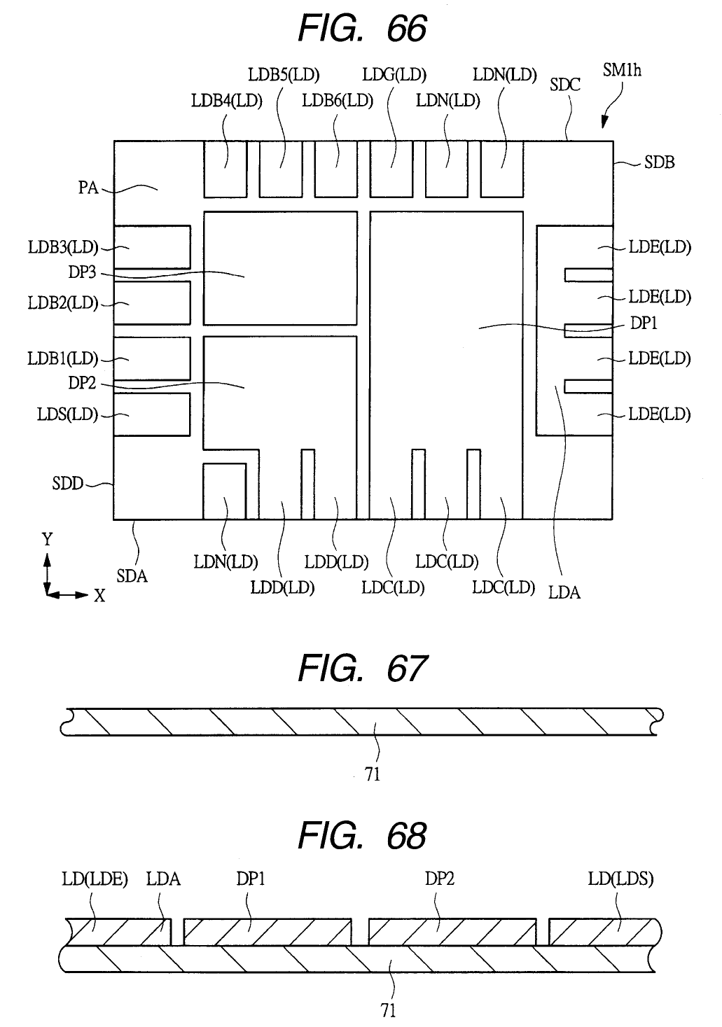

FIG. 59 to FIG. 63 are sectional views of a semiconductor device SM1h in an 11th embodiment and respectively taken in substantially the same sectional position as in FIG. 6 to FIG. 10. FIG. 64 is a planar transparent view of the semiconductor device SM1h, corresponding to FIG. 11, and shows an overall plan view illustrating the interior of the package PA seen through. A sectional view of the semiconductor device SM1h taken in the position of line A-A of FIG. 64 substantially corresponds to FIG. 59; a sectional view of the semiconductor device SM1h taken in the position of line B-B of FIG. 64 substantially corresponds to FIG. 60; a sectional view of the semiconductor device SM1h taken in the position of line C1-C1 of FIG. 64 substantially corresponds to FIG. 61; a sectional view of the semiconductor device SM1h taken in the position of line D1-D1 of FIG. 64 substantially corresponds to FIG. 62; and a sectional view of the semiconductor device SM1h taken in the position of line E-E of FIG. 64 substantially corresponds to FIG. 63. FIG. 65 is a planar transparent view of the semiconductor device SM1h in FIG. 64 with the metal plate MPL, wires BW, and semiconductor chips CP1, CP2, CP3 further removed (seen through) and corresponds to FIG. 13. Though FIG. 65 is a plan view, in FIG. 65, the die pads DP1, DP2, DP3, lead wiring LDA and leads LD are hatched with oblique lines and the material (resin material) comprising the package PA is hatched with dots to facilitate visualization. FIG. 66 is a bottom view (back side back view) of the semiconductor device SM1h and corresponds to FIG. 5. A top view of the semiconductor device SM1h in this embodiment is the same as FIG. 4 and it will be omitted here.

As seen from the comparison of FIG. 64 and FIG. 65 with FIG. 11 and FIG. 13, the semiconductor device SM1h in this embodiment illustrated in FIG. 59 to FIG. 66 is not provided with what is equivalent to the lead LDN1. (What is equivalent to the lead LDN1 is, in other words, a non-contact lead integrally coupled to the die pad DP3.) In this embodiment, therefore, the die pad DP3 is not coupled to any lead LD and is isolated. Since what is equivalent to the lead LDN1 is not present in this embodiment, the following measure is taken as seen from the comparison of FIG. 65 with FIG. 13: the lead LDB4 is placed in the position of the lead LDN1 in FIG. 13; the lead LDB5 is placed in the position of lead LDB4 in FIG. 13; the lead LDB6 is placed in the position of the lead LDB5 in FIG. 13; the lead LDG is placed in the position of the lead LDB6 in FIG. 13; and a non-contact lead LDN is placed in the position of the lead LDG in FIG. 13.

In this embodiment, a lead LD (the lead LDN1) is not coupled to the die pad DP3 and the die pad DP3 is not provided with anything like a suspended lead. The planar dimensions of the semiconductor device SM1h can be accordingly reduced.

In this embodiment, the under surfaces of the die pads DP1 to DP3 are exposed in the back surface of the package PA. Since it is unnecessary to cover the under surface of each of the die pads DP1, DP2, DP3 with the resin comprising the package PA, it is possible to reduce the thickness of the package PA and thus the thickness of the semiconductor device SM1h.

The semiconductor device SM1h in this embodiment is manufactured by the electrocasting described later. As illustrated in the sectional views in FIG. 59 to FIG. 63 as well, therefore, the leads LD, lead wiring LDA, and die pads DP1, DP2, DP3 are substantially flat and have substantially the same thickness as a whole. As illustrated in the bottom view in FIG. 66 as well, for this reason, the entire under surface of each of the leads LD and die pads DP1, DP2, DP3 is exposed in the back surface of the package PA. The semiconductor device SM1h in this embodiment is substantially the same as the semiconductor device SM1 in the first embodiment in the other respects in configuration and functions.

In the semiconductor device SM1h in this embodiment, the die pad DP3 is not provided with anything like a suspended lead (what is equivalent to the lead LDN1). Therefore, it is difficult to manufacture the semiconductor device SM1h using a lead frame but it can be manufactured by the electrocasting described below (FIG. 67 to FIG. 74). Since the semiconductor device SM1h is manufactured by electrocasting, the under surface of each of the die pads DP1, DP2, DP3 is exposed in the back surface of the package PA.

FIG. 67 to FIG. 74 are sectional views of the semiconductor device SM1h in this embodiment in manufacturing process and illustrate the section corresponding to FIG. 59.

To manufacture the semiconductor device SM1h, first, a metal plate 71 such as a copper plate is prepared as illustrated in FIG. 67. As illustrated in FIG. 68, thereafter, the die pads DP1, DP2, DP3, leads LD, and lead wiring LDA for the semiconductor device SM1h are formed over the upper surface of the metal plate 71 by plating.

More specific description will be given. A mask pattern having openings in the areas where the die pads DP1, DP2, DP3, leads LD, and lead wiring LDA are to be formed is formed over the upper surface of the metal plate 71. A plating layer (preferably, an electrolytic plating layer) is formed in the areas not covered with this mask pattern. Thereafter, this mask pattern is removed. Thus a plating layer pattern comprising the die pads DP1, DP2, DP3, leads LD, and lead wiring LDA can be formed over the upper surface of the metal plate 71. This plating layer is formed by stacking, for example, a gold (Au) layer, a nickel (Ni) layer, and a silver (Ag) layer in this order from bottom.

The die pads DP1, DP2, DP3, leads LD and lead wiring LDA are formed over the metal plate 71 and held there; therefore, it is unnecessary to provide the die pad DP3 with something like a suspended lead (what is equivalent to the lead LDN1) as mentioned above. Since FIG. 68 is a sectional view corresponding to FIG. 59, the die pad DP3 is not shown in the sectional view in FIG. 68.

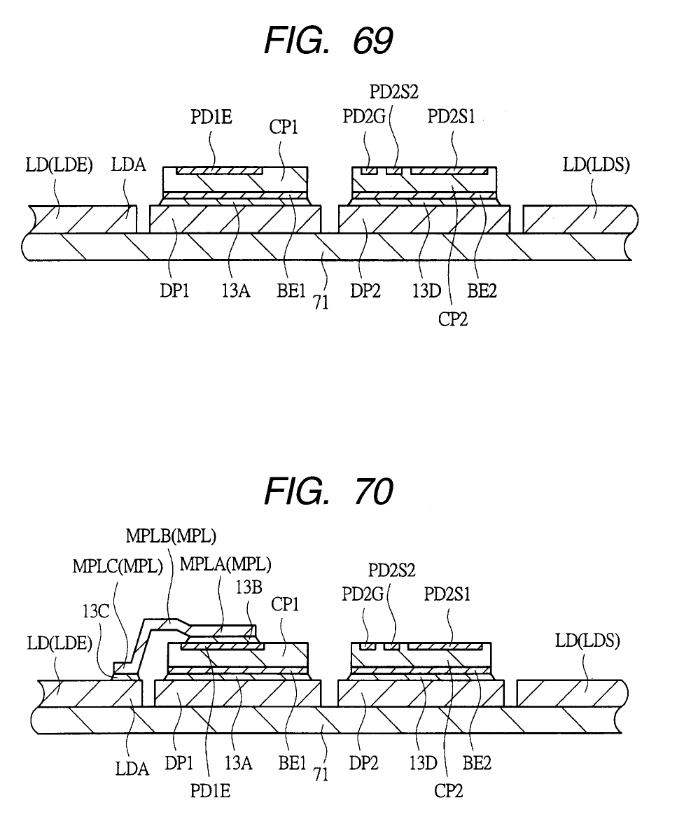

Subsequently, the semiconductor chips CP1, CP2, CP3 are respectively die-bonded to the die pads DP1, DP2, DP3 over the metal plate 71. As illustrated in FIG. 69, as a result, the semiconductor chip CP1 is bonded to the die pad DP1 through the adhesive layer 13A; and the semiconductor chip CP2 is bonded to the die pad DP2 through the adhesive layer 13D. Though not shown in the sectional view in FIG. 69, the semiconductor chip CP3 is bonded to the die pad DP3 through the adhesive layer 13E.

Subsequently, the metal plate MPL is placed over and joined to the semiconductor chip CP1 and the lead wiring LDA. As illustrated in FIG. 70, as a result, the first portion MPLA of the metal plate MPL is joined to the pad electrode PD1E for emitter of the semiconductor chip CP1 through the adhesive layer 13B; and the second portion MPLB of the metal plate MPL is joined to the lead wiring LDA through the adhesive layer 13C.

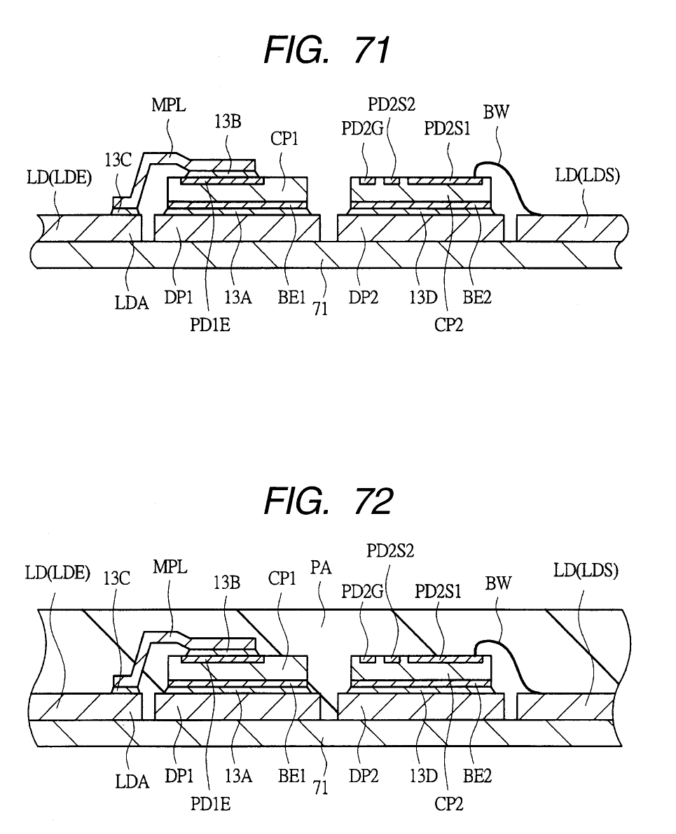

Subsequently, a wire bonding step (step for bonding wires BW) is carried out. The pad electrodes PD1G, PD2S1, PD3 of the semiconductor chips CP1, CP2, CP3 and respective leads LD to be electrically coupled thereto are thereby coupled together through wires BW. Further, the pad electrodes PD1G, PD2S1, PD2S2 of the semiconductor chip CP2 and respective pad electrodes PD3 of the semiconductor chip CP3 to be electrically coupled thereto are coupled together through wires BW. FIG. 71 is a sectional view obtained after the wire bonding step.

Subsequently, a molding step (resin sealing step) is carried out. The semiconductor chips CP1, CP2, CP3, leads LD, lead wiring LDA, die pads DP1, DP2, DP3, metal plate MPL, and wires BW are thereby sealed with the resin comprising the package PA. FIG. 72 is a sectional view obtained after the molding step. The package PA formed of sealing resin is so formed as to cover the semiconductor chips CP1, CP2, CP3, leads LD, lead wiring LDA, die pads DP1, DP2, DP3, metal plate MPL, and wires BW over the upper surface of the metal plate 71. The metal plate 71 is exposed from the package PA.

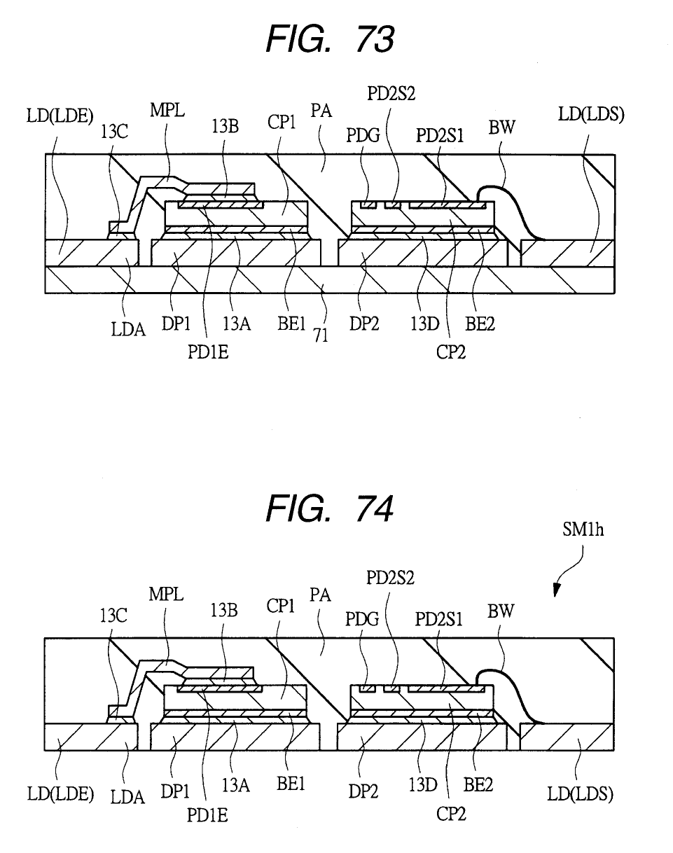

Subsequently, the package PA is diced (cut)) together with the metal plate 71. At this time, the package PA is cut together with the metal plate 7 so that each piece obtained as the result of cutting corresponds to one semiconductor device SM1h. FIG. 73 is a sectional view obtained by the dicing (cutting). At this stage, the metal plate 71 still remains over the back surface of the package PA.

Subsequently, the metal plate 71 is removed by etching or the like. As illustrated in FIG. 74, as a result, the metal plate 71 is removed from over the back surface of the package PA and the semiconductor device SM1h is obtained. The metal plate 71 is so etched that the metal plate 71 is removed but the die pads DP1, DP2, DP3, leads LD, and lead wiring LDA remain.

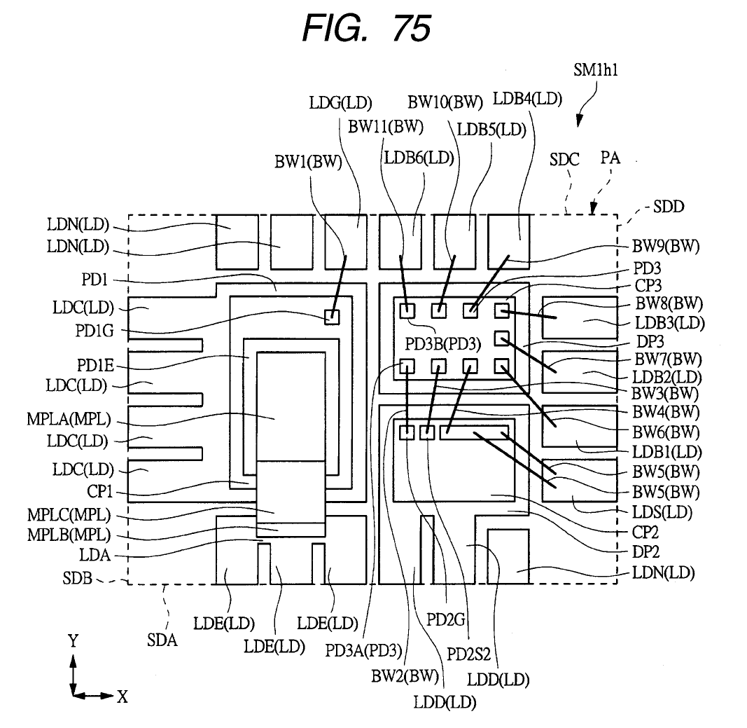

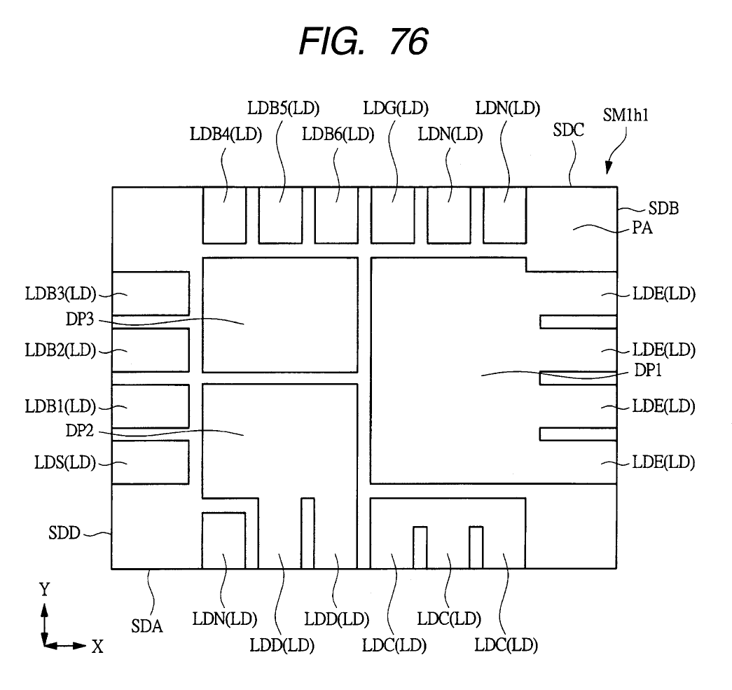

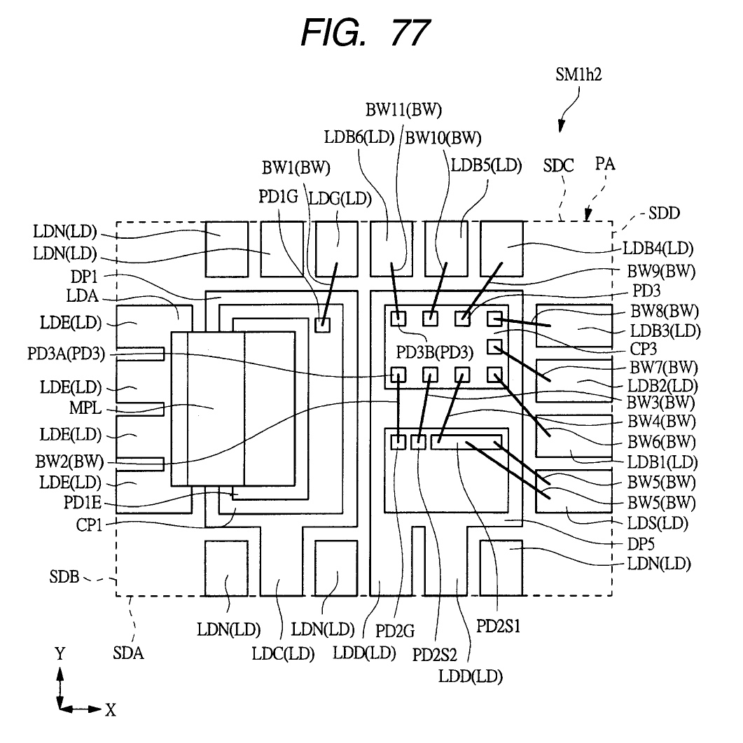

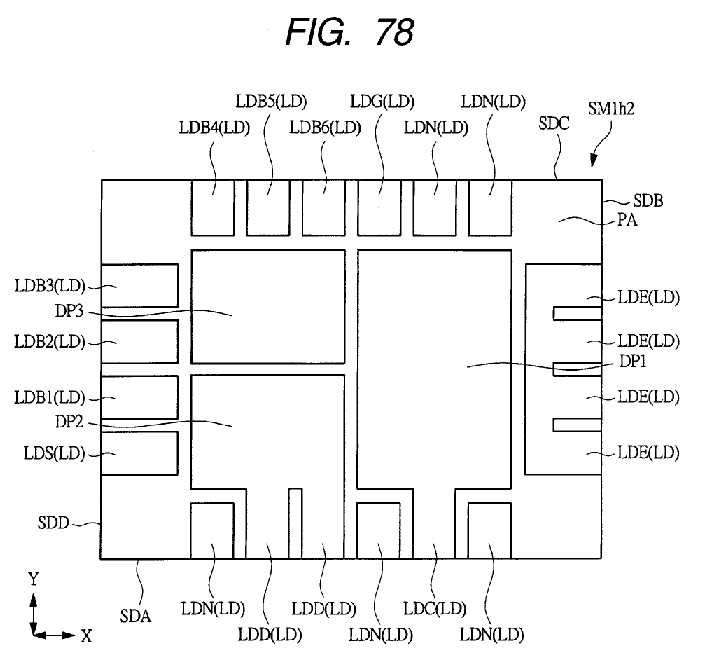

FIG. 75 is a planar transparent view of a semiconductor device SM1h1 obtained by manufacturing the semiconductor device SM1e in the sixth embodiment by the electrocasting described in relation to this embodiment and FIG. 76 is a bottom view (back side back view) thereof. These drawings respectively correspond to FIG. 35 and FIG. 39. FIG. 77 is a planar transparent view of a semiconductor device SM1h2 obtained by manufacturing the semiconductor device SM1f in the seventh embodiment by the electrocasting described in relation to this embodiment and FIG. 78 is a bottom view (back side back view) thereof. These drawings respectively correspond to FIG. 40 and FIG. 5.

The comparison of FIG. 75 and FIG. 76 with FIG. 35 and FIG. 39 and the comparison of FIG. 77 and FIG. 78 with FIG. 40 and FIG. 5 reveal the following: also in the semiconductor devices SM1h1, SM1h2 as well as the semiconductor device SM1h, there is not provided what is equivalent to the lead LDN1 (that is, a non-contact lead integrally coupled to the die pad DP3). Therefore, also in the semiconductor devices SM1h1, SM1h2 as well as the semiconductor device SM1h, the die pad DP3 is not coupled to any lead LD and is isolated. For this reason, the following measure is taken also in the semiconductor devices SM1h1, SM1h2 ₐₛ in the semiconductor device SM1h: the lead LDB4 is placed in the position of the lead LDN1 in FIG. 35 and FIG. 40; the lead LDB5 is placed in the position of the lead LDB4 in FIG. 35 and FIG. 40; the lead LDB6 is placed in the position of the lead LDB5 in FIG. 35 and FIG. 40; the lead LDG is placed in the position of the lead LDB6 in FIG. 35 and FIG. 40; and a non-contact lead LDN is placed in the position of the lead LDG in FIG. 35 and FIG. 40. Also in the semiconductor devices SM1h1, SM1h2, no lead LD (the lead LDN1) is coupled to the die pad DP3 and the die pad DP3 is not provided with anything like a suspended lead. The planar dimensions of the semiconductor devices SM1h1, SM1h2 can be accordingly reduced.

Similarly with the semiconductor device SM1h, the semiconductor devices SM1h1, SM1h2 are also manufactured by electrocasting. As illustrated in FIG. 76 and FIG. 78, therefore, the under surfaces of the die pads DP1, DP2, DP3 are exposed in the back surface of the package PA. The leads LD, lead wiring LDA, and die pads DP1, DP2, DP3 are substantially flat and have substantially the same thickness as a whole. Since it is unnecessary to cover the under surfaces of the die pads DP1, DP2, DP3 with the resin comprising the package PA, it is possible to reduce the thickness of the package PA and thus the thickness of the semiconductor devices SM1h1, SM1h2.

The semiconductor devices SM1a, SM1b, SM1c, SM1d in the second to fifth embodiments can also be manufactured by the electrocasting described in relation to this embodiment. In this case, however, the under surface of each of the die pads DP1, DP2, DP3, DP4, DP5, DP6 is exposed in the back surface of the package PA; and the leads LD, lead wiring LDA, and die pads DP1, DP2, DP3, DP4, DP5, DP6 are substantially flat and have substantially the same thickness as a whole. In this case, it is unnecessary to cover the under surface of each of the die pads DP1, DP2, DP3, DP4, DP5, DP6 with the resin comprising the package PA; therefore, it is possible to reduce the thickness of the package PA and thus the thickness of the semiconductor device.

Meanwhile, in the semiconductor devices SM1, SM1a, SM1b, SM1c, SM1d, SM1e, SM1f in the first to seventh embodiments, the exposure of the under surface of each of the die pads DP1, DP2, DP3, DP4, DP5, DP6 in the back surface of the package PA is avoided. In this case, it is possible to further enhance the breakdown voltage of the leads LD and to further enhance the reliability of the semiconductor device.

### 12th Embodiment

With respect to this embodiment, description will be given to an example of the configuration of the semiconductor chip CP1 used in the first to 11th embodiments.

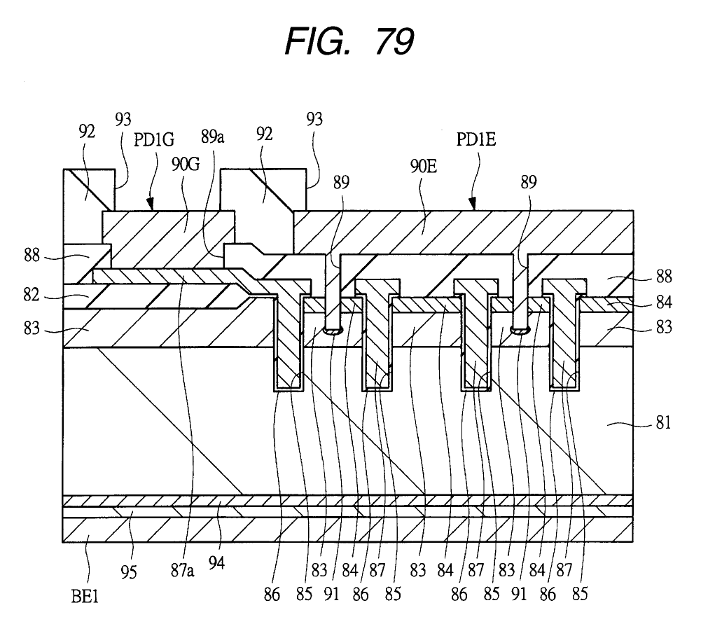

As mentioned above, the semiconductor chip CP1 is a semiconductor chip in which an IGBT element comprising the IGBT 2 is formed. FIG. 79 is a substantial part sectional view of the semiconductor chip CP1.

The IGBT 2 is formed in the semiconductor substrate 81 comprising the semiconductor chip CP1. The semiconductor substrate 81 is comprised of single-crystal silicon lightly doped with an n-type impurity (for example, phosphorus (P)) or the like. Over the principal surface of this semiconductor substrate 81, there is formed a field insulating film (element isolation region) 82 comprised of, for example, silicon oxide or the like. In an active region defined by this field insulating film 82, there are formed multiple unit IGBT cells comprising the IGBT 2. The IGBT 2 is formed by coupling these unit IGBT cells in parallel.

In the upper part (superficial portion) of the semiconductor substrate 81, there are formed a p-type semiconductor region 83 and a n⁺-type semiconductor region 84. The n⁺-type semiconductor region 84 is shallowly formed in the upper part of the p-type semiconductor region 83. The p-type semiconductor region 83 functions as a channel region of the IGBT and the n⁺-type semiconductor region 84 functions as the emitter region of the IGBT.

In the semiconductor substrate 81, in addition, there are formed trenches 85 extended from its principal surface in the direction of the thickness of the semiconductor substrate 81. Each trench 85 is so formed that it penetrates the n⁺-type semiconductor region 84 and the p-type semiconductor region 83 from the upper surface of the n⁺-type semiconductor region 84 and is terminated in the semiconductor substrate 81 positioned thereunder. Over the bottom surface and lateral surface of each trench 85, there is formed an insulating film 86 comprised of, for example, silicon oxide. This insulating film 86 functions as the gate oxide film of the IGBT. In each trench 85, a gate electrode 87 is buried with the insulating film 86 in-between. This gate electrode 87 functions as the gate electrode of the IGBT. The gate electrode 87 is comprised of a polycrystalline silicon film added with, for example, an n-type impurity (for example, phosphorus).

Also over part of the field insulating film 82, there is formed a wiring portion 87a for drawing gate comprised of a conductive film in the same layer as the gate electrodes 87 are. The gate electrodes 87 and the wiring portion 87a for drawing gate are integrally formed and electrically coupled to each other. Over the principal surface of the semiconductor substrate 81, an insulating film 88 is so formed that it covers the gate electrodes 87 and the wiring portion 87a for drawing gate. The wiring portion 87a for drawing gate is electrically coupled with wiring 90G through a contact trench (contact hole) 89a formed in the insulating film 88 covering it. The wiring 90G functions as gate wiring and is electrically coupled to a gate electrode 87 through the wiring portion 87a drawing gate.

Contact trenches 89 that penetrate the insulating film 88 and the n⁺-type semiconductor region 84 and whose bottom portion is terminated in the p-type semiconductor region 83 are formed between adjoining gate electrodes 87. At the bottom of each contact trench 89, there is formed a p⁺-type semiconductor region 91 covering it. This p⁺-type semiconductor region 91 is for bringing wiring 90E filled in the contact trenches 89 into ohmic contact with the p-type semiconductor region 83 at the bottom of each contact trench 89. The wiring 90E is formed over the insulating film 88 so that it fills the contact trenches 89. The wiring 90E functions as an emitter electrode (emitter wiring) and is electrically coupled to the n⁺-type semiconductor region 84 (emitter region). The wiring 90E is electrically coupled to the n⁺-type semiconductor region 84 for emitter through the contact trenches 89. The wiring 90E is electrically coupled to the p-type semiconductor region 83 for channel formation through the contact trenches 89.

The wiring 90G and the wiring 90E can be formed by, for example: forming a thin barrier conductor film (for example, a titanium tungsten film) over the insulating film 88 so that the contact trenches 89, 89a are filled therewith; forming a thick main conductor film (for example, an aluminum film or an aluminum alloy film) thereover; and then patterning the main conductor film and the barrier conductor film.

The wirings 90G, 90E are covered with a protective film (insulating film) 92 comprised of polyimide resin or the like. This protective film 92 is the film (insulating film) in the uppermost layer of the semiconductor chip CP1.

In part of the protective film 92, there are formed openings 93 exposing the wiring 90G for gate and wiring 90E for emitter positioned thereunder. The portion of the wiring 90G for gate exposed from one of these openings 93 is the pad electrode PD1G for gate; and the portion of the wiring 90E for emitter exposed from one of the openings 93 is the pad electrode PD1E for emitter.

In the superficial portion of the semiconductor substrate 81 on the back surface, there are formed a n⁺-type semiconductor region 94 and a p⁺-type semiconductor region 95 positioned between the n⁺-type semiconductor region 94 and the back surface. The p⁺-type semiconductor region 95 functions as the collector region of the IGBT and is formed in the backmost surface of the semiconductor substrate 81. The n⁺-type semiconductor region 94 functions as a field stop layer.

Over the back surface of the semiconductor substrate 81 (that is, over the p⁺-type semiconductor region 95), there is formed the back surface electrode BE1 for collector electrode. This back surface electrode BE1 is formed by, for example, stacking a titanium (Ti) layer, a nickel (Ni) layer, and a gold (Au) layer over the back surface of the semiconductor substrate 81 in this order. A metal silicide layer such as a nickel silicide film may be placed between the titanium (Ti) layer and the semiconductor substrate 81 (p⁺-type semiconductor region 95).

As mentioned above, the semiconductor chip CP1 is a semiconductor chip in which IGBT is formed.

Up to this point, concrete description has been given to the invention made by the present inventors based on its embodiments. However, the invention is not limited to these embodiments and can be variously modified without departing from its subject matter, needless to add.

What is claimed is:

1. A semiconductor device used in a light emitting device including a luminescent discharge tube, an IGBT for a discharge switch of the discharge tube coupled in series with the discharge tube, a capacitor coupled in parallel with a series circuit of the discharge tube and the IGBT and used for discharging the discharge tube, and MOSFET for the charge switch of the capacitor, the semiconductor device comprising:
a first semiconductor chip in which the IGBT is formed;
a second semiconductor chip in which the MOSFET is formed;
a third semiconductor chip in which a drive circuit of the IGBT and a control circuit of the MOSFET are formed; and
a sealing body sealing the first, second, and third semiconductor chips.

2. The semiconductor device according to claim 1, further comprising:
a plurality of lead terminals sealed in the sealing body so that part of each thereof is exposed from the sealing body,
wherein in the front surface of the third semiconductor chip, a plurality of pad electrodes are formed,
wherein the lead terminals include:
a first lead terminal for emitter electrically coupled to the emitter of the IGBT;
a second lead terminal for collector electrically coupled to the collector of the IGBT;
a third lead terminal for source electrically coupled to the source of the MOSFET;
a fourth lead terminal for drain electrically coupled to the drain of the MOSFET; and
a plurality of fifth lead terminals respectively electrically coupled to the pad electrodes of the third semiconductor chip.

3. The semiconductor device according to claim 2,
wherein the fifth lead terminals, and the first lead terminal for emitter and the second lead terminal for collector are respectively arranged on different sides of the sealing body as viewed in a plane.

4. The semiconductor device according to claim 3,
wherein the fifth lead terminals, the first lead terminal for emitter, and the second lead terminal for collector are respectively arranged on different sides of the sealing body as viewed in a plane.

5. The semiconductor device according to claim 4,
wherein the first lead terminal for emitter is arranged on a first side of the sealing body as viewed in a plane,
wherein the second lead terminal for collector is arranged on a second side of the sealing body intersecting the first side as viewed in a plane, and
wherein the fifth lead terminals are arranged both on a third side of the sealing body opposite to the first side and on a fourth side opposite to the second side as viewed in a plane.

6. The semiconductor device according to claim 5,
wherein the light emitting device is used for flash photography.

7. The semiconductor device according to claim 6,
wherein in the light emitting device, the MOSFET is brought into on state by the control circuit and the capacitor is thereby charged, and
wherein in the light emitting device, the IGBT is brought into on state by the drive circuit and as a result, the discharge tube is discharged and caused to emit light by voltage supplied by the capacitor.

8. The semiconductor device according to claim 7,
wherein the discharge tube is a xenon tube.

9. The semiconductor device according to claim 8, further comprising:
a first chip placement portion over which the first semiconductor chip is placed through a first joining material layer and which is sealed in the sealing body;
a second chip placement portion over which the second semiconductor chip is placed through a second joining material layer and which is sealed in the sealing body; and
a third chip placement portion over which the third semiconductor chip is placed through a third joining material layer and which is sealed in the sealing body,
wherein the lead terminals are arranged around the first, second, and third chip placement portions.

10. The semiconductor device according to claim 9,
wherein in the front surface of the first semiconductor chip, a first pad electrode for the emitter of the IGBT and a second pad electrode for the gate thereof are formed,
wherein in the back surface of the first semiconductor chip, a first back surface electrode for the collector of the IGBT is formed,
wherein in the front surface of the second semiconductor chip, a third pad electrode for the source of the MOSFET and a fourth pad electrode for the gate thereof are formed,
wherein in the back surface of the second semiconductor chip, a second back surface electrode for the drain of the MOSFET is formed,
wherein the first lead terminal for emitter is electrically coupled to the first pad electrode for emitter of the first semiconductor chip through a first conductive member,
wherein the second lead terminal for collector is integrally coupled to the first chip placement portion,
wherein the third lead terminal for source is electrically coupled to the third pad electrode for source of the second semiconductor chip through a second conductive member,
wherein the fourth lead terminal for drain is integrally coupled to the second chip placement portion, and
wherein the fifth lead terminals are respectively electrically coupled to the pad electrodes of the third semiconductor chip through a third conductive member.

11. The semiconductor device according to claim 10,
wherein the first and second chip placement portions and the first and second joining material layers are conductive,
wherein the first back surface electrode for collector of the first semiconductor chip is electrically coupled to the first chip placement portion through the first joining material layer that is conductive, and
wherein the second back surface electrode for drain of the second semiconductor chip is electrically coupled to the second chip placement portion through the second joining material layer that is conductive.

12. The semiconductor device according to claim 11,
wherein the fourth pad electrode for gate of the second semiconductor chip is electrically coupled to at least one of the pad electrodes of the third semiconductor chip through a fourth conductive member.

13. The semiconductor device according to claim 12,
wherein the first conductive member is a metal plate, and
wherein the second, third, and fourth conductive members are respectively a conductive wire.

14. The semiconductor device according to claim 13,
wherein in the light emitting device, the first lead terminal for emitter of the semiconductor device is coupled to the capacitor and the second lead terminal for collector of the semiconductor device is coupled to the discharge tube.

15. The semiconductor device according to claim 14,
wherein none of the surfaces of the first, second, third chip placement portions on the opposite side to the side where the first, second, and third semiconductor chips are placed is exposed from the sealing body.

16. The semiconductor device according to claim 15,
wherein the lead terminals further includes a sixth lead terminal that is not electrically coupled with any of the electrodes of the first, second, and third semiconductor chips, and
wherein the sixth lead terminal is integrally coupled to the third chip placement portion.

17. The semiconductor device according to claim 16,
wherein the lead terminals further include a seventh lead terminal for the gate of the IGBT electrically coupled to the second pad electrode for gate of the first semiconductor chip through a fifth conductive member.

18. The semiconductor device according to claim 17,
wherein the fifth conductive member is a conductive wire.

19. The semiconductor device according to claim 14,
wherein the second pad electrode for gate of the first semiconductor chip is electrically coupled to at least one of the pad electrodes of the third semiconductor chip through a sixth conductive member.

20. The semiconductor device according to claim 19,
wherein the sixth conductive member is a conductive wire.

21. The semiconductor device according to claim 14,
wherein the surfaces of the first, second, and third chip placement portions on the opposite side to the side where the first, second, and third semiconductor chips are placed are exposed from the sealing body.

22. The semiconductor device according to claim 7, further comprising:
a chip placement portion over which the first, second, and third semiconductor chips are respectively placed through first, second, and third joining material layers and which is sealed in the sealing body,
wherein the lead terminals are arranged around the chip placement portion.

23. The semiconductor device according to claim 22,
wherein in the front surface of the first semiconductor chip, a first pad electrode for the emitter of the IGBT and a second pad electrode for the gate thereof are formed,
wherein in the back surface of the first semiconductor chip, a first back surface electrode for the collector of the IGBT is formed,
wherein in the front surface of the second semiconductor chip, a third pad electrode for the source of the MOSFET, a fourth pad electrode for the gate thereof, and a fifth pad electrode for the drain thereof are formed,
wherein the first lead terminal for emitter is electrically coupled to the first pad electrode for emitter of the first semiconductor chip through a first conductive member,
wherein the second lead terminal for collector is integrally coupled to the first chip placement portion,
wherein the third lead terminal for source is electrically coupled to the third pad electrode for source of the second semiconductor chip through a second conductive member,
wherein the fourth lead terminal for drain is electrically coupled to the fifth pad electrode for drain of the second semiconductor chip through a seventh conductive member, and
wherein the fifth lead terminals are respectively electrically coupled to the pad electrodes of the third semiconductor chip through a third conductive member.

24. The semiconductor device according to claim 23,
wherein the chip placement portion and the first joining material layer are conductive,
wherein the first back surface electrode for collector of the first semiconductor chip is electrically coupled to the chip placement portion through the first joining material layer that is conductive, and
wherein the second and third joining material layers have insulating properties.

25. The semiconductor device according to claim 7, further comprising:
a first chip placement portion over which the first semiconductor chip is placed through a first joining material layer and which is sealed in the sealing body; and
a second chip placement portion over which the second and third semiconductor chips are respectively placed through second and third joining material layers and which is sealed in the sealing body,
wherein the lead terminals are arranged around the first and second chip placement portions.

26. The semiconductor device according to claim 25,
wherein in the front surface of the first semiconductor chip, a first pad electrode for the emitter of the IGBT and a second pad electrode for the gate thereof are formed,
wherein in the back surface of the first semiconductor chip, a first back surface electrode for the collector of the IGBT is formed,
wherein in the front surface of the second semiconductor chip, a third pad electrode for the source of the MOSFET and a fourth pad electrode for the gate thereof are formed,
wherein in the back surface of the second semiconductor chip, a second back surface electrode for the drain of the MOSFET is formed,
wherein the first lead terminal for emitter is electrically coupled to the first pad electrode for emitter of the first semiconductor chip through a first conductive member,
wherein the second lead terminal for collector is integrally coupled to the first chip placement portion,
wherein the third lead terminal for source is electrically coupled to the third pad electrode for source of the second semiconductor chip through a second conductive member,
wherein the fourth lead terminal for drain is integrally coupled to the second chip placement portion, and
wherein the fifth lead terminals are respectively coupled to the pad electrodes of the third semiconductor chip through a third conductive member.

27. The semiconductor device according to claim 26,
wherein the first and second chip placement portions and the first and second joining material layers are conductive,
wherein the first back surface electrode for collector of the first semiconductor chip is electrically coupled to the first chip placement portion through the first joining material layer that is conductive,
wherein the second back surface electrode for drain of the second semiconductor chip is electrically coupled to the second chip placement portion through the second joining material layer that is conductive, and
wherein the third joining material layer has insulating properties.

28. The semiconductor device according to claim 7, further comprising:
a first chip placement portion over which the first and third semiconductor chips are respectively placed through first and third joining material layers and which is sealed in the sealing body; and
a second chip placement portion over which the second semiconductor chip is placed through a second joining material layer and which is sealed in the sealing body,
wherein the lead terminals are arranged around the first and second chip placement portions.

29. The semiconductor device according to claim 28,
wherein in the front surface of the first semiconductor chip, a first pad electrode for the emitter of the IGBT and a second pad electrode for the gate thereof are formed,
wherein in the back surface of the first semiconductor chip, a first back surface electrode for the collector of the IGBT is formed,
wherein in the front surface of the second semiconductor chip, a third pad electrode for the source of the MOSFET and a fourth pad electrode for the gate thereof are formed,
wherein in the back surface of the second semiconductor chip, a second back surface electrode for the drain of the MOSFET is formed,
wherein the first lead terminal for emitter is electrically coupled to the first pad electrode for emitter of the first semiconductor chip through a first conductive member,
wherein the second lead terminal for collector is integrally coupled to the first chip placement portion,
wherein the third lead terminal for source is electrically coupled to the third pad electrode for source of the second semiconductor chip through a second conductive member,
wherein the fourth lead terminal for drain is integrally coupled to the second chip placement portion, and
wherein the fifth lead terminals are respectively electrically coupled to the pad electrodes of the third semiconductor chip through a third conductive member.

30. The semiconductor device according to claim 29,
wherein the first and second chip placement portions and the first and second joining material layers are conductive,
wherein the first back surface electrode for collector of the first semiconductor chip is electrically coupled to the first chip placement portion through the first joining material layer that is conductive,
wherein the second back surface electrode for drain of the second semiconductor chip is electrically coupled to the second chip placement portion through the second joining material layer that is conductive, and
wherein the third joining material layer has insulating properties.

31. The semiconductor device according to claim 5,
wherein the fourth lead terminal for drain is arranged on the first side of the sealing body as viewed in a plane, and
wherein the third lead terminal for source is arranged on the fourth side of the sealing body as viewed in a plane.

32. The semiconductor device according to claim 5,
wherein the fourth lead terminal for drain is arranged on the second side of the sealing body as viewed in a plane, and
wherein the third lead terminal for source is arranged on the third side of the sealing body as viewed in a plane.

33. The semiconductor device according to claim 4,
wherein the lead terminals further include a sixth lead terminal that is not electrically coupled with any of the electrodes of the first, second, and third semiconductor chips.

34. The semiconductor device according to claim 33,
wherein the sixth lead terminal is arranged next to the second lead terminal for collector.

35. The semiconductor device according to claim 34,
wherein the sixth lead terminal is arranged on both adjacent sides of the second lead terminal for collector.

36. The semiconductor device according to claim 34,
wherein the second lead terminal for collector and the fourth lead terminal for drain are arranged on the same side of the sealing body as viewed in a plane, and
wherein the sixth lead terminal is arranged between the second lead terminal for collector and the fourth lead terminal for drain.
